(19) United States
(12) Patent Application Publication
(10) Pub. No.: US 2019/0011835 A1
(43) Pub. Date: Jan. 10, 2019

(54) PROTECTIVE FILM FORMING COMPOSITION, METHOD FOR PRODUCING PROTECTIVE FILM FORMING COMPOSITION, PATTERN FORMING METHOD, AND METHOD FOR MANUFACTURING ELECTRONIC DEVICE

(71) Applicant: FUJIFILM Corporation, Tokyo (JP)

(72) Inventor: Yasunori YONEKUTA, Haibara-gun (JP)

(73) Assignee: FUJIFILM Corporation, Tokyo (JP)

(21) Appl. No.: 16/131,167

(22) Filed: Sep. 14, 2018

Related U.S. Application Data
(63) Continuation of application No. PCT/JP2017/009019, filed on Mar. 7, 2017.

(30) Foreign Application Priority Data
Mar. 30, 2016 (JP) 2016-067337

(51) Int. Cl. G03F 7/11; C09D 133/08; G03F 7/20; G03F 7/16; C09D 133/16; C09D 125/18; C09D 125/14; G03F 7/38; G03F 7/32

(52) U.S. Cl. CPC G03F 7/11; C09D 133/08; G03F 7/2041; G03F 7/16; G03F 7/168; G03F 7/32; C09D 133/16; C09D 125/18; C09D 125/14; G03F 7/38; G03F 7/2006

(57) ABSTRACT

The present invention provides a protective film forming composition capable of forming a pattern having excellent depth of focus and exposure latitude even after being stored for a predetermined period of time.

The protective film forming composition of the present invention contains a resin, a basic compound, a solvent, and an antioxidant.

### CROSS-REFERENCE TO RELATED APPLICATIONS

This application is a Continuation of PCT International Application No. PCT/JP2017/009019 filed on Mar. 7, 2017, which claims priority under 35 U.S.C. § 119(a) to Japanese Patent Application No. 2016-067337 filed on Mar. 30, 2016. The above application is hereby expressly incorporated by reference, in its entirety, into the present application.

### BACKGROUND OF THE INVENTION

### 1. Field of the Invention

The present invention relates to a protective film forming composition, a method for producing a protective film forming composition, a pattern forming method, and a method for manufacturing an electronic device.

### 2. Description of the Related Art

As the structures of various electronic devices such as semiconductor devices and liquid crystal devices become finer, liquid immersion exposure is used in some cases in order to form finer resist patterns. During the liquid immersion exposure, a protective film called a topcoat is formed on an actinic ray-sensitive or radiation-sensitive film (hereinafter also referred to as a “resist film”) formed using an actinic ray-sensitive or radiation-sensitive resin composition.

For example, JP2014-56194A describes “a protective film forming composition for a negative tone pattern forming method, using a developer containing an organic solvent, in which the protective film forming composition contains [A] fluorine atom-containing polymer and [B] solvent, and [B] solvent includes at least one selected from the group consisting of a chained ether-based solvent, a hydrocarbon-based solvent, and an alcohol-based solvent having 5 or more carbon atoms”.

### SUMMARY OF THE INVENTION

The present inventors have investigated the protective film forming composition described in JP2014-56194A, and thus, have thus clarified that there are cases where a protective film is formed on a resist film to form a laminate film, using a protective film forming composition, after passage of a certain period of time from the production of the composition, and in a case of forming a pattern using the laminate film, depth of focus (DOF) and/or exposure latitude (EL) becomes insufficient in some cases.

Therefore, an object of the present invention is to provide a protective film forming composition capable of forming a pattern having excellent depth of focus and exposure latitude even after being stored for a predetermined period of time.

In addition, another object of the present invention is to provide a method for producing a protective film forming composition, a pattern forming method, and a method for manufacturing an electronic device.

In order to accomplish the objects, the present inventors have conducted extensive studies, and as a result, they have found that the objects can be accomplished by a protective film forming composition containing a resin, a basic compound, a solvent, and an antioxidant, thereby completing the present invention.

That is, the present inventors have found that the objects can be accomplished by the following configurations.

[1] A protective film forming composition, comprising:
a resin;
a basic compound;
a solvent; and
an antioxidant.

[2] The protective film forming composition as described in [1],
in which the resin contains a resin XA and a resin XB containing fluorine atoms, and the resin XA is a resin not containing fluorine atoms, or in a case where the resin XA contains fluorine atoms, the resin XA is a resin having a lower content of fluorine atoms than the content of fluorine atoms in the resin XB, based on a mass.

[3] The protective film forming composition as described in [2],
in which the content of the resin XB is 20% by mass or less with respect to the total solid content of the protective film forming composition.

[4] The protective film forming composition as described in any one of [1] to [3],
in which the solvent contains a secondary alcohol.

[5] The protective film forming composition as described in any one of [2] to [4],
in which the content of fluorine atoms in the resin XA is 0% to 5% by mass.

[6] The protective film forming composition as described in any one of [2] to [5],
in which the content of fluorine atoms in the resin XB is 15% by mass or more.

[7] The protective film forming composition as described in any one of [1] to [6],
in which the solvent contains a secondary alcohol and an ether-based solvent.

[8] The protective film forming composition as described in any one of [2] to [7],
in which the difference between the content of fluorine atoms in the resin XA and the content of fluorine atoms in the resin XB is 10% by mass or more.

[9] The protective film forming composition as described in any one of [2] to [8],
in which the resin XA is a resin not containing fluorine atoms.

[10] The protective film forming composition as described in any one of [1] to [9],
in which the basic compound contains at least one selected from the group consisting of an amine compound and an amide compound.

[11] A method for producing a protective film forming composition, comprising:
a step of preparing a solvent having a content of peroxides of an acceptable value or less; and
a step of mixing the solvent, a resin, a basic compound, and an antioxidant to prepare a protective film forming composition.

[12] A pattern forming method comprising:
a step of forming an actinic ray-sensitive or radiation-sensitive film on a substrate, using an actinic ray-sensitive or radiation-sensitive resin composition;
a step of forming a protective film on the actinic ray-sensitive or radiation-sensitive film, using the protective film forming composition as described in any one of [1] to [10];
a step of exposing a laminate film including the actinic ray-sensitive or radiation-sensitive film and the protective film; and
a step of subjecting the exposed laminate film to development using a developer,
in which the protective film forming composition contains a resin, a basic compound, a solvent, and an antioxidant.

[13] The pattern forming method as described in [12],
in which the exposure is liquid immersion exposure.

[14] A method for manufacturing an electronic device, comprising the pattern forming method as described in [12] or [13].

According to the present invention, it is possible to provide a protective film forming composition capable of forming a pattern having excellent depth of focus and exposure latitude even after being stored for a predetermined period of time.

In addition, according to the present invention, it is also possible to provide a method for producing a protective film forming composition, a pattern forming method, and a method for manufacturing an electronic device.

### DESCRIPTION OF THE PREFERRED EMBODIMENTS

Hereinafter, the present invention will be described in detail.

Description of configuration requirements described below may be made on the basis of representative embodiments of the present invention, but the present invention is not limited to such embodiments.

Moreover, in citations for a group (atomic group) in the present specification, in a case where the group (atomic group) is denoted without specifying whether it is substituted or unsubstituted, the group (atomic group) includes both a group (atomic group) not having a substituent and a group (atomic group) having a substituent within a range not impairing the effects of the present invention. For example, an “alkyl group” includes not only an alkyl group not having a substituent (unsubstituted alkyl group), but also an alkyl group having a substituent (substituted alkyl group). This also applies to the respective compounds.

Furthermore, “radiation” in the present specification means, for example, a bright line spectrum of a mercury lamp, far ultraviolet rays typified by an excimer laser, extreme ultraviolet rays (EUV light), X-rays, electron beams, or the like. In addition, in the present specification, light means actinic rays or radiation. Furthermore, unless otherwise specified, “exposure” in the present specification includes not only exposure by a mercury lamp, far ultraviolet rays typified by an excimer laser, X-rays, EUV, or the like, but also exposure by writing by particle rays such as electron beams and ion beams.

Furthermore, in the present specification, “(meth)acrylate” represents both or any one of acrylate and methacrylate, and “(meth)acryl” represents both or any one of acryl and methacryl.

Moreover, in the present specification, a “monomer” has the same definition as a “monomeric substance”. The monomer in the present specification is distinguished from an oligomer and a polymer, and refers to a compound having a weight-average molecular weight of 2,000 or less unless otherwise specified. In the present specification, a polymerizable compound refers to a compound having a polymerizable functional group, and may be either a monomer or a polymer. The polymerizable functional group refers to a group that is involved in a polymerization reaction.

Furthermore, the expression of “preparation” in the present specification is meant to encompass providing predetermined materials by purchase or the like as well as providing by synthesis or combination of specific materials.

In addition, in the present specification, a numerical value range expressed using “to” means a range that includes the preceding and succeeding numerical values of “to” as the lower limit value and the upper limit value, respectively.

[Protective Film Forming Composition]

The protective film forming composition of the present invention contains a resin, a basic compound, a solvent, and an antioxidant.

The protective film forming composition of the present invention is a protective film forming composition capable of forming a pattern having excellent depth of focus and exposure latitude even after being stored for a predetermined period of time (hereinafter also referred to as “the effects of the present invention”).

Details of the reason are not clear, but the present inventors presume as follows.

As a chemically amplified resist, there are a positive tone chemically amplified resist and a negative tone chemically amplified resist, and generally, for both of the resists, a composition including a photoacid generator and a resin having a change in polarity by the action of an acid is used. By exposing the composition, an acid generated by a photoacid generator included in the exposed area reacts with a resin, and thus, the polarity of the resin is changed. As a result, the exposed composition is developed with a developer including an alkali developer or an organic solvent to obtain a positive tone pattern or a negative tone pattern.

In these chemically amplified resists, the polarity of the resin is changed by the acid generated by exposure, and thus, a pattern is obtained. Accordingly, in order to obtain excellent DOF and EL, it is necessary to control the diffusion distance of the acid. Accordingly, by neutralizing an acid excessively generated on a surface layer of the resist film by exposure with a basic compound which has been added to the protective film, deterioration of the performance of DOF and EL can be suppressed.

By the motion of the basic compound in the protective film into the unexposed area of the resist film during post-exposure baking (PEB), the diffusion of an acid generated in the exposed area into the unexposed area of the acid generated is suppressed, and as a result, this is presumed to be caused by an increase in the contrast of the acid diffusion in the exposed area and the unexposed area.

According to the investigation of the present inventors, it has been found that the basic compound is chemically changed in the protective film forming composition after passage of a predetermined period from the production of the composition, and thus, the above-mentioned neutralization function is lost in some cases. The passage of a predetermined period from the production of the composition specifically means, for example, storage for a predetermined period from the production of the composition to use.

As a result of further investigations conducted by the present inventors, it has been found that such a chemical change of the basic compound is caused by peroxides included in the protective film forming composition.

The protective film forming composition of the present invention contains a resin, a basic compound, a solvent, and an antioxidant. In the present invention, it is presumed that desired effects are obtained by preventing the basic compound from being chemically changed by the peroxides included in protective film forming composition, using the antioxidant included in the protective film forming composition. Hereinafter, the respective components of the protective film forming composition of the present invention will be described in detail.

[Resin]

The protective film forming composition of the present invention contains a resin. The resin has, for example, actions as exemplified below in a protective film formed on a resist film using the protective film forming composition. First, the resin has an action to minimize or interfere with the movement of a resist film component into an immersion liquid in the liquid immersion exposure. Incidentally, the resin has another action to prevent defects due to liquid residues of an immersion liquid during scanning exposure with a liquid immersion exposure apparatus at the interface between the protective film and the immersion liquid. As the resin, known resins can be used, and for example, the resins described in paragraphs 0016 to 0165 of JP2014-56194A, the contents of which are incorporated herein by reference, can be used.

The resin preferably contains a resin XA and a resin XB. Here, the resin XB is a resin containing fluorine atoms, and the resin XA is a resin not containing fluorine atoms, or in a case where the resin XA contains fluorine atoms, the resin XA is a resin having a lower content of fluorine atoms than the content of fluorine atoms in the resin XB, based on a mass.

It is presumed that by incorporating the resin XA and the resin XB, whose contents of fluorine atoms are different from each other, into the resin, the resin XB having a higher content of fluorine atoms is easily unevenly distributed in a surface of the protective film, and the hydrophobicity of the surface of the protective film easily increases. Accordingly, the protective film has a more excellent receding contact angle for water. Thus, it is possible to reduce generation of defects due to liquid residues of the immersion liquid during scanning exposure. Further, it is presumed that volatilization of a basic compound which will be described later from the protective film is suppressed and the basic compound efficiently moves into the unexposed area of the resist film, and thus, a resist film formed by lamination of the protective film of the present invention has excellent EL and DOF.

Hereinafter, suitable aspects of the resin XA and the resin XB containing fluorine atoms will be described in detail.

<Resin XA>

It is preferable that the resin XA is transparent to an exposure light source used since light reaches the resist film through the protective film upon exposure. In a case where the resin XA is used for ArF liquid immersion exposure, it is preferable that the resin does not substantially have an aromatic group in terms of transparency to ArF light.

(Content of Fluorine Atoms in Resin XA)

The content of fluorine atoms in the resin XA is preferably 0% to 5% by mass, more preferably 0% to 2.5% by mass, and still more preferably 0% by mass. In a case where the content of fluorine atoms in the resin XA is within the range, a hydrophobic film due to the resin XB having a higher content of fluorine atoms on the surface of the protective film is easily formed, and therefore, the protective film forming composition has more excellent effects of the present invention.

Furthermore, the resin XA is preferably a resin having a CH₃ partial structure in the side chain moiety.

Here, the CH₃ partial structure (hereinafter also simply referred to as a “side chain CH₃ partial structure”) contained in the side chain moiety in the resin XA includes a CH₃ partial structure contained in an ethyl group, a propyl group, or the like.

On the other hand, a methyl group bonded directly to the main chain of the resin XA (for example, an α-methyl group in the repeating unit having a methacrylic acid structure) is not included in the CH₃ partial structure in the present invention.

More specifically, in a case where the resin XA contains a repeating unit derived from a monomer having a polymerizable moiety with a carbon-carbon double bond, such as a repeating unit represented by Formula (M), and in addition, R¹¹ to R¹⁴ are each CH₃ “itself”, such the CH₃ is not included in the CH₃ partial structure contained in the side chain moiety in the present invention.

On the other hand, a CH₃ partial structure which is present via a certain atom from a C—C main chain corresponds to the CH₃ partial structure in the present invention. For example, in a case where R¹¹ is an ethyl group (CH₂CH₃), the resin XA has “one” CH₃ partial structure in the present invention.

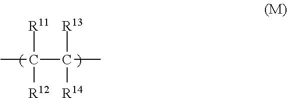

In Formula (M), R¹¹ to R¹⁴ each independently represent a side chain moiety. Examples of R¹¹ to R¹⁴ include a hydrogen atom and a monovalent organic group.

Examples of the monovalent organic group include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and these groups may further have a substituent.

It is preferable that the resin XA is a resin having a repeating unit having the CH₃ partial structure in a side chain moiety thereof. In a view that the protective film forming composition has the more excellent effects of the present invention, it is more preferable that the resin XA has at least one repeating unit (x) selected from the group consisting of a repeating unit represented by Formula (II) and a repeating unit represented by Formula (III). Among those, in a case where KrF, EUV, or electron beams (EB) are used as an exposure light source, it is still more preferable that the resin XA has the repeating unit represented by Formula (III).

Hereinafter, the repeating unit represented by Formula (II) will be described in detail.

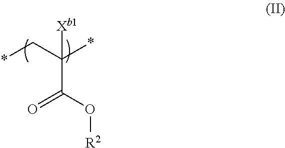

In Formula (II), X^{b1} represents a hydrogen atom, an alkyl group, a cyano group, or a halogen atom, and R² represents an organic group having one or more CH₃ partial structures, which is stable against an acid. Here, more specifically, the organic group which is stable against an acid is preferably an organic group not having a group that decomposes by the action of an acid to generate an alkali-soluble group.

Furthermore, the group that decomposes by the action of an acid to generate an alkali-soluble group is a group that may be sometimes contained in a resin included in an actinic ray-sensitive or radiation-sensitive resin composition which will be described later.

In addition, in Formula (II), * represents a binding position.

The alkyl group of X^{b}t is preferably an alkyl group having 1 to 4 carbon atoms. Examples of the alkyl group having 1 to 4 carbon atoms include a methyl group, an ethyl group, a propyl group, a hydroxymethyl group, and a trifluoromethyl group. Among those, the methyl group is preferable.

X^{b1} is preferably a hydrogen atom or a methyl group.

Examples of R² include an alkyl group, a cycloalkyl group, an alkenyl group, a cycloalkenyl group, an aryl group, and an aralkyl group, each of which has one or more CH₃ partial structures. The cycloalkyl group, the alkenyl group, the cycloalkenyl group, the aryl group, and the aralkyl group may further have an alkyl group as a substituent.

R² is preferably an alkyl group or an alkyl-substituted cycloalkyl group, which has one or more CH₃ partial structures.

The number of the CH₃ partial structures contained in the organic group which has one or more CH₃ partial structures and is stable against an acid is preferably 2 to 10, and more preferably 3 to 8.

The alkyl group having one or more CH₃ partial structures in R² is preferably a branched alkyl group having 3 to 20 carbon atoms. Preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. Among those, the isobutyl group, the t-butyl group, the 2-methyl-3-butyl group, the 2-methyl-3-pentyl group, the 3-methyl-4-hexyl group, the 3,5-dimethyl-4-pentyl group, the 2,4,4-trimethylpentyl group, the 2-ethylhexyl group, the 2,6-dimethylheptyl group, the 1,5-dimethyl-3-heptyl group, or the 2,3,5,7-tetramethyl-4-heptyl group is preferable.

The cycloalkyl group having one or more CH₃ partial structures in R² may be monocyclic or polycyclic. Specific examples thereof include groups having a monocyclo, bicyclo, tricyclo, or tetracyclo structure having 5 or more carbon atoms. Above all, the number of carbon atoms is preferably 6 to 30, and more preferably 7 to 25.

As the cycloalkyl group, for example, an adamantyl group, a noradamantyl group, a decalin residue, a tricyclodecanyl group, a tetracyclododecanyl group, a norbomyl group, a cedrol group, a cyclopentyl group, a cyclohexyl group, a cycloheptyl group, a cyclooctyl group, a cyclodecanyl group, or a cyclododecanyl group is preferable. Among those, the adamantyl group, the norbornyl group, the cyclohexyl group, the cyclopentyl group, the tetracyclododecanyl group, and the tricyclodecanyl group are more preferable, and the norbomyl group, the cyclopentyl group, and the cyclohexyl group is still more preferable.

As R², a cycloalkyl group having one or more CH₃ partial structures is preferable, a polycyclic cycloalkyl group having one or more CH₃ partial structures is more preferable, a polycyclic cycloalkyl group having two or more CH₃ partial structures is still more preferable, and a polycyclic cycloalkyl group having three or more CH₃ partial structures is particularly preferable. Among those, a polycyclic cycloalkyl group substituted with three or more alkyl groups is the most preferable.

As the alkenyl group having one or more CH₃ partial structures in R², a linear or branched alkenyl group having 1 to 20 carbon atoms is preferable, and a branched alkenyl group is more preferable.

The aryl group having one or more CH₃ partial structures in R² is preferably an aryl group having 6 to 20 carbon atoms, and examples thereof include a phenyl group and a naphthyl group, with the phenyl group being more preferable.

The aralkyl group having one or more CH₃ partial structures in R² is preferably an aralkyl group having 7 to 12 carbon atoms, and examples thereof include a benzyl group, a phenethyl group, and a naphthylmethyl group.

Examples of the hydrocarbon group having two or more CH₃ partial structures in R² include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t-butylcyclohexyl group, and an isobornyl group. Among those, the isobutyl group, the t-butyl group, the 2-methyl-3-butyl group, the 2,3-dimethyl-2-butyl group, the 2-methyl-3-pentyl group, the 3-methyl-4-hexyl group, the 3,5-dimethyl-4-pentyl group, the 2,4,4-trimethylpentyl group, the 2-ethylhexyl group, the 2,6-dimethylheptyl group, the 1,5-dimethyl-3-heptyl group, the 2,3,5,7-tetramethyl-4-heptyl group, the 3,5-dimethylcyclohexyl group, the 3,5-di-tert-butylcyclohexyl group, the 4-isopropylcyclohexyl group, the 4-t-butylcyclohexyl group, and the isobornyl group are preferable.

Specific preferred examples of the repeating unit represented by Formula (II) are shown below, but the present invention is not limited thereto.

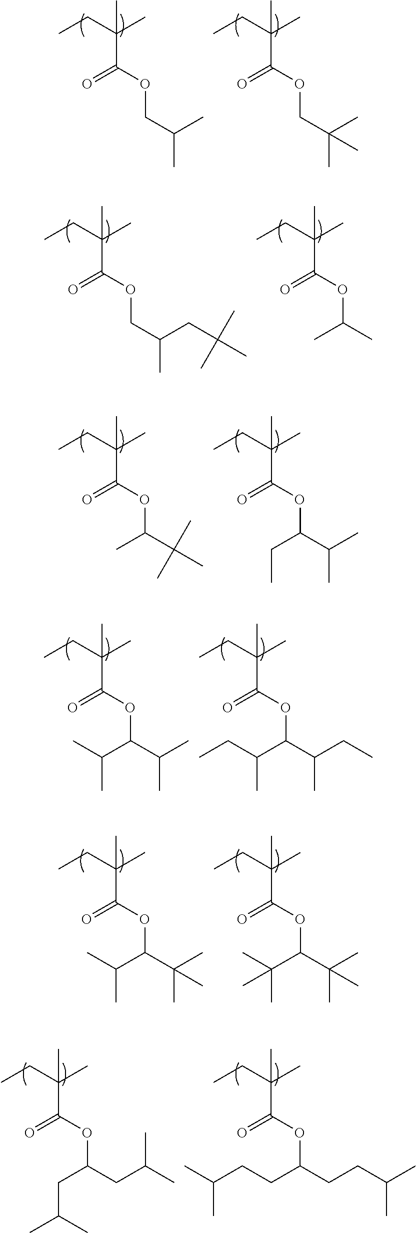

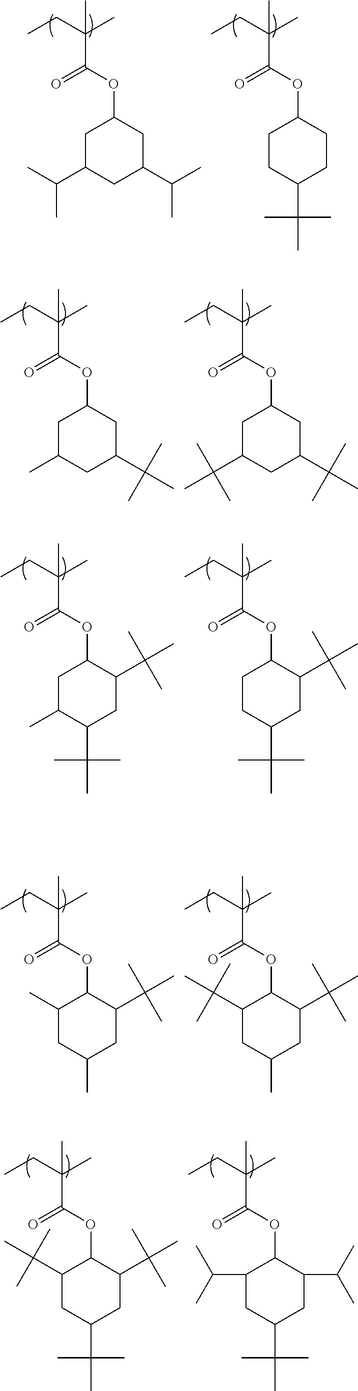

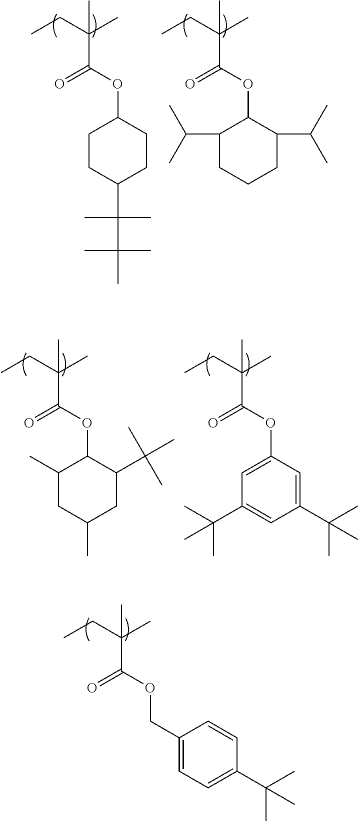

The repeating unit represented by Formula (II) is preferably a repeating unit which is stable against an acid (non-acid-decomposable), and specifically, it is preferably a repeating unit not having the above-mentioned group that decomposes by the action of an acid to generate an alkali-soluble group.

Hereinafter, the repeating unit represented by Formula (III) will be described in detail.

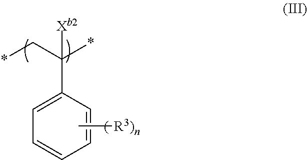

In Formula (III), X^{b2} represents a hydrogen atom, an alkyl group, a cyano group, or a halogen atom, among which the hydrogen atom is preferable. As the alkyl group, an alkyl group having 1 to 4 carbon atoms is preferable, and examples thereof include a methyl group, an ethyl group, a propyl group, a hydroxymethyl group, and a trifluoromethyl group.

Furthermore, in Formula (III), * represents a binding position.

In Formula (III), R³ represents an organic group which has one or more CH₃ partial structures and is stable against an acid. The number of the CH₃ partial structures contained in the organic group which has one or more CH₃ partial structures and is stable against an acid as R³ is preferably 1 to 10, more preferably 1 to 8, and still more preferably 1 to 4.

R³ may be an alkyl group having one or more CH₃ partial structures, among which a branched alkyl group having 3 to 20 carbon atoms, which has one or more CH₃ partial structures, is preferable.

Examples of the branched alkyl group having 3 to 20 carbon atoms include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. Among those, the isobutyl group, the t-butyl group, the 2-methyl-3-butyl group, the 2-methyl-3-pentyl group, the 3-methyl-4-hexyl group, the 3,5-dimethyl-4-pentyl group, the 2,4,4-trimethylpentyl group, the 2-ethylhexyl group, the 2,6-dimethylheptyl group, the 1,5-dimethyl-3-heptyl group, and the 2,3,5,7-tetramethyl-4-heptyl group is preferable.

R³ may be an alkyl group having two or more CH₃ partial structures, and examples thereof include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. Among those, a branched alkyl group having 5 to 20 carbon atoms is preferable, and examples thereof include an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 1,5-dimethyl-3-heptyl group, a 2,3,5,7-tetramethyl-4-heptyl group, and a 2,6-dimethylheptyl group.

Furthermore, since R³ is an organic group which is stable against an acid, more specifically, it is preferably an organic group not having the above-mentioned group that decomposes by the action of an acid to generate an alkali-soluble group.

In Formula (III), n represents an integer of 1 to 5, preferably an integer of 1 to 3, and more preferably 1 or 2.

Specific preferred examples of the repeating unit represented by Formula (III) are shown below, but the present invention is not limited thereto.

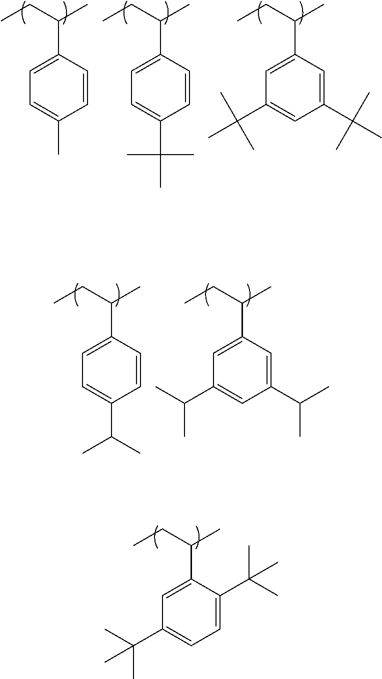

The repeating unit represented by Formula (III) is preferably a repeating unit which is stable against an acid (non-acid-decomposable), and specifically, it is preferably a repeating unit not having a group that decomposes by the action of an acid to generate an alkali-soluble polar group.

In a case where the resin XA includes a CH₃ partial structure in the side chain moiety and includes neither fluorine atoms nor a silicon atom, the content of at least one repeating unit (x) selected from the group consisting of the repeating unit represented by Formula (II) and the repeating unit represented by Formula (III) is preferably 90% by mole or more, and more preferably 95% by mole or more, with respect to all the repeating units of the resin XA. The content is usually 100% by mole or less with respect to all the repeating units of the resin XA.

By incorporation of at least one repeating unit (x) selected from the group consisting of the repeating unit represented by Formula (II) and the repeating unit represented by Formula (III) in a proportion of 90% by mole or more with respect to all the repeating units of the resin XA, it is easy that the surface free energy of the resin XA increases, and the surface free energy of the resin XB containing fluorine atoms which will be described later relatively decreases. Thus, the resin XB containing fluorine atoms which will be described later is likely to be unevenly distributed on the surface of a protective film formed with the protective film forming composition of the present invention, and the receding contact angle of the surface of the protective film increases. As a result, a resist film having the protective film formed with the protective film forming composition of the present invention has further reduced generation of defects due to liquid residues of an immersion liquid during scanning exposure.

Furthermore, the resin XA is preferably a resin containing a repeating unit derived from a monomer containing fluorine atoms and/or silicon atoms, and more preferably a water-insoluble resin containing a repeating unit derived from a monomer containing fluorine atoms and/or silicon atoms, within a scope in which the resin XA exhibits the effects of the present invention. By incorporation of the repeating unit derived from a monomer containing fluorine atoms and/or silicon atoms, good solubility in an organic solvent developer is obtained and the effects of the present invention are sufficiently obtained.

The resin XA may have fluorine atoms and/or silicon atoms in the main chain or a side chain of the resin XA.

The resin XA is preferably a resin having an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have another substituent.

The cycloalkyl group having a fluorine atom is a monocyclic or polycyclic cycloalkyl group in which at least one hydrogen atom is substituted with a fluorine atom, and may further have another substituent.

Examples of the aryl group having a fluorine atom include an aryl group in which at least one hydrogen atom is substituted with a fluorine atom, such as a phenyl group and a naphthyl group, and the aryl group may further have another substituent.

Specific examples of the alkyl group having a fluorine atom, the cycloalkyl group having a fluorine atom, and the aryl group having a fluorine atom are shown below, but the present invention is not limited thereto.

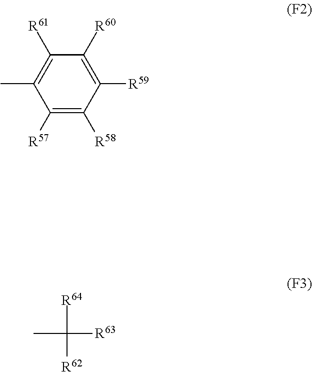

In Formulae (F2) and (F3), R⁵⁷ to R⁶⁴ each independently represent a hydrogen atom, a fluorine atom, or an alkyl group, provided that at least one of R⁵⁷, . . . , or R⁶¹ or of R⁶², . . . , or R⁶⁴ is a fluorine atom or an alkyl group (preferably having 1 to 4 carbon atoms) in which at least one hydrogen atom is substituted for by a fluorine atom. It is preferable that all of R⁵⁷ to R⁶¹ are a fluorine atom. R⁶² and R⁶³ are each preferably an alkyl group (preferably having 1 to 4 carbon atoms) in which at least one hydrogen atom is substituted with a fluorine atom, and more preferably a perfluoroalkyl group having 1 to 4 carbon atoms. R⁶² and R⁶³ may be linked to each other to form a ring.

Specific examples of the group represented by Formula (F2) include a p-fluorophenyl group, a pentafluorophenyl group, and a 3,5-di(trifluoromethyl)phenyl group.

Specific examples of the group represented by Formula (F3) include a trifluoroethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Among those, the hexafluoroisopropyl group, the heptafluoroisopropyl group, the hexafluoro(2-methyl)isopropyl group, the octafluoroisobutyl group, a nonafluoro-t-butyl group, and the perfluoroisopentyl group are preferable, and the hexafluoroisopropyl group and the heptafluoroisopropyl group are more preferable.

The resin XA is preferably a resin having an alkylsilyl structure (preferably a trialkylsilyl group) or a cyclic siloxane structure as a partial structure having a silicon atom.

Specific examples of the alkylsilyl structure or the cyclic siloxane structure include groups represented by Formulae (CS-1) to (CS-3).

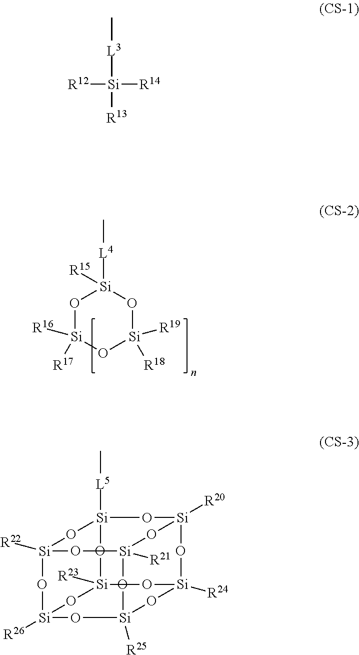

In Formulae (CS-1) to (CS-3), R¹² to R²⁶ each independently represent a linear or branched alkyl group (preferably having 1 to 20 carbon atoms) or a cycloalkyl group (preferably having 3 to 20 carbon atoms).

L³ to L⁵ each represent a single bond or a divalent linking group. Examples of the divalent linking group include any one or a combination of two or more groups selected from the group consisting of an alkylene group, a phenyl group, an ether group, a thioether group, a carbonyl group, an ester group, an amido group, a urethane group, and a urea group.

In Formula (CS-2), n represents an integer of 1 to 5.

As the resin XA, a resin having at least one selected from the group consisting of repeating units represented by Formulae (C-I) to (C-V) is preferable.

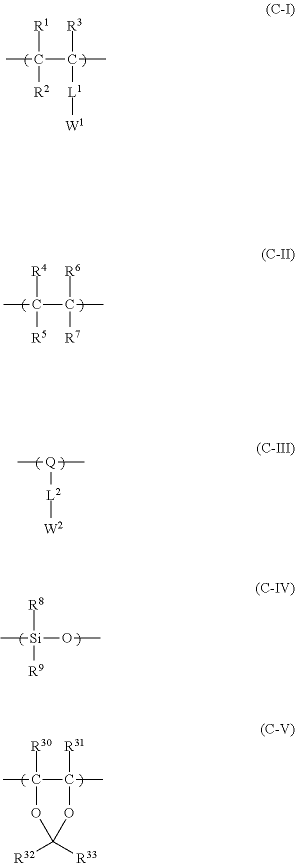

In Formulae (C-I) to (C-V), R¹ to R³ each independently represent a hydrogen atom, a fluorine atom, a linear or branched alkyl group having 1 to 4 carbon atoms, or a linear or branched fluorinated alkyl group having 1 to 4 carbon atoms.

In Formulae (C-I) to (C-V), R⁴ to R⁷ each independently represent a hydrogen atom, a fluorine atom, a linear or branched alkyl group having 1 to 4 carbon atoms, or a linear or branched fluorinated alkyl group having 1 to 4 carbon atoms.

In addition, at least one of R⁴, . . . , or R⁷ represents a fluorine atom. In addition, R⁴ and R⁵, or R⁶ and R⁷ may form a ring.

W¹ and W² each represent an organic group having at least one of a fluorine atom or a silicon atom.

R⁸ represents a hydrogen atom or a linear or branched alkyl group having 1 to 4 carbon atoms.

R⁹ represents a linear or branched alkyl group having 1 to 4 carbon atoms or a linear or branched fluorinated alkyl group having 1 to 4 carbon atoms.

L¹ and L² each represent a single bond or a divalent linking group, and aspects of the divalent linking groups exemplified are the same as in L³ to L⁵.

Q represents a monocyclic or polycyclic aliphatic group. That is, it represents an atomic group containing two carbon atoms (C—C) bonded to each other for forming an alicyclic structure.

R³⁰ and R³¹ each independently represent a hydrogen atom or a fluorine atom.

R³² and R³³ each independently represent an alkyl group, a cycloalkyl group, a fluorinated alkyl group, or a fluorinated cycloalkyl group.

It is to be noted that at least one selected from the group consisting of R³⁰, R³¹, R³², and R³³ has at least one fluorine atom.

The resin XA preferably has a repeating unit represented by Formula (C-I), and more preferably has at least one selected from the group consisting of repeating units represented by Formulae (C-Ia) to (C-Id).

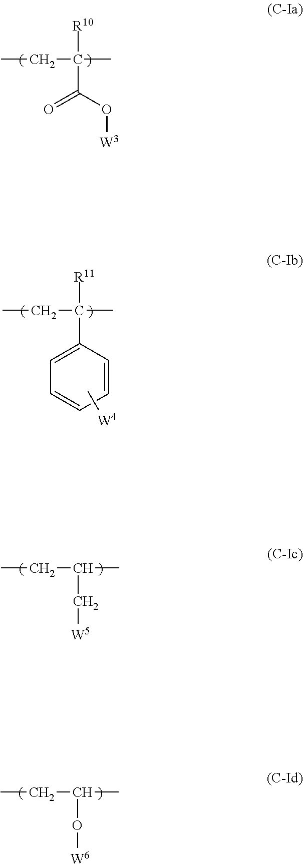

In Formulae (C-Ia) to (C-Id), R¹⁰ and R¹¹ each represent a hydrogen atom, a fluorine atom, a linear or branched alkyl group having 1 to 4 carbon atoms, or a linear or branched fluorinated alkyl group having 1 to 4 carbon atoms.

W³ to W⁶ each represent an organic group having one or more of at least one of a fluorine atom or a silicon atom.

In a case where W³ to W⁶ are each an organic group having a fluorine atom, they are each preferably a fluorinated, linear or branched alkyl group or cycloalkyl group having 1 to 20 carbon atoms, or a linear, branched, or cyclic fluorinated alkyl ether group having 1 to 20 carbon atoms.

Examples of the fluorinated alkyl group of each of W³ to W⁶ include a trifluoroethyl group, a pentafluoropropyl group, a hexafluoroisopropyl group, a hexafluoro(2-methyl)isopropyl group, a heptafluorobutyl group, a heptafluoroisopropyl group, an octafluoroisobutyl group, a nonafluorohexyl group, a nonafluoro-t-butyl group, a perfluoroisopentyl group, a perfluorooctyl group, and a perfluoro(trimethyl)hexyl group.

In a case where W³ to W⁶ are each an organic group having a silicon atom, an alkylsilyl structure or a cyclic siloxane structure is preferable. Specific examples thereof include groups represented by Formulae (CS-1) to (CS-3).

Specific examples of the repeating unit represented by Formula (C-I) are shown below, but the present invention is not limited thereto. X represents a hydrogen atom, —CH₃, —F, or —CF₃.

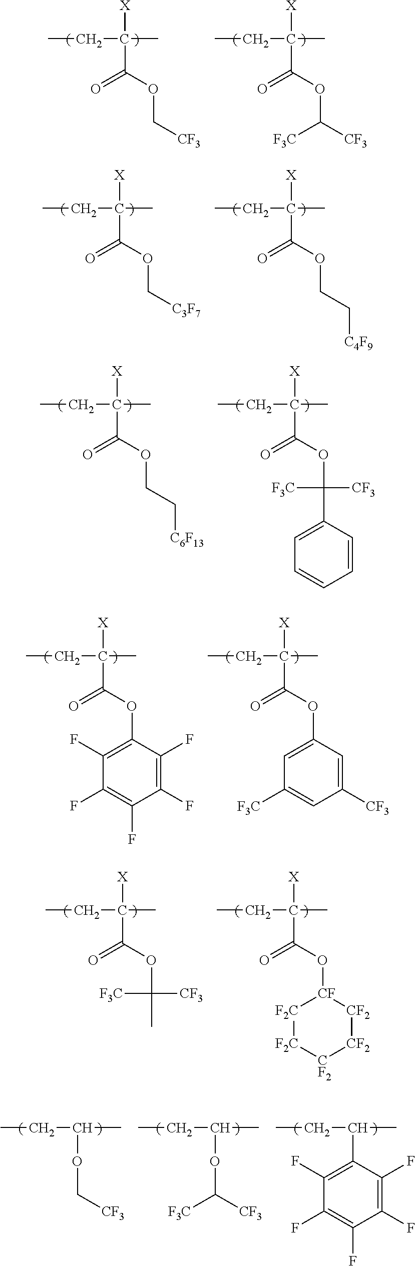

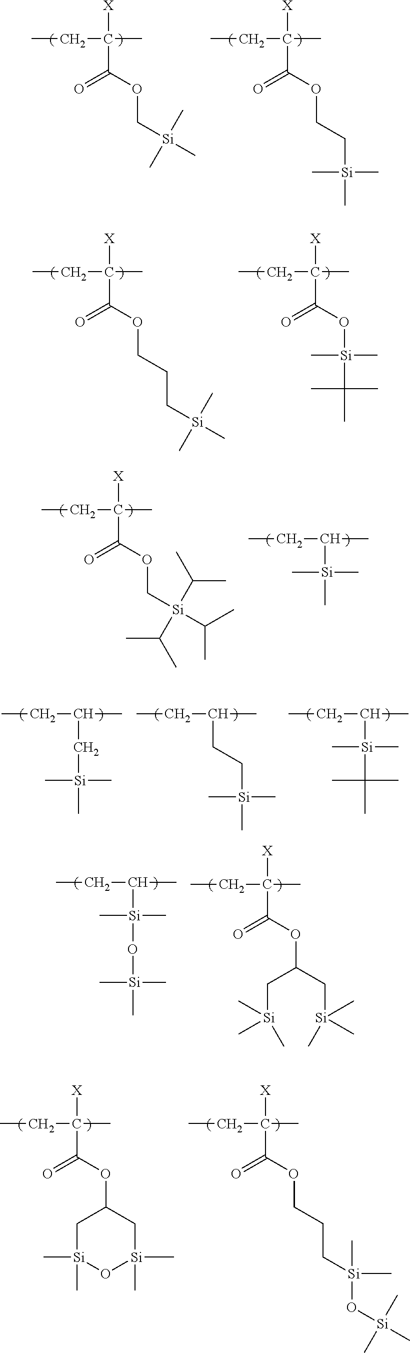

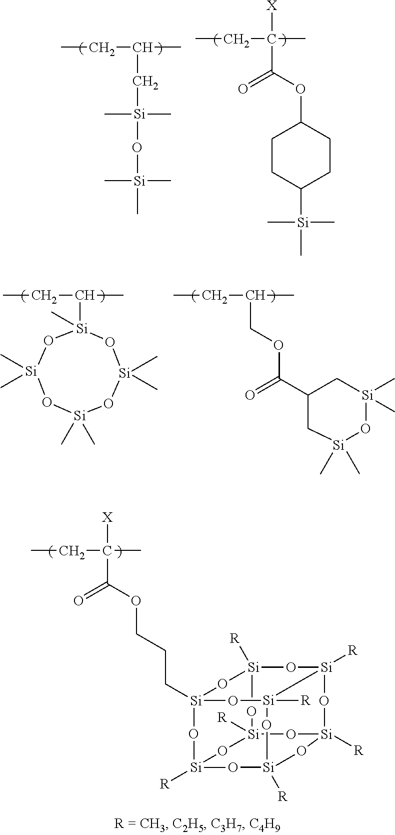

In order to adjust the solubility in an organic solvent developer, the resin XA may have a repeating unit represented by Formula (Ia).

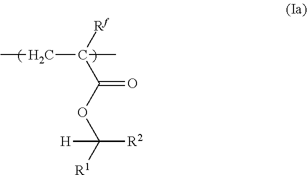

In Formula (Ia), R^{f} represents a fluorine atom or an alkyl group in which at least one hydrogen atom is substituted with a fluorine atom, and is preferably one having 1 to 3 carbon atoms, and more preferably a trifluoromethyl group.

In Formula (Ia), R¹ represents an alkyl group, and is preferably a linear or branched alkyl group having 3 to 10 carbon atoms, and more preferably a branched alkyl group having 3 to 10 carbon atoms.

In Formula (Ia), R² represents a hydrogen atom or an alkyl group, and is preferably a linear or branched alkyl group having 1 to 10 carbon atoms, and more preferably a linear or branched alkyl group having 3 to 10 carbon atoms.

Specific examples of the repeating unit represented by Formula (Ia) are shown below, but the present invention is not limited thereto. Further, in the following formulae, X represents a fluorine atom or CF₃.

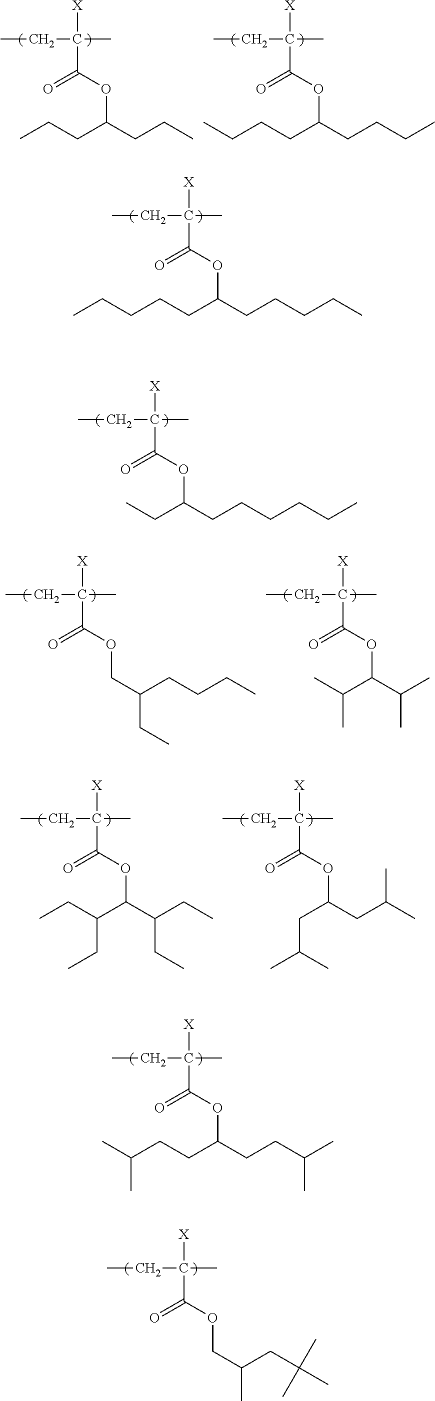

The resin XA may further have a repeating unit represented by Formula (IIIb).

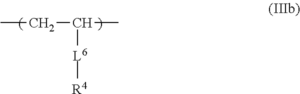

In Formula (IIIb), R⁴ represents an alkyl group, a cycloalkyl group, an alkenyl group, a cycloalkenyl group, a trialkylsilyl group, or a group having a cyclic siloxane structure.

L⁶ represents a single bond or a divalent linking group.

In Formula (IIIb), the alkyl group of R⁴ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The trialkylsilyl group is preferably a trialkylsilyl group having 3 to 20 carbon atoms.

The group having a cyclic siloxane structure is preferably a group having a cyclic siloxane structure having 3 to 20 carbon atoms.

The divalent linking group of L⁶ is preferably an alkylene group (preferably having 1 to 5 carbon atoms) or an oxy group.

The resin XA may have the same group as a lactone group, an ester group, an acid anhydride, and/or the same group as the above-mentioned group that decomposes by the action of an acid to generate an alkali-soluble group. The resin XA may further have a repeating unit represented by Formula (VIII).

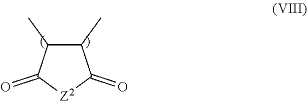

The resin XA is preferably at least one resin selected from the group consisting of the following (X-1) to (X-8).

(X-1) A resin having a repeating unit (a) having a fluoroalkyl group (preferably having 1 to 4 carbon atoms), and more preferably a resin having only the repeating unit (a).

(X-2) A resin having a repeating unit (b) having a trialkylsilyl group or a cyclic siloxane structure, and more preferably a resin having only the repeating unit (b).

(X-3) A resin having the following repeating unit (a) and the following repeating unit (c).

Repeating unit (a): A repeating unit having a fluoroalkyl group (preferably having 1 to 4 carbon atoms).

Repeating unit (c): A repeating unit having a branched alkyl group (preferably having 4 to 20 carbon atoms), a cycloalkyl group (preferably having 4 to 20 carbon atoms), a branched alkenyl group (preferably having 4 to 20 carbon atoms), a cycloalkenyl group (preferably having 4 to 20 carbon atoms), or an aryl group (preferably having 4 to 20 carbon atoms).

A copolymerization resin of the repeating unit (a) and the repeating unit (c), which is more preferable.

(X-4) A resin having the following repeating unit (b) and the following repeating unit (c).

Repeating unit (b): A repeating unit having a trialkylsilyl group or a cyclic siloxane structure.

Repeating unit (c): A repeating unit having a branched alkyl group (preferably having 4 to 20 carbon atoms), a cycloalkyl group (preferably having 4 to 20 carbon atoms), a branched alkenyl group (preferably having 4 to 20 carbon atoms), a cycloalkenyl group (preferably having 4 to 20 carbon atoms), or an aryl group (preferably having 4 to 20 carbon atoms).

A copolymerization resin of the repeating unit (b) and the repeating unit (c), which is more preferable.

(X-5) A resin having the repeating unit (a) having a fluoroalkyl group (preferably having 1 to 4 carbon atoms) and the repeating unit (b) having a trialkylsilyl group or a cyclic siloxane structure, and more preferably a copolymerization resin of the repeating unit (a) and the repeating unit (b).

(X-6) A resin having the repeating unit (a) having a fluoroalkyl group (preferably having 1 to 4 carbon atoms), the repeating unit (b) having a trialkylsilyl group or a cyclic siloxane structure, and the repeating unit (c) having a branched alkyl group (preferably having 4 to 20 carbon atoms), a cycloalkyl group (preferably having 4 to 20 carbon atoms), a branched alkenyl group (preferably having 4 to 20 carbon atoms), a cycloalkenyl group (preferably having 4 to 20 carbon atoms), or an aryl group (preferably having 4 to 20 carbon atoms), and more preferably a copolymerization resin of the repeating unit (a), the repeating unit (b), and the repeating unit (c).

Furthermore, as the repeating unit (c) having a branched alkyl group, a cycloalkyl group, a branched alkenyl group, a cycloalkenyl group, or an aryl group in the resins (X-3), (X-4), and (X-6), an appropriate functional group can be introduced in consideration of hydrophilicity, interactions, or the like into consideration.

(X-7) A resin having a repeating unit (preferably a repeating unit having an alkali-soluble group with a pKa of 4 or more) further having an alkali-soluble group (d) in the repeating unit constituting each of (X-1) to (X-6).

(X-8) A resin having only a repeating unit having an alkali-soluble group (d) having a fluoroalcohol group.

Moreover, in the resins (X-3), (X-4), (X-6), and (X-7), the content of the repeating unit (a) having a fluoroalkyl group and/or the repeating unit (b) having a trialkylsilyl group or a cyclic siloxane structure is preferably 1% to 99% by mole, and more preferably 1% to 50% by mole, with respect to all the repeating units of the resin XA.

Furthermore, by incorporation of the alkali-soluble group (d) into the resin (X-7), the peeling ease upon the use of an organic solvent developer as well as the peeling ease upon the use of other peeling solutions, for example, the use of an alkaline aqueous solution as a peeling solution are improved.

The resin XA is preferably solid at normal temperature (25° C.). Incidentally, the glass transition temperature (T_{g}) is preferably 50° C. to 200° C., and more preferably 80° C. to 160° C. In addition, in the present specification, the expression of being solid at 25° C. means having a melting point of 25° C. or higher.

The glass transition temperature (T_{g}) represents a glass transition temperature that is measured as follows, by differential scanning calorimetry.

10 mg of the resin XA is weighed and set in an aluminum pan. Thereafter, the resin XA is heated from room temperature to a temperature lower than a 1% decomposition temperature by 5° C. at a heating rate of 10° C./min, then rapidly cooled, and warmed again at 10° C./min to obtain a DSC curve. The temperature at which the obtained DSC curve is bent is defined as a glass transition temperature. Further, the 1% decomposition temperature (° C.) is a temperature with a decrease by 1% weight at a time of measurement of a thermogravimetric value in a nitrogen atmosphere using a simultaneous differential thermogravimetric measurement device (TG/DTA: ThermoGravimetry/differential thermal analysis) (1% weight lowering temperature) (° C.).

It is preferable that the resin XA is insoluble in an immersion liquid (preferably water), and soluble in an organic solvent developer (preferably a developer including an ester-based solvent). In a case where the pattern forming method using the protective film forming composition of the present invention further includes a step of performing development using an alkali developer, it is preferable that the resin XA is also soluble in the alkali developer from the viewpoint that it is possible to perform development and peeling using the alkali developer.

In a case where the resin XA has silicon atoms, the content of the silicon atoms is preferably 2% to 50% by mass, and more preferably 2% to 30% by mass, with respect to the total mass of the resin XA. Further, the content of the repeating units containing silicon atoms is preferably 10% to 100% by mass, and more preferably 20% to 100% by mass in the resin XA.

By setting the content of the silicon atoms and the content of the repeating unit including the silicon atoms to the ranges, it is possible to improve all of insolubility in an immersion liquid (preferably water) of the protective film, peeling ease of a protective film upon the use of an organic solvent developer, and incompatibility of the protective film with a resist film.

By setting the content of the fluorine atoms and the content of the repeating unit including the fluorine atoms to the ranges, it is possible to improve all of insolubility in an immersion liquid (preferably water) of the protective film, peeling ease of a protective film upon the use of an organic solvent developer, and incompatibility of the protective film with a resist film.

The weight-average molecular weight (Mw) of the resin XA is preferably 1,000 to 100,000, more preferably 1,000 to 50,000, still more preferably 2,000 to 15,000, and particularly preferably 3,000 to 15,000. Here, measurement of the weight-average molecular weight and the number-average molecular weight is measured using gel permeation chromatography (GPC) under the following conditions.
Column: KF-804L manufactured by Tosoh Corporation (three columns)
Developing solvent: Tetrahydrofuran (THF)
Column temperature: 40° C.
Flow rate: 1.0 mL/min
Device: HLC-8220 manufactured by Tosoh Corporation
Calibration curve: TSK Standard PSt series

In the resin XA, it is obvious that the content of impurities such as a metal is small, and the content of residual monomers is also preferably 0% to 10% by mass, more preferably 0% to 5% by mass, and still more preferably 0% to 1% by mass, with respect to the total mass of the resin XA, from the viewpoint of reduction in elution from a protective film to an immersion liquid. Further, the molecular weight distribution (Mw/Mn, also referred to as “dispersity”) of the resin XA is preferably in a range of 1 to 5, more preferably in a range of 1 to 3, and still more preferably in a range of 1 to 1.5. Further, the molecular weight distribution is a value that can be determined by the above-mentioned GPC method.

Various commercially available products may be used as the resin XA, or the resin XA may be synthesized by a conventional method (for example, radical polymerization). Examples of the general synthesis method include a batch polymerization method of dissolving monomer species and an initiator in a solvent and heating the solution, thereby carrying out the polymerization, and a dropwise-addition polymerization method of adding dropwise a solution containing monomer species and an initiator to a heated solvent for 1 to 10 hours, with the dropwise-addition polymerization method being preferable. Examples of the reaction solvent include ethers such as tetrahydrofuran, 1,4-dioxane, and diisopropyl ether, ketones such as methyl ethyl ketone and methyl isobutyl ketone; ester solvents such as ethyl acetate; amide solvents such as dimethyl formamide and dimethyl acetamide; and solvents, such as propylene glycol monomethyl ether acetate, propylene glycol monomethyl ether, and cyclohexanone.

It is preferable that the polymerization reaction is carried out in an inert gas atmosphere such as nitrogen and/or argon. As the polymerization initiator, commercially available radical initiators (azo-based initiators, peroxides, or the like) are used to initiate the polymerization. As the radical initiator, an azo-based initiator is preferable, and the azo-based initiator having an ester group, a cyano group, or a carboxyl group is preferable. Preferable examples of the initiators include azobisisobutyronitrile, azobisdimethylvaleronitrile, and dimethyl 2,2′-azobis(2-methyl propionate). As desired, a chain transfer agent can also be used. The concentration of the solids in the reaction system is usually 5% to 50% by mass, preferably 20% to 50% by mass, and more preferably 30% to 50% by mass. The reaction temperature is usually 10° C. to 150° C., preferably 30° C. to 120° C., and more preferably 60° C. to 100° C.

After the completion of the reaction, the reaction solution is left to be cooled to room temperature, and purified. Examples of the purification include a liquid-liquid extraction method in which residual monomers and/or oligomer components are removed by washing with a combination of water and/or suitable solvents; a purification method in a solution state such as ultrafiltration which extracts and removes only substances having a specific molecular weight or less; a re-precipitation method in which residual monomers or the like are removed by adding a resin solution dropwise to a poor solvent to coagulate the resin in the poor solvent; and a purification method in a solid state in which filtered resin slurry is washed with a poor solvent, and known methods can be applied to the purification. For example, by bringing the resin into contact with a solvent (poor solvent), which sparingly dissolves or does not dissolve the resin, corresponding to 10 times or less the volume amount of the reaction solution (resin solution), or preferably 5 to 10 times the volume amount of the reaction solution, the resin is solidified and precipitated.

The solvent (precipitation or reprecipitation solvent) to be used during a precipitation and/or reprecipitation operation from the resin solution may be an arbitrary one so long as it is a poor solvent to the resin. Depending on the kind of the resin, a solvent that is appropriately selected from, for example, a hydrocarbon (an aliphatic hydrocarbon such as pentane, hexane, heptane, and octane; an alicyclic hydrocarbon such as cyclohexane and methylcyclohexane; and an aromatic hydrocarbon such as benzene, toluene, and xylene), a halogenated hydrocarbon (a halogenated aliphatic hydrocarbon such as methylene chloride, chloroform, and carbon tetrachloride; and a halogenated aromatic hydrocarbon such as chlorobenzene and dichlorobenzene), a nitro compound (nitromethane, nitroethane, and the like), a nitrile (acetonitrile, benzonitrile, and the like), an ether (a chain ether such as diethyl ether, diisopropyl ether, and dimethoxyethane; and a cyclic ether such as tetrahydrofuran and dioxane), a ketone (acetone, methyl ethyl ketone, diisobutyl ketone, and the like), an ester (ethyl acetate, butyl acetate, and the like), a carbonate (dimethyl carbonate, diethyl carbonate, ethylene carbonate, propylene carbonate, and the like), an alcohol (methanol, ethanol, propanol, isopropyl alcohol, butanol, and the like), a carboxylic acid (acetic acid and the like), water, and a mixed solvent containing the same can be used. Among those, the precipitation and/or reprecipitation solvent is preferably a solvent containing at least an alcohol (particularly methanol or the like) or water. In such a solvent containing at least a hydrocarbon, the ratio of the alcohol (particularly methanol or the like) to other solvents (for example, an ester such as ethyl acetate and/or an ether such as tetrahydrofuran) is approximately, for example, the former/the latter (volume ratio; 25° C.) of 10/90 to 99/1, preferably the former/the latter (volume ratio; 25° C.) of 30/70 to 98/2, and more preferably the former/the latter (volume ratio; 25° C.) of 50/50 to 97/3.

The amount of the precipitation and/or reprecipitation solvent to be used may be appropriately selected by taking into consideration efficiency and/or yield, or the like. In general, it is used in an amount of 100 to 10,000 parts by mass, preferably 200 to 2,000 parts by mass, and more preferably 300 to 1,000 parts by mass, with respect to 100 parts by mass of the resin solution.

In a case of feeding the resin solution into a precipitation and/or reprecipitation solvent (poor solvent), the nozzle pore diameter is preferably 4 mm$ or less (for example, 0.2 to 4 mm+) and the feeding rate (dropwise addition rate) of the resin solution into the poor solvent is, for example, in terms of a linear velocity, approximately 0.1 to 10 m/sec, and preferably 0.3 to 5 m/sec.

The precipitation and/or reprecipitation operation is preferably carried out under stirring. Examples of the stirring blade which can be used for the stirring include a disc turbine, a fan turbine (including a paddle), a curved vane turbine, an arrow feather turbine, a Pfaudler type, a bull margin type, an angled vane fan turbine, a propeller, a multistage type, an anchor type (or a horseshoe type), a gate type, a double ribbon type, and a screw type. It is preferable that the stirring is further carried out for 10 minutes or more, in particular, 20 minutes or more, after the completion of feeding of the resin solution. In a case where the stirring time is short, the monomer content in the resin solution may not be sufficiently reduced in some cases. Further, the mixing and stirring of the resin solution and the poor solvent may also be carried out by using a line mixer instead of the stirring blade.

Although the temperature during the precipitation and/or reprecipitation may be appropriately selected by taking into consideration efficiency and/or operability, the temperature is usually approximately 0° C. to 50° C., preferably in the vicinity of room temperature (for example, approximately 20° C. to 35° C.). The precipitation and/or reprecipitation operation may be carried out by using a commonly employed mixing vessel such as stirring tank according to a known method such as batch system and continuous system.

The precipitated and/or reprecipitated particulate resin is usually subjected to commonly employed solid-liquid separation such as filtration and/or centrifugation and then dried before using. The filtration is carried out by using a solvent-resistant filter material preferably under elevated pressure. The drying is carried out under normal pressure or reduced pressure (preferably under reduced pressure) at a temperature of approximately 30° C. to 100° C., and preferably approximately 30° C. to 50° C.

Furthermore, after the resin is once precipitated and separated, it may be redissolved in a solvent and then brought into contact with a solvent in which the resin is sparingly soluble or insoluble.

That is, the method may be a method including, after the completion of a polymerization reaction, precipitating a resin by bringing the resin solution into contact with a solvent in which the resin is sparingly soluble or insoluble (step a), separating the resin from the solution (step b), dissolving the resin in a solvent again to prepare a resin solution A (step c), then precipitating a resin by bringing the resin solution A into contact with a solvent in which the resin is sparingly soluble or insoluble and which is in a volume amount of less than 10 times (preferably a volume amount of 5 times or less) the resin solution A (step d), and separating the precipitated resin (step e).

As the solvent used in a case of the preparation of the resin solution A, the same solvent as the solvent for dissolving the monomer in a case of the polymerization reaction may be used, and the solvent may be the same as or different from each other from the solvent used in a case of the polymerization reaction.

The resin XA may be used singly or in combination of two or more kinds thereof.

The content of the resin XA in the protective film forming composition is preferably 0.5% to 10.0% by mass, more preferably 1.0% to 6.0% by mass, and still more preferably 1.5% to 5.0% by mass, with respect to the total solid content of the protective film forming composition.

<Resin XB>

In a case where the resin XB is used for ArF liquid immersion exposure in the same manner as the above-mentioned resin XA, it is preferable that the resin XB does not have an aromatic group in view of transparency to ArF light.

The resin XB is a resin containing fluorine atoms, and preferably a water-insoluble resin (hydrophobic resin).

The resin XB preferably has fluorine atoms in the main chain or a side chain of the resin XB. Further, in a case where the resin XB contains silicon atoms, it may have the silicon atoms in the main chain or a side chain of the resin XB.

The resin XB is preferably a resin having an alkyl group having a fluorine atom, a cycloalkyl group having a fluorine atom, or an aryl group having a fluorine atom as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have another substituent.

The cycloalkyl group having a fluorine atom is a monocyclic or polycyclic cycloalkyl group in which at least one hydrogen atom is substituted with a fluorine atom, and they may further have another substituent.

The aryl group having a fluorine atom is an aryl group in which at least one hydrogen atom is substituted with a fluorine atom, such as a phenyl group and a naphthyl group, and they may further have another substituent.

Specific examples of the alkyl group having a fluorine atom, the cycloalkyl group having a fluorine atom, or the aryl group having a fluorine atom include the above-mentioned group represented by Formula (F2) or Formula (F3).

Examples of the resin XB include a resin having at least one repeating unit selected from the group consisting of the above-mentioned repeating units represented by Formulae (C-I) to (C-V).

The resin XB preferably includes a CH₃ partial structure in a side chain moiety thereof as for the resin XA, and it is preferable that the resin XA includes, for example, at least one repeating unit (x) selected from the group consisting of the repeating unit represented by Formula (II) and the repeating unit represented by Formula (III).

It is preferable that the resin XB is insoluble in an immersion liquid (preferably water), and soluble in an organic developer. It is preferable that the resin XB is also soluble in the alkali developer from the viewpoint that it is possible to perform development and peeling using the alkali developer.

(Content of Fluorine Atoms in Resin XB) The content of the fluorine atoms in the resin XB is preferably 15% by mass or more, more preferably 15% to 80% by mass, still more preferably 20% to 80% by mass, and particularly preferably 25% to 80% by mass, with respect to the total mass of the resin XB. Further, the content of the repeating units including fluorine atoms is preferably 10% to 100% by mass, and more preferably 30% to 100% by mass in the resin XB.

The weight-average molecular weight of the resin XB in terms of standard polystyrene is preferably 1,000 to 100,000, more preferably 1,000 to 50,000, still more preferably 2,000 to 15,000, and particularly preferably 3,000 to 15,000. Further, a method for measuring the weight-average molecular weight of the resin XB is the same as the method for measuring the weight-average molecular weight of the resin XA.

In the resin XB, it is obvious that the content of impurities such as a metal is small, and the content of residual monomers is also preferably 0% to 10% by mass, more preferably 0% to 5% by mass, and still more preferably 0% to 1% by mass, with respect to the total mass of the resin XB, from the viewpoint of reduction in elution from a protective film to an immersion liquid. Further, the molecular weight distribution (Mw/Mn, also referred to as “dispersity”) of the resin XB is preferably in a range of 1 to 5, more preferably in a range of 1 to 3, and still more preferably in a range of 1 to 1.5.

As the resin XB, various commercially available products can also be used, and the resin XB can be synthesized in accordance with an ordinary method (for example, radical polymerization). For example, reference can be made to the above-mentioned method for synthesizing the resin XA.

The resin XB may be used singly or in combination of two or more kinds thereof.

The content of the resin XB in the protective film forming composition is preferably 20% by mass or less with respect to the total solid content of the protective film forming composition. In a case where the content of the resin XB is within the range, the diffusivity of the protective film itself is good and the protective film forming composition has more excellent effects of the present invention.

(Difference between Content of Fluorine Atoms of Resin XB and Content of Fluorine Atoms of Resin XA)

As described above, it is preferable that the protective film forming composition of the present invention uses a resin containing the resin XA and the resin XB having different contents of fluorine atoms, together with a basic compound which will be described later.

Here, the difference between the content of fluorine atoms in the resin XA and the content of fluorine atoms in the resin XB is preferably 10% by mass or more, more preferably 15% by mass or more, and still more preferably 18% by mass or more. In a case where the difference in the contents of fluorine atoms is within the range, a surface of the protective film formed with the protective film forming composition of the present invention is likely to be covered with a hydrophobic film formed with the resin XB having a higher content of fluorine atoms, and the protective film is likely to have a more excellent receding contact angle for water. By this, it is possible to further reduce generation of defects due to liquid residues of the immersion liquid during scanning exposure. Incidentally, volatilization of the basic compound which will be described later from the protective film is suppressed and the basic compound efficiently moves into the unexposed area of a resist film, and therefore a resist film formed by lamination of the protective film of the present invention has excellent EL and DOF.

Preferred examples of the resin XA and/or the resin XB are shown below.

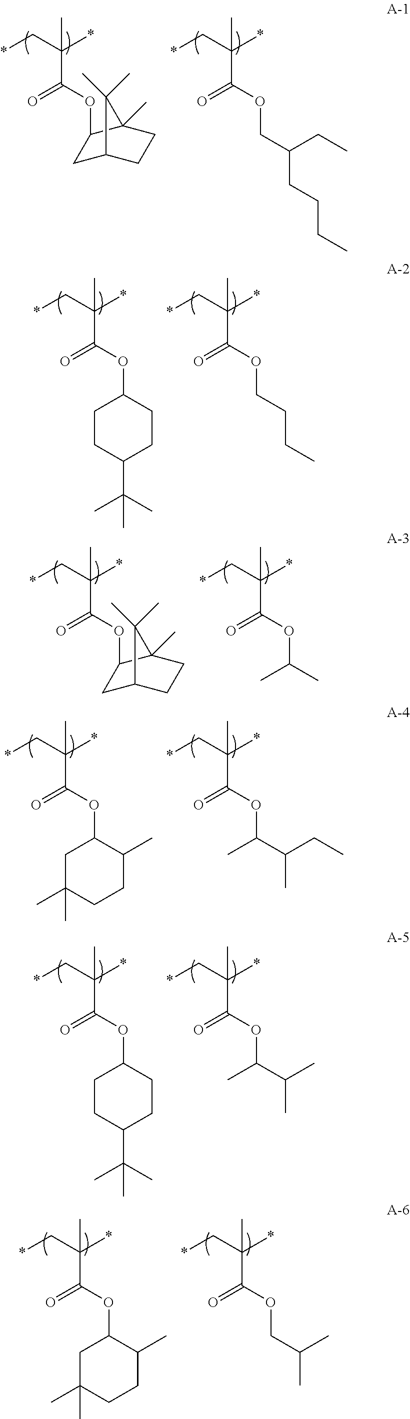

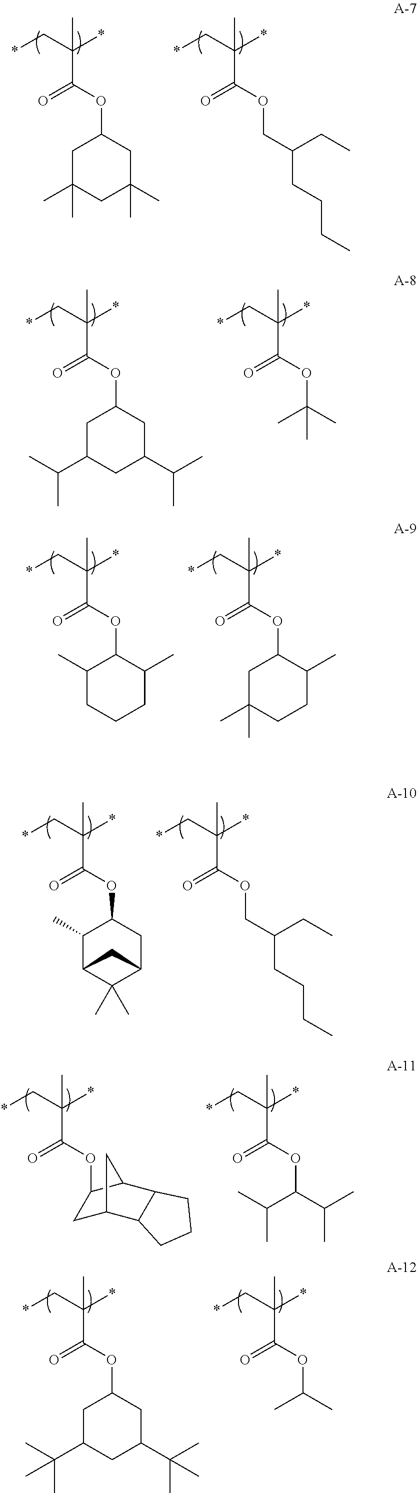

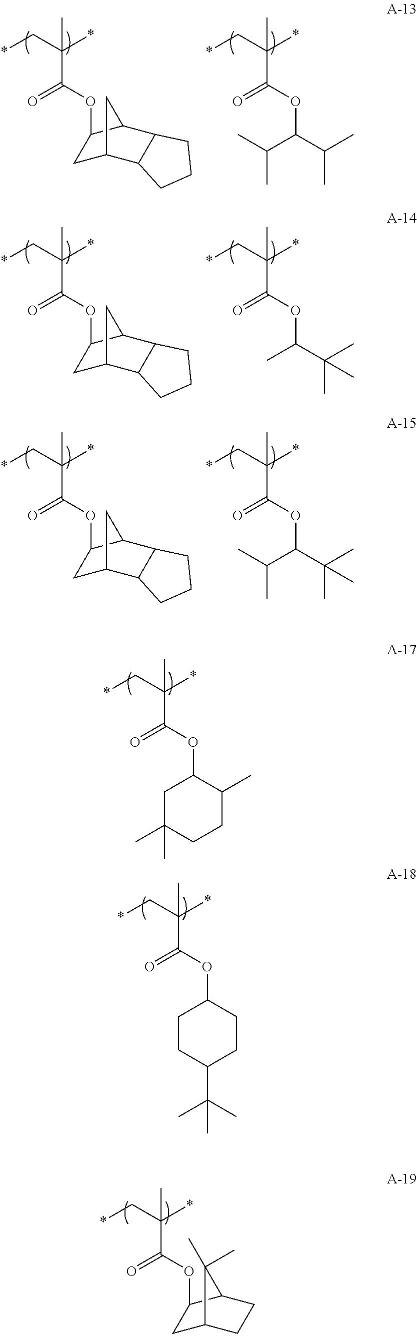

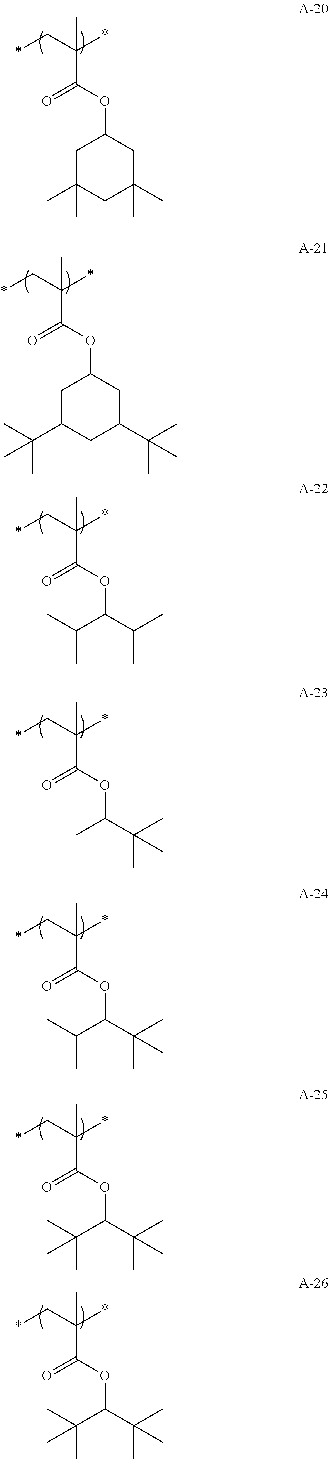

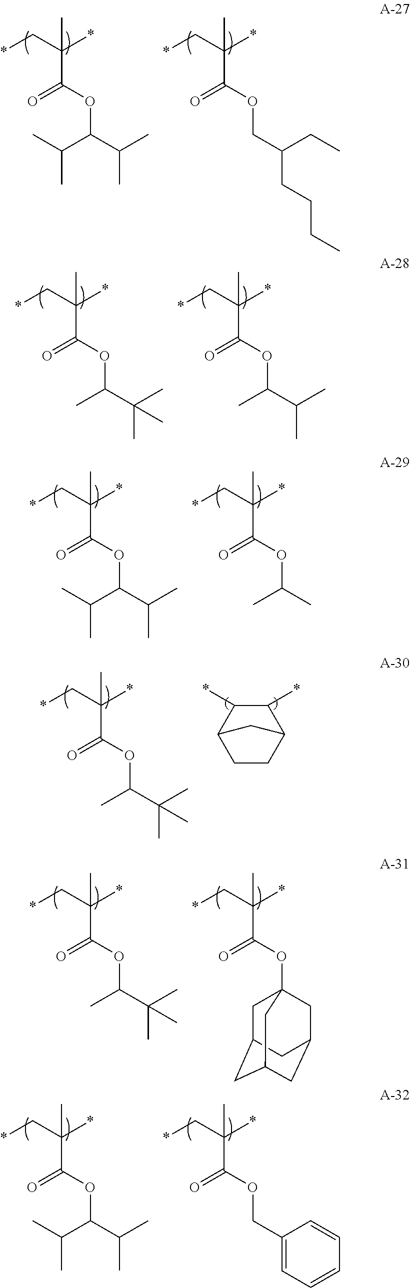

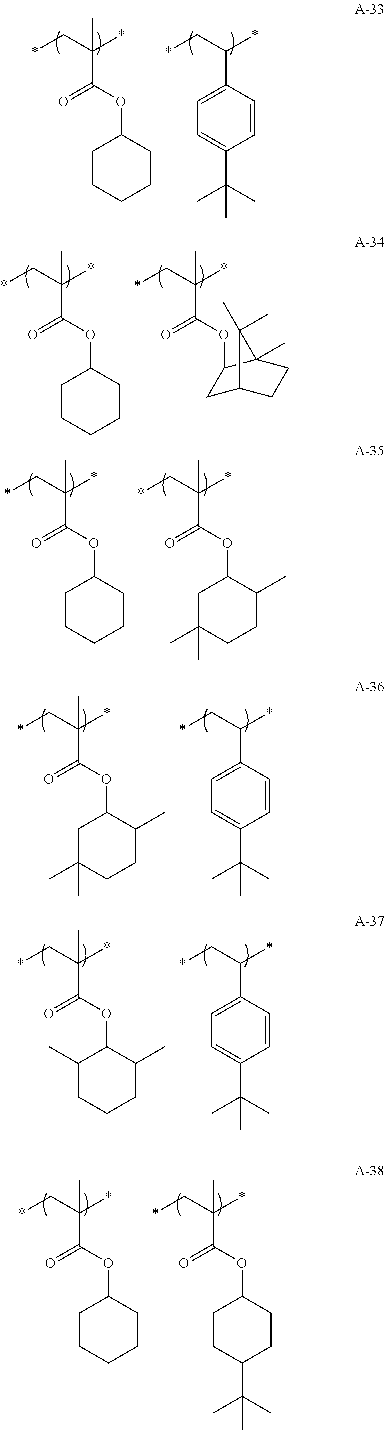

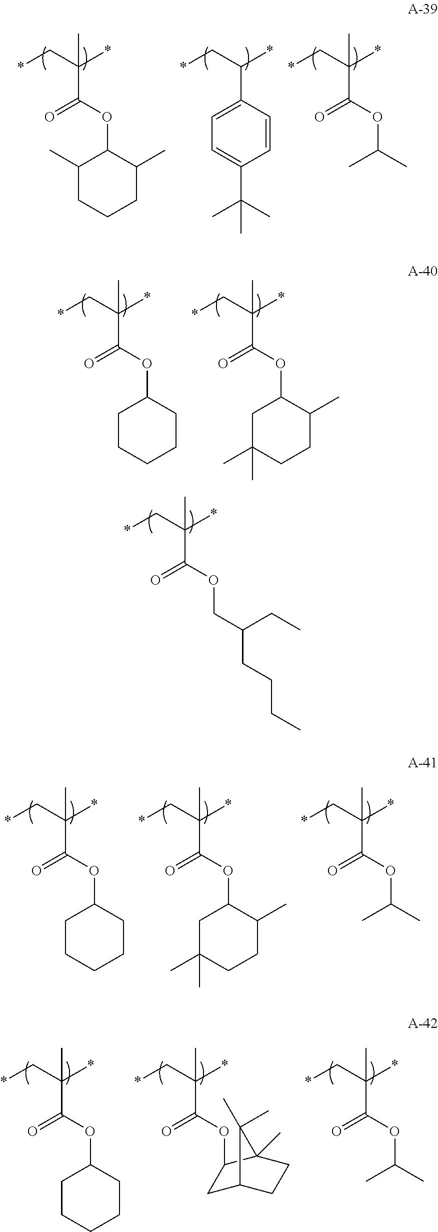

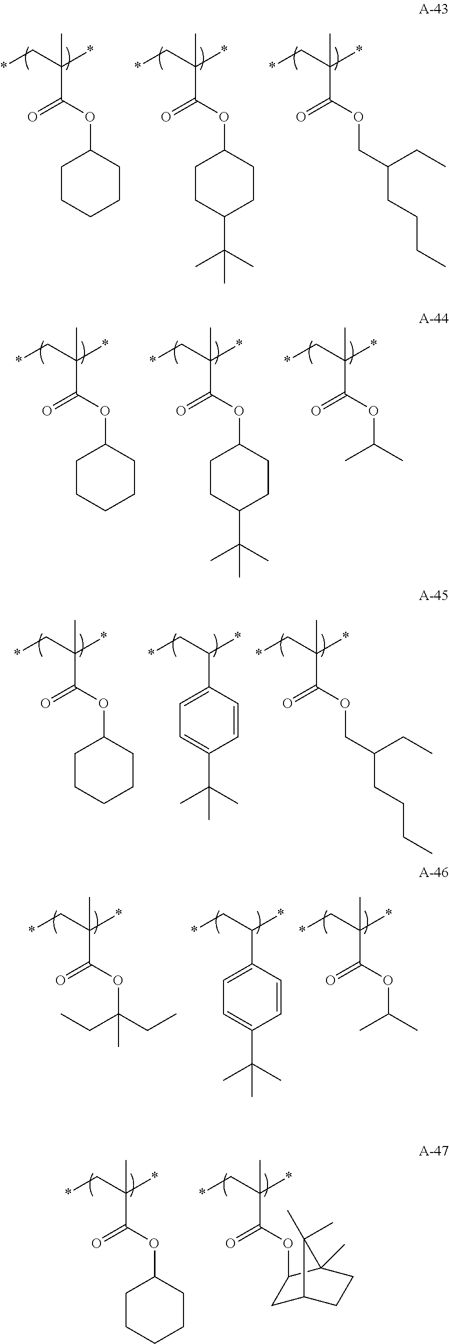

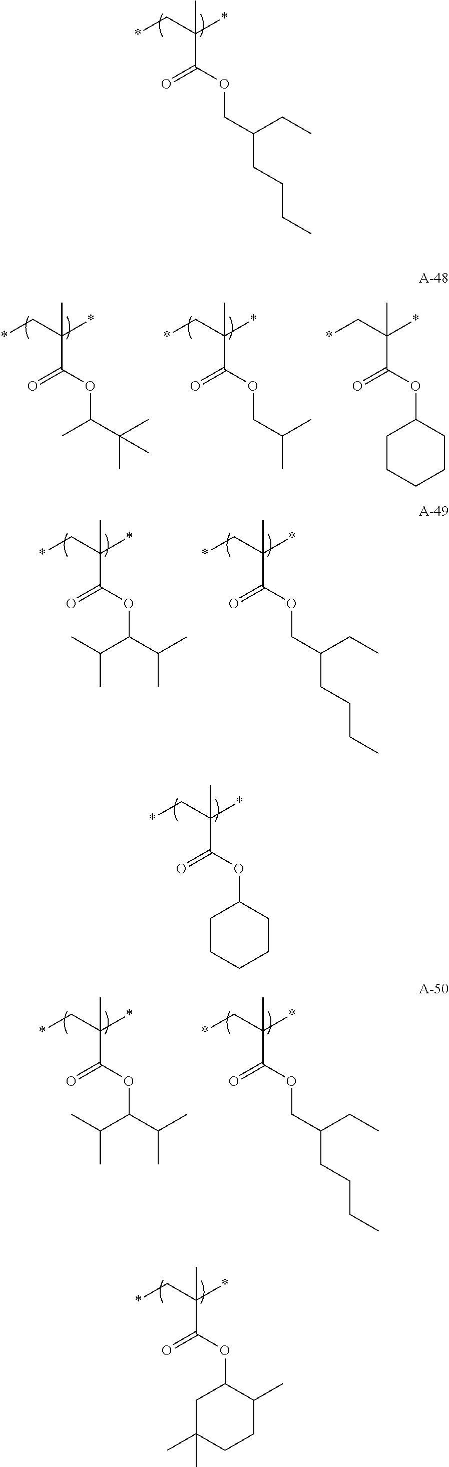

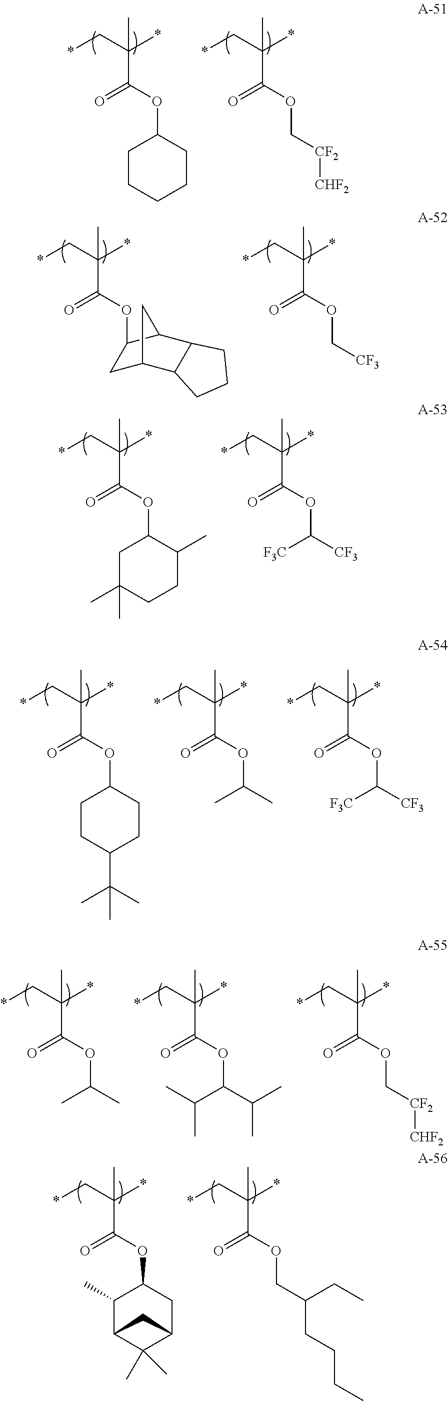

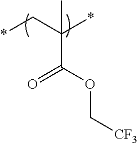

[Basic Compound XC]

The protective film forming composition of the present invention contains a basic compound (hereinafter also referred to as a “basic compound XC”).

The basic compound XC preferably has a ClogP value of 1.30 or less, and more preferably has a ClogP value of 1.00 or less, and still more preferably has a ClogP value of 0.70 or less. The ClogP value of the basic compound (XC) is usually−3.00 or more.

Here, the ClogP value is a value calculated for the compound using Chem DrawUltra ver. 12.0.2.1076 (Cambridge Corporation).

The basic compound XC is preferably a compound having an ether bond, and more preferably a compound having an alkyleneoxy group.

The basic compound XC may be a base generator which will be described later. The basic generator preferably has a ClogP value of 1.30 or less. Further, the basic compound XC functions as a quencher that traps an acid generated from the photoacid generator in the resist film. In addition, the action as a quencher that traps an acid refers to an action for neutralizing an acid generated.

The basic compound XC is preferably an organic basic compound, and more preferably a nitrogen-containing basic compound. Among those, an amine compound or an amide compound is more preferable. Specific suitable examples of the basic compound XC include compounds having structures represented by Formulae (A) to (E) which will be described later. Among the specific examples of the amine compound and the amide compound include compounds corresponding to the amine compound and the amide compound.

Moreover, for example, compounds classified into the following (1) to (5) can be used.

<(1) Compound Represented by Formula (BS-1)>

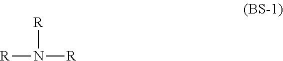

In Formula (BS-1), R's each independently represent a hydrogen atom or an organic group, provided that at least one of three R's is an organic group.

It is preferable that this organic group is selected such that the ClogP of the compound is 1.30 or less, and examples thereof include a linear or branched alkyl group, a monocyclic or polycyclic cycloalkyl group, an aryl group, and an aralkyl group, each having a heteroatom in the chain or as a ring member, or having a polar group as a substituent.

The number of carbon atoms in the alkyl group as R is not particularly limited, but is usually 1 to 20, and preferably 1 to 12.

The number of carbon atoms in the cycloalkyl group as R is not particularly limited, but is usually 3 to 20, and preferably 5 to 15.

The number of carbon atoms in the aryl group as R is not particularly limited, but is usually 6 to 20, and preferably 6 to 10. Specific examples thereof include a phenyl group and a naphthyl group.

The number of carbon atoms in the aralkyl group as R is not particularly limited, but is usually 7 to 20, and preferably 7 to 11. Specific examples thereof include a benzyl group.

Examples of a polar group as the substituent contained in the alkyl group, the cycloalkyl group, the aryl group, or the aralkyl group as R include a hydroxy group, a carboxy group, an alkoxy group, an aryloxy group, an alkylcarbonyloxy group, and an alkyloxycarbonyl group.

Furthermore, it is preferable that at least two of R's in the compound represented by Formula (BS-1) are organic groups.

Specific suitable examples of the compound represented by Formula (BS-1) include an alkyl group in which at least one R is substituted with a hydroxy group. Specific examples thereof include triethanolamine and N,N-dihydroxyethylaniline.

Moreover, the alkyl group as R preferably has an oxygen atom in the alkyl chain. That is, an oxyalkylene chain is preferably formed. The oxyalkylene chain is preferably —CH₂CH₂O—. Specific examples thereof include tris(methoxyethoxyethyl)amine and a compound disclosed after line 60 of column 3 in the specification of U.S. Pat. No. 6,040,112A.

Examples of the basic compound represented by Formula (BS-1) include the following compounds.

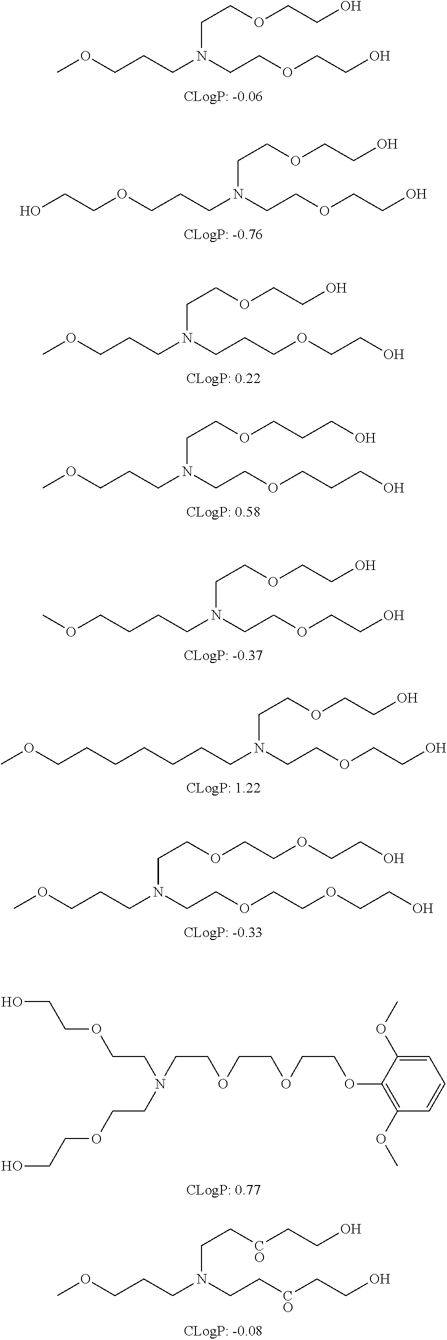

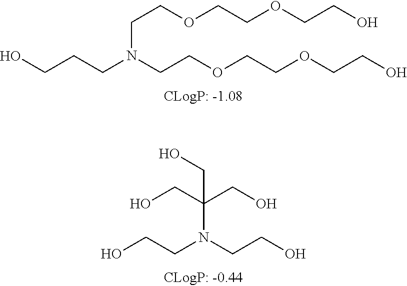 [SMILES: OCCCN(CCOCCOCCO)CCOCCOCCO ; OCCN(CCO)C(CO)(CO)CO]

<(2) Compound Having Nitrogen-Containing Heterocyclic Structure>

A compound having a nitrogen-containing heterocyclic structure can also be appropriately used as the basic compound XC.

This nitrogen-containing heterocycle may have aromaticity. Further, the compound may have a plurality of nitrogen atoms. It is preferable that the compound further contains a heteroatom other than a nitrogen atom. Specific examples thereof include a compound having an imidazole structure, a compound having a piperidine structure [N-hydroxyethylpiperidine (ClogP: −0.81) and the like], a compound having a pyridine structure, and a compound having an antipyrine structure [antipyrine (ClogP: −0.20), hydroxyantipyrine (ClogP: −0.16), and the like].

In addition, a compound having two or more ring structures is also suitably used. Specific examples thereof include 1,5-diazabicyclo[4.3.0]-non-5-ene (ClogP: −0.02) and 1,8-diazabicyclo[5.4.0]-undec-7-ene (ClogP: 1.14).

<(3) Amine Compound Having Phenoxy Group>

An amine compound having a phenoxy group can also be appropriately used as the basic compound XC.

The amine compound having a phenoxy group is a compound having a phenoxy group at the terminal on the opposite side to the N atom of the alkyl group which is contained in an amine compound. The phenoxy group may have a substituent such as an alkyl group, an alkoxy group, a halogen atom, a cyano group, a nitro group, a carboxy group, a carboxylic acid ester group, a sulfonic acid ester group, an aryl group, an aralkyl group, an acyloxy group, or an aryloxy group.

This compound preferably has at least one oxyalkylene chain between the phenoxy group and the nitrogen atom. The number of oxyalkylene chains in one molecule is preferably 3 to 9, and more preferably 4 to 6. Among oxyalkylene chains, —CH₂CH₂O— is particularly preferable.

The amine compound having a phenoxy group is obtained by, for example, heating a mixture of a primary or secondary amine having a phenoxy group and a haloalkyl ether to be reacted, by adding an aqueous solution of a strong base such as sodium hydroxide, potassium hydroxide, and tetraalkylammonium thereto, and by extracting the resultant product with an organic solvent such as ethyl acetate and chloroform. In addition, an amine compound having a phenoxy group can also be obtained by heating a mixture of a primary or secondary amine and a haloalkyl ether having a phenoxy group at the terminal to be reacted, by adding an aqueous solution of a strong base such as sodium hydroxide, potassium hydroxide, and tetraalkylammonium to the obtained reaction solution, and by extracting the resultant product with an organic solvent such as ethyl acetate and chloroform.

<(4) Ammonium Salt>

An ammonium salt can also be appropriately used as the basic compound XC. Examples of the anion of the ammonium salt include halide, sulfonate, borate, and phosphate. Among these, halide and sulfonate are preferable.

As the halide, chloride, bromide, and iodide are preferable.

As the sulfonate, an organic sulfonate having 1 to 20 carbon atoms is preferable. Examples of the organic sulfonate include alkyl sulfonate and aryl sulfonate, having 1 to 20 carbon atoms.

The alkyl group included in the alkyl sulfonate may have a substituent. Examples of the substituent include a fluorine atom, a chlorine atom, a bromine atom, an alkoxy group, an acyl group, and an aryl group. Specific examples of the alkyl sulfonate include methanesulfonate, ethanesulfonate, butanesulfonate, hexanesulfonate, octanesulfonate, benzyl sulfonate, trifluoromethanesulfonate, pentafluoroethanesulfonate, and nonafluorobutanesulfonate.

Examples of the aryl group included in the aryl sulfonate include a phenyl group, a naphthyl group, and an anthryl group. These aryl groups may have a substituent. As the substituent, for example, a linear or branched alkyl group having 1 to 6 carbon atoms or a cycloalkyl group having 3 to 6 carbon atoms is preferable. Specifically, for example, a methyl group, an ethyl group, an n-propyl group, an isopropyl group, an n-butyl group, an i-butyl group, a t-butyl group, an n-hexyl group, and a cyclohexyl group are preferable. Examples of other substituents include an alkoxy group having 1 to 6 carbon atoms, a halogen atom, a cyano group, a nitro group, an acyl group, and an acyloxy group.

This ammonium salt may be hydroxide or carboxylate. In this case, the ammonium salt is preferably tetraalkylammonium hydroxide (tetraalkylammonium hydroxide such as tetramethylammonium hydroxide, tetraethylammonium hydroxide, and tetra-(n-butyl)ammonium hydroxide) having 1 to 8 carbon atoms.

Preferred examples of the basic compound XC include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, and aminoalkylmorpholine. These may further have a substituent.

Preferred examples of the above-mentioned substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

More preferred examples of the basic compound XC include guanidine (ClogP: −2.39), 1,1-dimethylguanidine (ClogP: −1.04), 1,1,3,3-tetramethylguanidine (ClogP: −0.29), imidazole (ClogP: −0.03), 2-methylimidazole (ClogP: 0.24), 4-methylimidazole (ClogP: 0.24), N-methylimidazole (ClogP: −0.01), 2-aminopyridine (ClogP: 0.32), 3-aminopyridine (ClogP: 0.32), 4-aminopyridine (ClogP: 0.32), 2-(aminomethyl)pyridine (ClogP: −0.40), 2-amino-3-methylpyridine (ClogP: 0.77), 2-amino-4-methylpyridine (ClogP: 0.82), 2-amino-5-methylpyridine (ClogP: 0.82), 2-amino-6-methylpyridine (ClogP: 0.82), 3-aminoethylpyridine (ClogP: −0.06), 4-aminoethylpyridine (ClogP: −0.06), 3-aminopyrrolidine (ClogP: −0.85), piperazine (ClogP: −0.24), N-(2-aminoethyl)piperazine (ClogP: −0.74), N-(2-aminoethyl)piperidine (ClogP: 0.88), 4-piperidinopiperidine (ClogP: 0.73), 2-iminopiperidine (ClogP: 0.29), l-(2-aminoethyl)pyrrolidine (ClogP: 0.32), pyrazole (ClogP: 0.24), 3-amino-5-methylpyrazole (ClogP: 0.78), pyrazine (ClogP: −0.31), 2-(aminomethyl)-5-methylpyrazine (ClogP: −0.86), pyrimidine (ClogP: −0.31), 2,4-diaminopyrimidine (ClogP: −0.34), 4,6-dihydroxypyrimidine (ClogP: 0.93), 2-pyrazoline (ClogP: −0.57), 3-pyrazoline (ClogP: −1.54), N-aminomorpholine (ClogP: −1.22), and N-(2-aminoethyl)morpholine (ClogP: −0.33).

<(5) Low Molecular Compound Having Nitrogen Atom and Group that Leaves by Action of Acid>

The protective film forming composition of the present invention can contain a low molecular compound (hereinafter referred to as a “low molecular compound (D)” or a “compound (D)”) which has a nitrogen atom and a group that leaves by the action of an acid, as the basic compound XC. The low molecular compound (D) preferably has basicity after the group that leaves by the action of an acid leaves.

The group that leaves by the action of an acid is not particularly limited, but an acetal group, a carbonate group, a carbamate group, a tertiary ester group, a tertiary hydroxyl group, or a hemiaminal ether group is preferable. Among those, the carbamate group or the hemiaminal ether group is more preferable.

The molecular weight of the low molecular compound (D) having a group that leaves by the action of an acid is preferably 100 to 1,000, more preferably 100 to 700, and still more preferably 100 to 500. Incidentally, in a case where the “molecular weight” is simply mentioned in the present specification, it refers to a molecular weight that can be calculated from a chemical structural formula unless otherwise specified.

As the compound (D), an amine derivative having a group that leaves by the action of an acid on a nitrogen atom is preferable.

The compound (D) may also have a carbamate group having a protecting group on a nitrogen atom. The protecting group constituting the carbamate group can be represented by Formula (d-1).

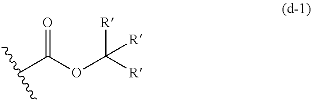

In Formula (d-1), R′'s each independently represent a hydrogen atom, a linear or branched alkyl group, a cycloalkyl group, an aryl group, an aralkyl group, or an alkoxyalkyl group. R′'s may be bonded to each other to form a ring.

R′ is preferably a linear or branched alkyl group, a cycloalkyl group, or an aryl group, and more preferably a linear or branched alkyl group or a cycloalkyl group.

Specific structures of such groups are shown below.

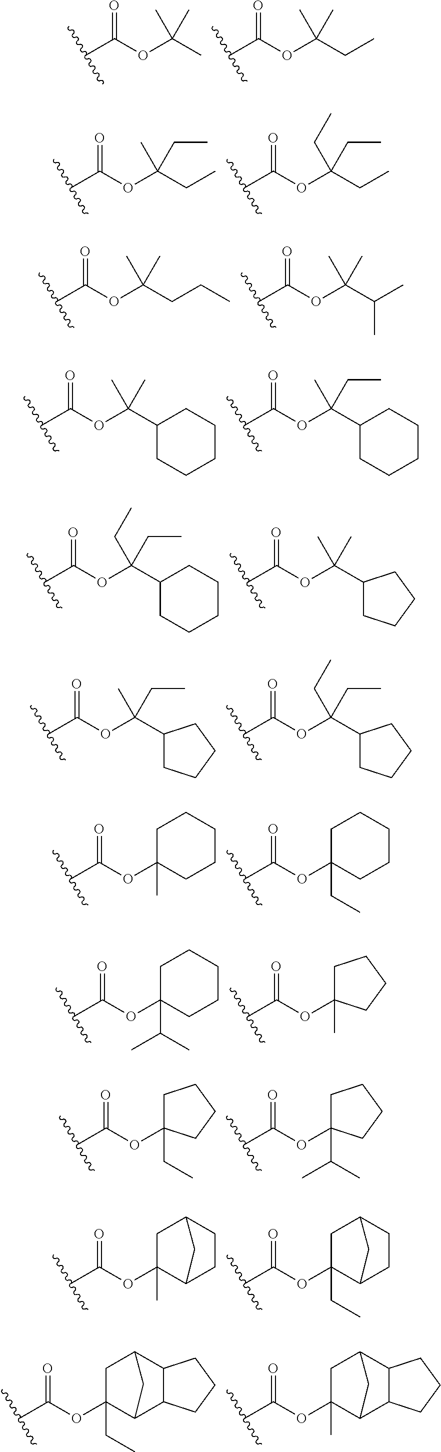

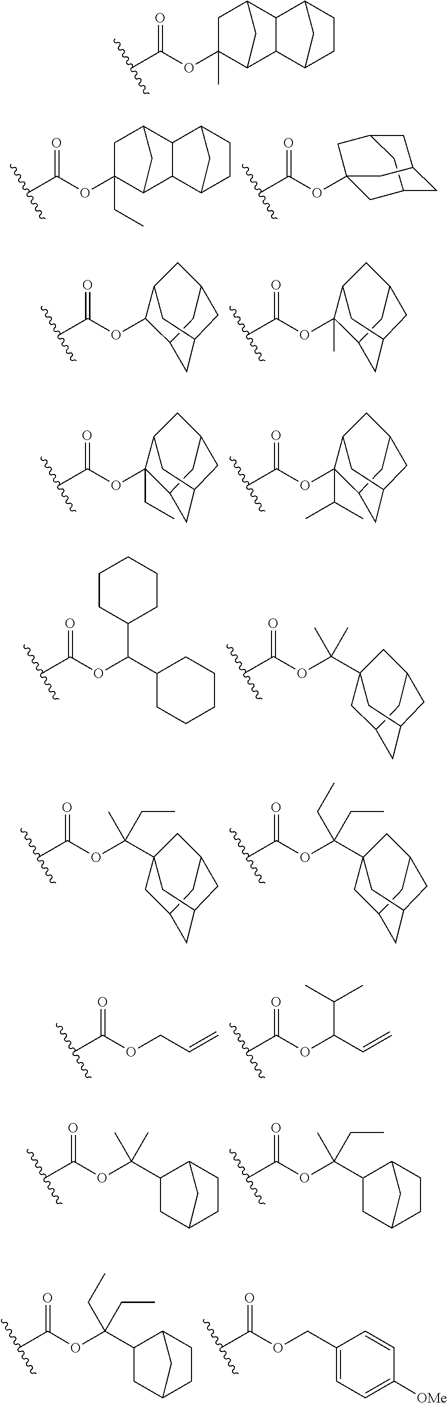

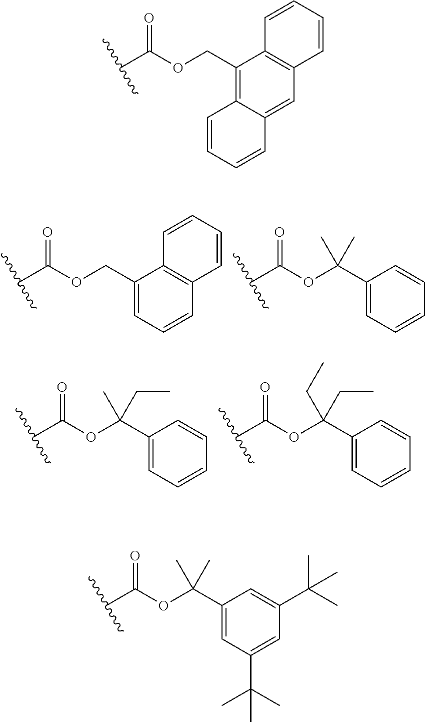

The compound (D) can also be constituted with a combination of the above-mentioned basic compound and a structure represented by Formula (d-1).

The compound (D) is preferably a compound having a structure represented by Formula (A).

Incidentally, the compound (D) may be a compound corresponding to the above-mentioned basic compound as long as it is a low molecular compound having a group that leaves by the action of an acid.

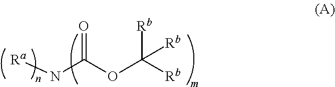

In Formula (A), R^{a} represents a hydrogen atom, an alkyl group, a cycloalkyl group, an aryl group, or an aralkyl group.

Furthermore, n represents an integer of 0 to 2 and m represents an integer of 1 to 3, with n+m=3.

In addition, with n=2, two R^{a}'s may be the same as or different from each other, and two R^{a}'s may be bonded to each other to form a divalent heterocyclic hydrocarbon group (preferably having 20 or less carbon atoms) or a derivative thereof.

R^{b}'s each independently represent a hydrogen atom, an alkyl group, a cycloalkyl group, an aryl group, an aralkyl group, or an alkoxyalkyl group, provided that in a case where one or more R^{b} in —C(R^{b})(R^{b})(R^{b}) are hydrogen atoms, at least one of the remaining R^{b}'s is a cyclopropyl group, a 1-alkoxyalkyl group, or an aryl group.

At least two R^{b}'s may be bonded to each other to form an alicyclic hydrocarbon group, an aromatic hydrocarbon group, a heterocyclic hydrocarbon group, or a derivative thereof.

In Formula (A), the alkyl group, the cycloalkyl group, the aryl group, and the aralkyl group represented by each of R^{e} and R^{b} may be substituted with a functional group such as a hydroxyl group, a cyano group, an amino group, a pyrrolidino group, a piperidino group, a morpholino group, and an oxo group, an alkoxy group, or a halogen atom. The same applies to the alkoxyalkyl group represented by R^{b}.

Examples of the alkyl group, the cycloalkyl group, the aryl group, and the aralkyl group represented by each of R^{a} and R^{b} are shown to be the following (a) to (e-1).

(a) A linear alkyl group or a branched alkyl group having 3 to 12 carbon atoms, such as methane, ethane, propane, butane, pentane, hexane, heptane, octane, nonane, decane, undecane, and dodecane.

(a-1) A group formed by substituting at least one of hydrogen atoms in the group exemplified in (a) with a cycloalkyl group such as a cyclobutyl group, a cyclopentyl group, and a cyclohexyl group.

(b) A group derived from a cycloalkane such as cyclobutane, cyclopentane, cyclohexane, cycloheptane, cyclooctane, norbornane, adamantane, and noradamantane, and a group formed by substituting at least one of hydrogen atoms in the group derived from the cycloalkane with a linear or branched alkyl group such as a methyl group, an ethyl group, an n-propyl group, an i-propyl group, an n-butyl group, a 2-methylpropyl group, a 1-methylpropyl group, and a t-butyl group.

(c) A group derived from an aromatic compound such as benzene, naphthalene, and anthracene, and a group formed by substituting at least one of hydrogen atoms in the group derived from the aromatic compound with a linear or branched alkyl group such as a methyl group, an ethyl group, an n-propyl group, an i-propyl group, an n-butyl group, a 2-methylpropyl group, a 1-methylpropyl group, and a t-butyl group.

(d) A group derived from a heterocyclic compound such as pyrrolidine, piperidine, morpholine, tetrahydrofuran, tetrahydropyran, indole, indoline, quinoline, perhydroquinoline, indazole, and benzimidazole, and a group formed by substituting at least one of hydrogen atoms in the group derived from the heterocyclic compound with a linear or branched alkyl group or a group derived from an aromatic compound.

(e) A group derived from a linear or branched alkane, a group derived from a cycloalkane, or a group formed by substituting at least one of hydrogen atoms in the group derived from the alkane or the group derived from the cycloalkane with a group derived from an aromatic compound, such as a phenyl group, a naphthyl group, and an anthracenyl group.

(e-1) A group formed by substituting at least one of hydrogen atoms in the group derived from the aromatic compound in (e) with a functional group such as a hydroxyl group, a cyano group, an amino group, a pyrrolidino group, a piperidino group, a morpholino group, and an oxo group.

Moreover, examples of the divalent heterocyclic hydrocarbon group (preferably having 1 to 20 carbon atoms) formed by the mutual bonding of R^{a}'s, or a derivative thereof include a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1 S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, and 1,5,9-triazacyclododecane, and a group formed by substituting at least one of hydrogen atoms in the group derived from the heterocyclic compound with a group derived from a group derived from a linear or branched alkane, a group derived from a cycloalkane, a group derived from an aromatic compound, a group derived from a heterocyclic compound, or a functional group such as a hydroxyl group, a cyano group, an amino group, a pyrrolidino group, a piperidino group, a morpholino group, and an oxo group.

Specific examples of the particularly preferred compound (D) in the present invention include the following compounds, but the present invention is not limited thereto.

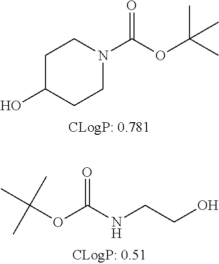

In the present invention, the low molecular compound (D) may be used singly or as a mixture of two or more kinds thereof.

Other examples of the low molecular compound which can be used include the compounds synthesized in Examples of JP2002-363146A and the compounds described in paragraph 0108 of JP2007-298569A.

A photosensitive basic compound may be used as the basic compound XC. As the photosensitive basic compound, for example, the compounds described in JP2003-524799A, J. Photopolym. Sci. & Tech., Vol. 8, pp. 543 to 553 (1995), or the like can be used.

<Base Generator>

As described above, examples of the basic compound XC also include a base generator. The base generator preferably has a ClogP value of 1.30 or less.

Examples of the base generator (photobase generator) with a ClogP of 1.30 or less include the compounds described in JP1992-151156A (JP-H04-151156A), JP1992-162040A (JP-H04-162040A), JP1993-197148A (JP-H05-197148A), JP1993-5995A (JP-H05-5995A), JP1994-194834A (JP-H06-194834A), JP1996-146608A (JP-H08-146608A), JP1998-83079A (JP-H10-83079A), and EP622682B.

Furthermore, the compounds described in JP2010-243773A are also appropriately used.

Specific suitable examples of the base generator with a ClogP value of 1.30 or less include 2-nitrobenzyl carbamate, but are not limited thereto.

(Content of Basic Compound XC in Protective Film Forming Composition)

The content of the basic compound XC in the protective film forming composition is preferably 0.01% to 20% by mass, more preferably 0.1% to 10% by mass, and still more preferably 0.3% to 5% by mass, with respect to the total solid content of the protective film forming composition.

In addition, the basic compound XC may be used singly or in combination of two or more kinds thereof.

[Solvent]

In order to form a good pattern while not dissolving the resist film, it is preferable that the protective film forming composition in the present invention contains a solvent in which the resist film is not dissolved, and it is more preferable that a solvent with components different from an organic developer is used.

Incidentally, from the viewpoint of the prevention of elution into an immersion liquid, low solubility in an immersion liquid is preferred, and low solubility in water is more preferable. In the present specification, the description of “having low solubility in an immersion liquid” represents insolubility in an immersion liquid. Similarly, “having low solubility in water” means insolubility in water. Further, from the viewpoints of volatility and coatability, the boiling point of the solvent is preferably 90° C. to 200° C.

The description of “having low solubility in an immersion liquid” indicates that in an example of the solubility in water, in a case where a protective film forming composition is applied onto a silicon wafer and dried to form a film, and then the film is immersed in pure water at 23° C. for 10 minutes, the decrease rate in the film thickness after drying is within 3% of the initial film thickness (typically 50 nm).

From the viewpoint of uniformly applying the protective film, a solvent having a concentration of the solid contents of the protective film forming composition of preferably 0.01% to 20% by mass, more preferably 0.1% to 15% by mass, and most preferably 1% to 10% by mass is used.

The solvent that can be used is not particularly limited as long as it can dissolve the above-mentioned resins XA and XB, and does not dissolve the resist film, but suitable examples thereof include an alcohol-based solvent, an ether-based solvent, an ester-based solvent, a fluorine-based solvent, and a hydrocarbon-based solvent, with a non-fluorinated alcohol-based solvent being more preferably used. Thus, the non-dissolving property for the resist film is further enhanced and in a case where the protective film forming composition is applied onto the resist film, a protective film can be more uniformly formed without dissolving the resist film. The viscosity of the solvent is preferably 5 centipoises (cP) or less, more preferably 3 cP or less, still more preferably 2 cP or less, and particularly preferably 1 cP or less. Further, centipoises can be converted into pascal seconds according to the following formula:

1,000 cP=1 Pa·s.

<Alcohol-Based Solvent>

From the viewpoint of coatability, the alcohol-based solvent is preferably a monohydric alcohol, and more preferably a monohydric alcohol having 4 to 8 carbon atoms. As the monohydric alcohol having 4 to 8 carbon atoms, a linear, branched, or cyclic alcohol may be used, but a linear or branched alcohol is preferable. As such an alcohol-based solvent, for example, alcohols such as 1-butanol, 2-butanol, 3-methyl-1-butanol, 4-methyl-1-pentanol, 4-methyl-2-pentanol, isobutyl alcohol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, and 4-octanol; glycols such as ethylene glycol, propylene glycol, diethylene glycol, and triethylene glycol; glycol ethers such as ethylene glycol monomethyl ether, propylene glycol monomethyl ether, diethylene glycol monomethyl ether, triethylene glycol monoethyl ether, and methoxymethylbutanol; or the like can be used. Among those, alcohol and glycol ether are preferable, and 1-butanol, 1-hexanol, 1-pentanol, 3-methyl-1-butanol, 4-methyl-1-pentanol, 4-methyl-2-pentanol, and propylene glycol monomethyl ether are more preferable.

As the alcohol-based solvent, a secondary alcohol is preferable from the viewpoints of temporal stability and coatability, and as a specific example thereof, the secondary alcohols in the specific examples of the above-mentioned monohydric alcohols is preferable.

<Ether-Based Solvent>

Examples of the ether-based solvent include, in addition to the glycol ether-based solvents, dioxane, tetrahydrofuran, isoamyl ether, and diisoamyl ether. Among the ether-based solvents, an ether-based solvent having a branched structure is more preferable.

<Ester-Based Solvent>

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, butyl butanoate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, and butyl propionate. Among the ester-based solvents, an ester-based solvent having a branched structure is preferable.

<Fluorine-Based Solvent>

Examples of the fluorine-based solvent include 2,2,3,3,4,4-hexafluoro-1-butanol, 2,2,3,3,4,4,5,5-octafluoro-1-pentanol, 2,2,3,3,4,4,5,5,6,6-decafluoro-1-hexanol, 2,2,3,3,4,4-hexafluoro-1,5-pentanediol, 2,2,3,3,4,4,5,5-octafluoro-1,6-hexanediol, 2,2,3,3,4,4,5,5,6,6,7,7-dodecafluoro-1,8-octanediol, 2-fluoroanisole, 2,3-difluoroanisole, perfluorohexane, perfluoroheptane, perfluoro-2-pentanone, perfluoro-2-butyltetrahydrofuran, perfluorotetrahydrofuran, perfluorotributylamine, and perfluorotetrapentylamine. Among those, a fluorinated alcohol and a fluorinated hydrocarbon-based solvent can be suitably used.

<Hydrocarbon-Based Solvent>

Examples of the hydrocarbon-based solvent include aromatic hydrocarbon-based solvents such as toluene, xylene, and anisole; and aliphatic hydrocarbon-based solvents such as n-heptane, n-nonane, n-octane, n-decane, 2-methylheptane, 3-methylheptane, 3,3-dimethylhexane, and 2,3,4-trimethylpentane.

(Content of Peroxides in Solvent)

The solvent (XD) contained in the protective film forming composition of the present invention is preferably a solvent having a content of peroxides of a predetermined acceptable value or less. By using the solvent (XD) having a content of peroxides of a predetermined acceptable value or less, it is possible to suppress the basic compound, particularly the nitrogen-containing basic material from being chemically modified with nitrogen oxide. As a result, the protective film forming composition of the present invention has more excellent effects of the present invention.

Examples of the acceptable value of the content of the peroxides in the solvent (XD) include numeral value ranges which will be described later.

Furthermore, in a case where the peroxides included in the solvent can be quantitatively analyzed by chromatography such as gas chromatography (GC) and high performance liquid chromatography (HPLC) in a case where peroxides to be generated specified. Further, in a case where the sites to be oxidized in chemical structures of solvent molecules are determined and the structures are already known, it is possible to perform quantitative analysis by signal intensity using nuclear magnetic resonance (NMR).

Furthermore, with regard to the peroxides included in the solvent, an analysis method using a redox reaction as an analysis principle can also be used for the content of peroxides. For example, with a use of an iodometric titration using a redox reaction as an analysis principle, the content of peroxides can be quantitatively analyzed in terms of peroxides even in a case where unknown peroxides are included or a case where multiple kinds of peroxides are included.

These solvents are used singly or as a mixture of a plurality of kinds thereof.

In a case of mixing other solvents with the solvents, the content is preferably 0% to 30% by mass, more preferably 0% to 20% by mass, and still more preferably 0% to 10% by mass, with the total amount of solvents contained in the protective film forming composition. By mixing a solvent other than the above-mentioned solvents, the solubility of the protective film forming composition for the resist film, the solubility of the resin in the protective film forming composition, the elution characteristics from the resist film, or the like can be appropriately adjusted.

It is more preferable that the solvent (XD) contains the secondary alcohol and the ether-based solvent since the viscosity of the protective film forming composition decreases, and thus the coatability is enhanced.

[Antioxidant]

The protective film forming composition of the present invention contains an antioxidant. The antioxidant is used to prevent organic materials from being oxidized in the presence of oxygen, and in the protective film forming composition of the present invention, the antioxidant has an action to suppress a basic compound from being chemically modified by peroxides included in the solvent.

The antioxidant is not particularly limited as long as it has an effect of preventing oxidation of plastics and the like which are used in general, and examples thereof include a phenol-based antioxidant, an antioxidant composed of an organic acid derivatives a sulfur-containing antioxidant, a phosphorus-based antioxidant, an amine-based antioxidant, an antioxidant formed of an amine-aldehyde condensate, and an antioxidant formed of an amine-ketone condensate. Further, among those antioxidants, it is preferable to use a phenol-based antioxidant or an antioxidant formed of an organic acid derivative as the antioxidant in order to bring out the effects of the present invention while not reducing the functions of the resist film.

Examples of the phenol-based antioxidant include substituted phenols such as 1-oxy-3-methyl-4-isopropylbenzene, 2,6-di-tert-butylphenol, 2,6-di-tert-butyl-4-ethylphenol, 2,6-di-tert-butyl-4-methylphenol, 4-hydroxymethyl-2,6-di-tert-butylphenol, butylhydroxyanisole, 2-(1-methylcyclohexyl)-4,6-dimethylphenol, 2,4-dimethyl-6-tert-butylphenol, 2-methyl-4,6-dinonylphenol, 2,6-di-tert-butyl-a-dimethylamino-p-cresol, 6-(4-hydroxy-3,5-di-tert-butylanilino)2,4-bisoctyl-thio-1,3,5-triazine, n-octadecyl-3-(4′-hydroxy-3′,5′-di-tert-butylphenyl)propionate, octylated phenol, aralkyl-substituted phenols, alkylated p-cresol, and hindered phenol; and bis- and trisphenols such as 4,4′-dihydroxyediphenyl, methylene-bis-(dimethyl-4,6-phenol), 2,2′-methylene-bis-(4-methyl-6-tert-buty 2,2′-methylene-bis-(4-methyl-6-tert-butylphenol), 2,2′-methylene-bis-(4-methyl-6-cyclohexylphenol), 2,2′-methylene-bis-(4-ethyl-6-tert-butylphenol), 4,4′-methylene-bis-(2,6-di-tert-butylphenol), 2,2′-methylene-bis-(6-a-methyl-benzyl-p-cresol), methylene crosslinked polyvalent alkylphenol, 4,4′-butylidenebis-(3-methyl-6-tert-butylphenol), 1,1-bis-(4-hydroxyphenyl)-cyclohexane, 2,2′-dihydroxy-3,3′-di-(α-methylcyclohexyl)-5,5′-dimethyldiphenylmethane, alkylated bisphenol, hindered bisphenol, 1,3,5-trimethyl-2,4,6-tris(3,5-di-tertbutyl-4-hydroxybenzyl)benzene, tris-(2-methyl-4-hydroxy-5-tert-butylphenyl)butane, and tetrakis-[methylene-3-(3′,5′-di-tert-butyl-4′-hydroxyphenyl)propionate]methane, and commercially available antioxidants can also be used as they are. Examples of the commercially available antioxidants include Irganox (manufactured by BASF).

Specific preferred examples of the antioxidant include 2,6-di-t-butyl-4-methylphenol, 4-hydroxymethyl-2,6-di-t-butylphenol, 2,2′-methylenebis(4-methyl-6-t-butylphenol), butylhydroxyanisole, t-butyl hydroquinone, 2,4,5-trihydroxybutyrophenone, nordihydroguaiaretic acid, propyl gallate, octyl gallate, lauryl gallate, and isopropyl citrate. Among those, 2,6-di-t-butyl-4-methylphenol, 4-hydroxymethyl-2,6-di-t-butylphenol, butylhydroxyanisole, and t-butyl hydroquinone are preferable, and 2,6-di-t-butyl-4-methylphenol and 4-hydroxymethyl-2,6-di-t-butylphenol are more preferable.

The content of the antioxidant is preferably 1 part per million (ppm) by mass or more, more preferably 10 ppm by mass or more, and still more preferably 100 ppm by mass or more, with respect to the total solid content of the protective film forming composition. Further, the upper limit vale of the content is not particularly limited, but is usually 1,000 ppm by mass or more. The antioxidants may be used singly or in combination of two or more kinds thereof.

[Other Components]

The protective film forming composition of the present invention may further contain a surfactant. The surfactant is not particularly limited, and any of an anionic surfactant, a cationic surfactant, and a nonionic surfactant can be used as long as it can allow the protective film forming composition to form a film uniformly and can dissolve the protective film forming composition in the solvent (XD).

The amount of the surfactant to be added is preferably 0.001% to 20% by mass, and more preferably 0.01% to 10% by mass, with respect to the total solid content in the protective film forming composition.

The surfactants may be used singly or in combination of two or more kinds thereof.

As the surfactant, for example, one selected from an alkyl cation-based surfactant, an amide-type quaternary cation-based surfactant, an ester type quaternary cation-based surfactant, an amine oxide-based surfactant, a betaine-based surfactant, an alkoxylate-based surfactant, a fatty acid ester-based surfactant, an amide-based surfactant, an alcohol-based surfactant, an ethylenediamine-based surfactant, and fluorine-based and silicon-based surfactants (a fluorine-based surfactant, a silicon-based surfactant, or a surfactant having both of a fluorine atom and a silicon atom) can be suitably used.

Specific examples of the surfactant include polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether; polyoxyethylene/polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; surfactants such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; and commercially available surfactants which will be mentioned later.

Examples of the commercially available surfactants that can be used include fluorine-based surfactants or silicon-based surfactants such as EFTOP EF301 and EF303 (manufactured by Shin-Akita Kasei K. K.), FLORAD FC430, 431, and 4430 (manufactured by Sumitomo 3M Inc.), MEGAFAC F171, F173, F176, F189, F113, F110, F177, F120, and R08 (manufactured by DIC Corp.), SURFLON S-382, SCIO1, 102, 103, 104, 105, and 106 (manufactured by Asahi Glass Co., Ltd.), TROYSOL S-366 (manufactured by Troy Chemical Corp.), GF-300 and GF-150 (manufactured by Toagosei Chemical Industry Co., Ltd.), SURFLON S-393 (manufactured by Seimi Chemical Co., Ltd.), EFTOP EF121, EF122A, EF122B, RF122C, EF125M, EFI35M, EF351, EF352, EF801, EF802, and EF601 (manufactured by JEMCO Inc.), PF636, PF656, PF6320, and PF6520 (manufactured by OMNOVA Solutions Inc.), and FTX-204G, 208G, 218G, 230G, 204D, 208D, 212D, 218D, and 222D (manufactured by NEOS COMPANY LIMITED). In addition, Polysiloxane Polymer KP-341 (manufactured by Shin-Etsu Chemical Co., Ltd.) can also be used as the silicon-based surfactant.

[Method for Producing Protective Film Forming Composition]

The method for producing a protective film forming composition of the present invention has a step of preparing a solvent having a content of peroxides of an acceptable value or less, and a step of mixing the solvent, a resin, a basic compound, and an antioxidant to prepare a protective film forming composition.

The protective film forming composition produced by the above-mentioned production method is controlled such that it has a content of peroxides satisfying an acceptable value. Thus, even after being stored for a predetermined period of time, it is possible to obtain a protective film forming composition capable of performing formation of a pattern having more excellent depth of focus and exposure latitude. Hereinafter, the respective steps will be described in detail.

<Step of Preparing Solvent Having Content of Peroxides of Acceptable Value or Less>

In the present specification, the term of preparation is meant to include preparing a solvent having a content of peroxides of an acceptable value or less as well as providing the solvent by purchase or the like. That is, the preparation refers to creation of a state where a solvent having a content of peroxides of an acceptable value or less is prepared, purchased, or the like to make the solvent be ready to be used in the next step.

In addition, the step of preparing a solvent having a content of peroxides of an acceptable value or less has (1) a step of measuring or confirming the content of peroxides in the solvent, and (2) a step of comparing the measured or confirmed content of peroxides with an acceptable value. Incidentally, (3) a step of diluting a solvent having a higher content of peroxides than an acceptable value thereof may further be included.

The step of preparing a solvent having a content of peroxides of an acceptable value or less may have the steps of (1) and (2), and may also have the step of (3) and/or the other steps. Hereinafter, the respective steps will be described in detail.

((1) Step of Measuring or Confirming Content of Peroxides in Solvent)

Measurement of the content of peroxides in the solvent can be carried out by the method as described above. In a case where the protective film forming composition is produced in a batch mode, measurement can be carried out for the solvent subjected to the preparation of the protective film forming composition at each time of preparation. Further, in a case where the protective film forming composition is prepared in a continuous mode, for example, continuous measurement can be carried out for the solvent to be continuously supplied. These measurement methods may be carried out singly or in combination.

The content of peroxides may be confirmed by a method other than the measurement. Examples of the method for confirming the content of peroxides include a method in which a content of peroxides is acquired from information or the like provided by a production source in a case where the solvent is a commercially available product.

Furthermore, in a case of using a plurality of solvents, the content of peroxides can be measured for the solvent after mixing. Further, for the solvent before mixing, each of the content of peroxides may be singly measured or confirmed, and then for the solvent after mixing, the content of peroxides may be estimated. Examples of the estimation method include determination of arithmetic averages.

((2) Step of Comparing Measured or Confirmed Content of Peroxides with Acceptable Value)

As an acceptable value of the content of peroxides in the solvent, a value of a preferred content of peroxides from which the effects of the present invention are obtained can be used. Specifically, as the acceptable value, the content of peroxides in the solvent is preferably 1 mmol/L or less, and more preferably 0.1 mmol/L or less. The lower limit is not particularly limited, but it is usually 0.01 mmol/L or more in many cases in terms of relationship with a detection limit which will be described later. Further, taking variation in production conditions, or the like into consideration, a value having a certain margin with respect to a preferred value thereof can be set as an acceptable value.

Comparison between the measured or confirmed content of peroxides in the solvent the above-mentioned acceptable values may be carried out by, for example, calculating a difference therebetween.

((3) Step of Diluting Solvent Having Higher Content of Peroxides than Acceptable Value)

The step of preparing a solvent having a content of peroxides of an acceptable value or less may further have a step of diluting the solvent having a higher content of peroxides than an acceptable value. In the diluting step, the solvent is diluted such that the content satisfies the above-mentioned acceptable value. As the solvent for dilution, a solvent that is the same as or different from the solvent to be diluted can be used. In addition, the solvents for dilution may be used singly or in combination of two or more kinds thereof. Dilution can be carried out by a known method, and can also be carried out by, for example, adding a solvent for dilution to a solvent to be diluted, and stirring the mixture.

The solvent after dilution can be subjected to a step of preparing the protective film forming composition which will be described later. Further, the solvent after dilution may be subjected to the above-mentioned (1) and (2), and the content of peroxides may be measured or confirmed again, and be compared with an acceptable value. Further, as a result of measuring or confirming the content of peroxides again, in a case where the content is still higher than the acceptable value, (3) the step of diluting a solvent having a higher content of peroxides than the acceptable value may be carried out again. That is, the above-mentioned (1), (2), and (3) may be repeated plural times.

<Step of Mixing Solvent, Resin, Basic Compound, and Antioxidant to Prepare Protective Film Forming Composition>

By the present step, the solvent having a content of peroxides an acceptable value or less is subjected to preparation of a protective film forming composition. Therefore, the content of peroxides in the protective film forming compositions thus prepared is controlled to a predetermined value, and thus, a protective film forming composition capable of performing formation of a pattern having excellent depth of focus and exposure latitude can be obtained after being stored for a predetermined period of time.

In the present step, the order, the method, and the like for dissolving a solvent, a resin, a basic compound, an antioxidant, and other components may be appropriately selected. As the dissolution method can be carried out by, for example, introducing desired materials into a solvent, and stirring them, and a known method can be used. Dissolution may be carried out in an atmospheric environment or may be performed in an inert gas atmosphere such as nitrogen gas.

<Other Steps>

The method for producing a protective film forming composition of the present invention may have the other steps. Among those, a step in which the above-mentioned respective components are dissolved in a solvent and then obtained mixture is filtered through a filter is preferably included. As a filter, a polytetrafluoroethylene-made filter, a polyethylene-made filter, or a nylon-made filter, having a pore size of 0.1 μm or less, more preferably 0.05 μm or less, and still more preferably 0.03 μm or less is preferable. Further, plural kinds of filters may be connected in series or in parallel, and used. In addition, the protective film forming composition may be filtered plural times, and filtration in plural times may be carried out by circulatory filtration. Incidentally, before and after filtration using a filter, the protective film forming composition may be subjected to a degassing treatment or the like. It is preferable that the protective film forming composition of the present invention does not include impurities such as metals (solid metals and metal ions; metal impurities). Examples of the metal impurity components include Na, K, Ca, Fe, Cu, Mn, Mg, Al, Cr, Ni, Zn, Ag, Sn, Pb, and Li. The total content of the impurities included in the protective film forming composition is preferably 1 ppm or less, more preferably 10 ppb or less, still more preferably 100 ppt or less, particularly preferably 10 ppt or less, and most preferably 1 ppt or less.

[Pattern Forming Method]

The pattern forming method of the present invention includes a step a of forming an actinic ray-sensitive or radiation-sensitive film on a substrate, using an actinic ray-sensitive or radiation-sensitive resin composition, a step b of forming a protective film on the actinic ray-sensitive or radiation-sensitive film, using the protective film forming composition, a step c of a laminate film including the actinic ray-sensitive or radiation-sensitive film and the protective film to exposure, and a step d of developing the exposed laminate film using a developer.

[Step a]

In the step a, an actinic ray-sensitive or radiation-sensitive film is formed on a substrate, using the actinic ray-sensitive or radiation-sensitive resin composition.

The actinic ray-sensitive or radiation-sensitive resin composition which is used in the pattern forming method of the present invention is not particularly limited. Specific examples of the actinic ray-sensitive or radiation-sensitive resin composition will be described in detail.

<Actinic Ray-Sensitive or Radiation-Sensitive Resin Composition>

(A) Resin

The actinic ray-sensitive or radiation-sensitive resin composition typically contains a resin that has a decrease in its solubility in a developer including an organic solvent due to an increase in the polarity by the action of an acid.

The resin that has a decrease in its solubility in a developer including an organic solvent due to an increase in the polarity by the action of an acid (hereinafter also referred to as a “resin (A)”) is preferably a resin (hereinafter also referred to as an “acid-decomposable resin” or an “acid-decomposable resin (A)”) having a group (hereinafter also referred to as an “acid-decomposable group”) that decomposes by the action of an acid to generate an alkali-soluble group at either the main chain or the side chain of the resin, or at both the main chain and the side chain.

Furthermore, the resin (A) is more preferably a resin having an alicyclic hydrocarbon structure which is monocyclic or polycyclic (hereinafter also referred to as an “alicyclic hydrocarbon-based acid-decomposable resin”). It is thought that the resin having an alicyclic hydrocarbon structure which is monocyclic or polycyclic has high hydrophobicity and has improved developability in a case of developing an area of the actinic ray-sensitive or radiation-sensitive film having a weak light irradiation intensity by an organic developer.

The actinic ray-sensitive or radiation-sensitive resin composition containing the resin (A) can be suitably used in a case of irradiation with ArF excimer laser light.

Examples of the alkali-soluble group included in the resin (A) include a group having a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the alkali-soluble group include a carboxylic acid group, a fluorinated alcohol group (preferably hexafluoroisopropanol), and a sulfonic acid group.

A preferred group capable of decomposing by an acid (acid-decomposable group) is a group obtained by substituting a hydrogen atom of these alkali-soluble groups with a group that leaves with an acid.

Examples of the group that leaves by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the acid-decomposable group, a cumyl ester group, an enol ester group, an acetal ester group, a tertiary alkyl ester group, and the like are preferable, and a tertiary alkyl ester group is more preferable.

The resin (A) is preferably a resin containing repeating units having partial structures represented by Formulae (pI) to Formula (pV).

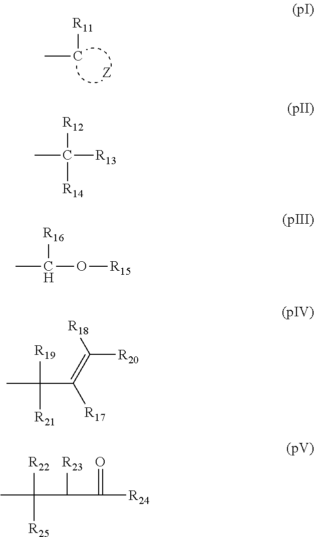

In Formulae (pI) to (pV),

R₁₁ represents a methyl group, an ethyl group, an n-propyl group, an isopropyl group, an n-butyl group, an isobutyl group, or a sec-butyl group, and Z represents an atomic group which is necessary for forming a cycloalkyl group together with carbon atoms.

R₁₂ to R₁₆ each independently represent a cycloalkyl group or a linear or branched alkyl group having 1 to 4 carbon atoms, provided that at least one of R₁₂, . . . , or R₁₄, or any one of R₁₅ and R₁₆ is a cycloalkyl group.

R₁₇ to R₂₁ each independently represent a hydrogen atom, a cycloalkyl group, or a linear or branched alkyl group having 1 to 4 carbon atoms, provided that at least one of R₁₇, . . . , or R₂₁ is a cycloalkyl group. Further, any one of R₁₉ and R₂₁ is a linear or branched alkyl group or cycloalkyl group, having 1 to 4 carbon atoms.

R₂₂ to R₂₅ each independently represent a hydrogen atom, a cycloalkyl group, or a linear or branched alkyl group having 1 to 4 carbon atoms, provided that at least one of R₂₂, . . . , or R₂₅ represents a cycloalkyl group. Further, R₂₃ and R₂₄ may be bonded to each other to form a ring.

In Formulae (pI) to (pV), the alkyl group in each of R₁₂ to R₂₅ is a linear or branched alkyl group having 1 to 4 carbon atoms.

The cycloalkyl group in each of R₁₁ to R₂₅ or the cycloalkyl group formed by Z together with carbon atoms may be monocyclic or polycyclic. Specific examples thereof include a group having 5 or more carbon atoms and having a monocyclo, bicyclo, tricyclo, or tetracyclo structure. These cycloalkyl groups preferably have 6 to 30 carbon atoms, and particularly preferably 7 to 25 carbon atoms. These cycloalkyl groups may have a substituent.

Preferred examples of the cycloalkyl group include an adamantyl group, a noradamantyl group, a decalin residue, a tricyclodecanyl group, a tetracyclododecanyl group, a norbornyl group, cedrol group, a cyclopentyl group, a cyclohexyl group, a cycloheptyl group, a cyclooctyl group, a cyclodecanyl group, and a cyclododecanyl group. More preferred examples thereof include an adamantyl group, a norbornyl group, a cyclohexyl group, a cyclopentyl group, a tetracyclododecanyl group, and a tricyclodecanyl group.

Examples of a substituent which may further be included in these alkyl groups and cycloalkyl groups include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). Examples of the substituent which may further be included in the alkyl group, the alkoxy group, the alkoxycarbonyl group, or the like include a hydroxyl group, a halogen atom, and an alkoxy group.

The structures represented by Formulae (pI) to (pV) in the resin can be used in the protection of the alkali-soluble group. Examples of the alkali-soluble group include various groups that have been known in the technical field.

Specific examples of the structure include a structure in which a hydrogen atom in a carboxylic acid group, a sulfonic acid group, a phenol group, or a thiol group is substituted with a structure represented by any one of Formulae (pI) to (pV), with a structure in which a hydrogen atom in a carboxylic acid group or a sulfonic acid group is substituted with a structure represented by any one of Formulae (pI) to (pV) being preferable.

As the repeating unit having an alkali-soluble group protected by the structure represented by each of Formulae (pI) to (pV), a repeating unit represented by Formula (pA) is preferable.

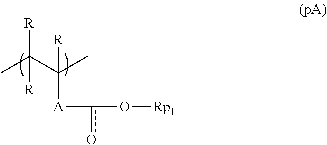

Here, R represents a hydrogen atom, a halogen atom, or a linear or branched alkyl group having 1 to 4 carbon atoms, and a plurality of R's may be the same as or different from each other.

A is a single bond, or one group or a combination of two or more groups selected from the group consisting of an alkylene group, an ether group, a thioether group, a carbonyl group, an ester group, an amido group, a sulfonamido group, a urethane group, or a urea group, with the single bond being preferable.

Rp₁ represents a group of any one of Formulae (pI) to (pV).

The repeating unit represented by Formula (pA) is particularly preferably a repeating unit derived from 2-alkyl-2-adamantyl (meth)acrylate or dialkyl (1-adamantyl)methyl (meth)acrylate.

Specific examples of the repeating unit represented by Formula (pA) are shown below, but the present invention is not limited thereto.

(In the following formulae, Rx represents H, CH₃, or CH₂OH and Rxa and Rxb each represent an alkyl group having 1 to 4 carbon atoms.)

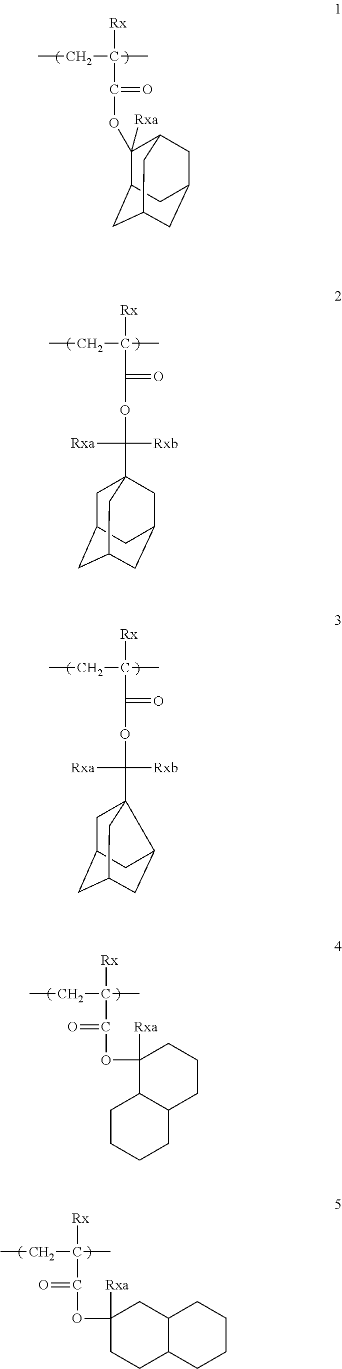

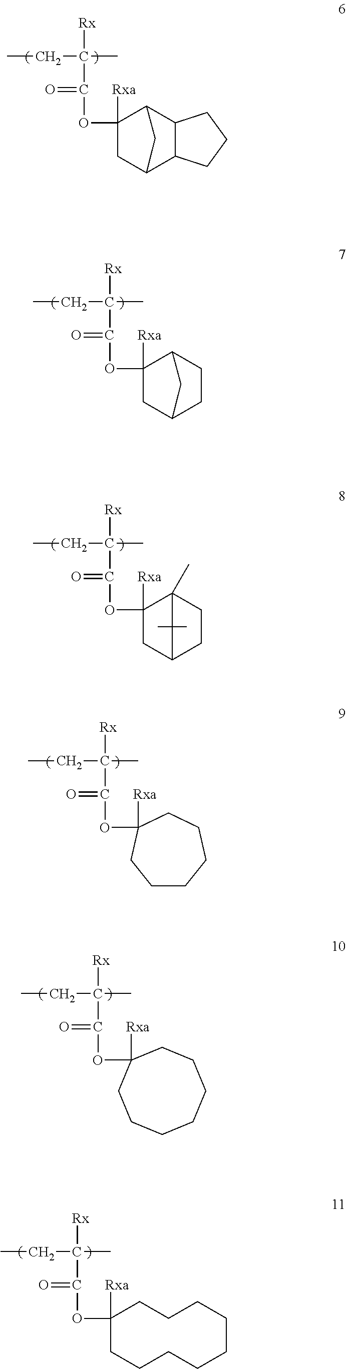

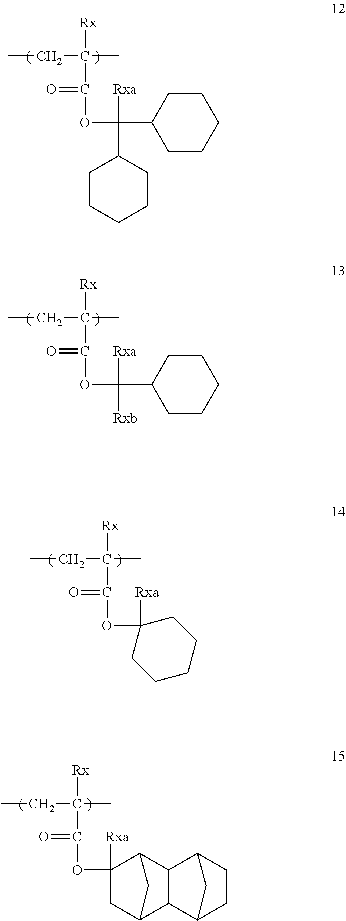

In one aspect, the repeating unit having an acid-decomposable group is an acid-decomposable repeating unit having an acid-leaving group acid-leaving group having 4 to 7 carbon atoms, and preferably satisfies any one condition of the following (i-1) to (iv-1).
(i-1): A resin having a maximum value of the number of carbon atoms of the acid-leaving group a of 4 and a protection rate of 70% by mole or less
(ii-1): A resin having a maximum value of the number of carbon atoms of the acid-leaving group a of 5 and a protection rate of 60% by mole or less
(iii-1): A resin having a maximum value of the number of carbon atoms of the acid-leaving group a of 6 and a protection rate of 47% by mole or less
(iv-1): A resin having a maximum value of the number of carbon atoms of the acid-leaving group a of 7 and a protection rate of 45% by mole or less

However, the protection rate means a ratio of a total of all the acid-decomposable repeating units included in the resin relative to all the repeating units.

In addition, the number of carbon atoms of the acid-leaving group a means the number of carbon included in the leaving group.

Therefore, reduction in a shrinkage amount of the resist film, expansion of depth of focus (DOF), and reduction in line edge roughness (LER) can be realized.

In a case where the resist film is irradiated with KrF excimer laser light, electron beams, X-rays, or high-energy rays (EUV and the like) at a wavelength of 50 nm or less, it is preferable that the resin (A) includes a repeating unit having an aromatic hydrocarbon group, and it is more preferable that the resin (A) includes a repeating unit having a phenolic hydroxyl group. As the repeating unit having a phenolic hydroxyl group, repeating units shown below are particularly preferable.

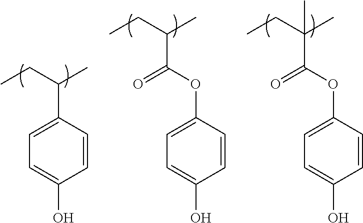

The repeating unit having an acid-decomposable group contained in the resin (A) may be used singly or in combination of two or more kinds thereof.

The resin (A) preferably contains a repeating unit having a lactone structure or a sultone (cyclic sulfonic acid ester) structure.

As the lactone group or the sultone group, any group may be used as long as it has a lactone structure or a sultone structure, but the structure is preferably a 5- to 7-membered ring lactone structure or sultone structure, and preferably a 5- to 7-membered ring lactone structure or sultone structure to which another ring structure is fused in the form of forming a bicyclo structure or a spiro structure. The resin (A) more preferably has a repeating unit having a lactone structure or a sultone structure represented by any one of Formulae (LC1-1) to (LC1-17), (SL1-1), and (SL1-2). Further, the lactone structure or the sultone structure may be bonded directly to the main chain. The lactone structures or the sultone structures are preferably (LC1-1), (LC1-4), (LC1-5), and (LC1-8), and more preferably (LC1-4). By using such a specific lactone structure or sultone structure, LWR and development defects are relieved.

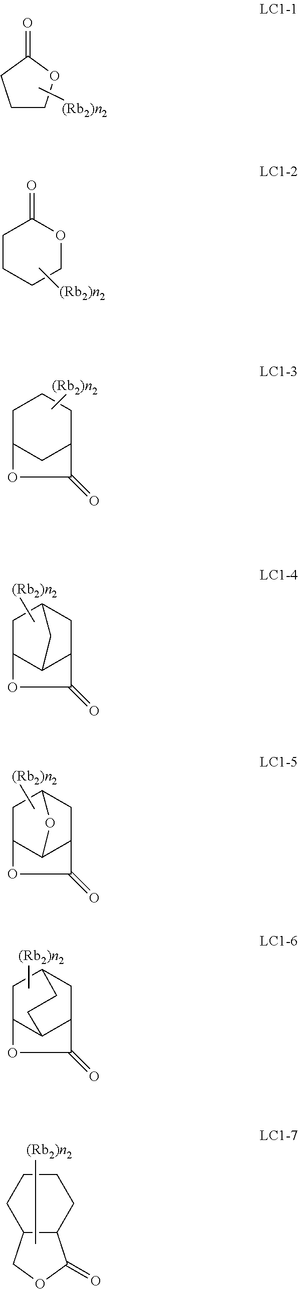

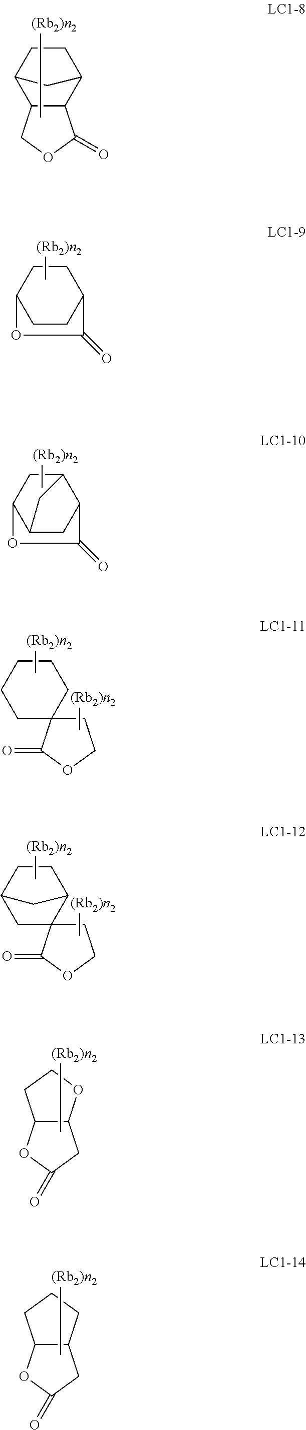

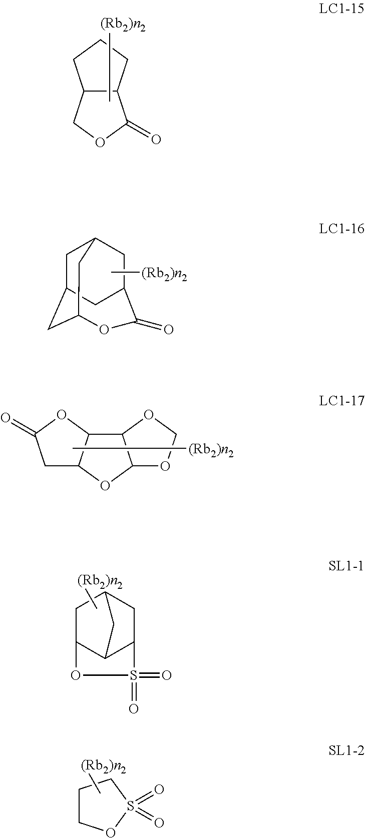

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among those, an alkyl group having 1 to 4 carbon atoms, a cyano group, and an acid-decomposable group are more preferable. n₂ represents an integer of 0 to 4. In a case where n2 is 2 or more, the substituents (Rb₂) which are present in plural numbers may be the same as or different from each other, and further, the substituents (Rb₂) which are present in plural numbers may be bonded to each other to form a ring.

The repeating unit having a lactone group or a sultone group usually has an optical isomer, and any optical isomer may be used. Further, one kind of optical isomer may be used singly or a plurality of optical isomers may be mixed and used. In a case of mainly using one kind of optical isomer, the optical purity (ee) thereof is preferably 90% or more, and more preferably 95% or more.

The content of the repeating unit having a lactone structure or a sultone structure is preferably 15% to 60% by mole, more preferably 20% to 50% by mole, and still more preferably 30% to 50% by mole, with respect to all the repeating units in the resin in a case where the repeating units are contained in a plurality of kinds.

In order to enhance the effects, it is also possible to use two or more kinds of the repeating units having a lactone structure or a sultone structure.

In a case where the actinic ray-sensitive or radiation-sensitive resin composition is to be used for ArF exposure, from the viewpoint of the transparency to the ArF light, it is preferable that the resin (A) does not have an aromatic group.

The resin (A) is preferably a resin in which all the repeating units are composed of (meth)acrylate-based repeating units. In this case, any of the resins in which all the repeating units may be methacrylate-based repeating units, all the repeating units may be acrylate-based repeating units, or all the repeating units may be composed of methacrylate-based repeating units and acrylate-based repeating units can be used, but it is preferable that the acrylate-based repeating units account for 50% by mole or less with respect to all the repeating units.

Preferred examples of the resin (A) include the resins described in paragraphs [0152] to [0158] of JP2008-309878A, but the present invention is not limited thereto.

The resin (A) can be synthesized by an ordinary method (for example, radical polymerization). Examples of the general synthesis method include a batch polymerization method of dissolving monomer species and an initiator in a solvent and heating the solution, thereby carrying out the polymerization, and a dropwise-addition polymerization method of adding dropwise a solution containing monomer species and an initiator to a heated solvent for 1 to 10 hours, with the dropwise-addition polymerization method being preferable. Examples of the reaction solvent include ethers such as tetrahydrofuran, 1,4-dioxane, and diisopropyl ether; ketones such as methyl ethyl ketone and methyl isobutyl ketone; ester solvents such as ethyl acetate, amide solvents such as dimethyl formamide and dimethyl acetamide; and solvents which dissolve the actinic ray-sensitive or radiation-sensitive resin composition, such as propylene glycol monomethyl ether acetate, propylene glycol monomethyl ether, and cyclohexanone, which will be described later. It is more preferable to carry out polymerization using the same solvent as the solvent used in the actinic ray-sensitive or radiation-sensitive resin composition. Thus, generation of the particles during storage can be suppressed.

It is preferable that the polymerization reaction is carried out in an inert gas atmosphere such as nitrogen and/or argon. As the polymerization initiator, commercially available radical initiators (azo-based initiators, peroxides, or the like) are used to initiate the polymerization. As the radical initiator, an azo-based initiator is preferable, and the azo-based initiator having an ester group, a cyano group, or a carboxyl group is preferable. Preferred examples of the initiators include azobisisobutyronitrile, azobisdimethylvaleronitrile, and dimethyl 2,2′-azobis(2-methyl propionate). The initiator is added or added in portionwise, depending on the purposes, and after completion of the reaction, the reaction mixture is poured into a solvent, and then a desired polymer is recovered by a method such as powder and solid recovery. The concentration of the reactant is 5% to 50% by mass, and preferably 10% to 30% by mass. The reaction temperature is usually 10° C. to 150° C., preferably 30° C. to 120° C., and more preferably 60° C. to 100° C.

For the purification, an ordinary method such as a liquid-liquid extraction method of applying water washing or combining it with an appropriate solvent to remove the residual monomers or oligomer components; a purification method in a solution state, such as ultrafiltration of extracting and removing only the polymers having a molecular weight no more than a specific molecular weight; a re-precipitation method of dropwise adding a resin solution into a poor solvent to solidify the resin in the poor solvent, thereby removing the residual monomers and the like; and a purification method in a solid state, such as washing of a resin slurry with a poor solvent after separation of the slurry by filtration can be applied.

The weight-average molecular weight (Mw) of the resin (A) is preferably 1,000 to 200,000, more preferably 1,000 to 20,000, and still more preferably 1,000 to 15,000, as a value in terms of polystyrene by means of gel permeation chromatography (GPC). By setting the weight-average molecular weight to 1,000 to 200,000, the heat resistance or the dry etching resistance can be prevented from being deteriorated, and the film forming properties can be prevented from being deteriorated due to deteriorated developability or increased viscosity.

The dispersity (molecular weight distribution) which is a ratio (Mw/Mn) of the weight-average molecular weight (Mw) to the number-average molecular weight (Mn) in the resin (A) is in a range of usually 1 to 5, preferably 1 to 3, more preferably 1.2 to 3.0, and particularly preferably 1.2 to 2.0 is used. As the dispersity is smaller, the resolution and the pattern shape are excellent, the side wall of the resist pattern is smooth, and the roughness is excellent.

The content of the resin (A) in the entire actinic ray-sensitive or radiation-sensitive resin composition is preferably 50% to 99.9% by mass, and more preferably 60% to 99.0% by mass in the total solid content of the actinic ray-sensitive or radiation-sensitive resin composition.

The resin (A) may be used singly or in combination of a plurality of kinds thereof.

It is preferable that the resin (A) contains neither fluorine atoms nor silicon atoms from the viewpoint of the compatibility with the protective film forming composition.

(B) Compound that Generates Acid Upon Irradiation with Actinic Rays or Radiation

The actinic ray-sensitive or radiation-sensitive resin composition typically contains a compound that generates an acid upon irradiation with actinic rays or radiation (also referred to as a “photoacid generator”).

As such a photoacid generator, a photoacid generator which is appropriately selected from known compounds that generate an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used.

Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

In addition, a compound in which a group or compound that generates an acid upon irradiation with actinic rays or radiation is introduced into the main or side chain of the polymer, for example, the compounds described in U.S. Pat. No. 3,849,137A, GE3914407A, JP1988-26653A (JP-S63-26653A), JP1980-164824A (JPS55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like can be used.

In addition, the compounds that generate an acid by light described in U.S. Pat. No. 3,779,778A, EP 126712B, and the like can also be used.

The photoacid generator contained in the actinic ray-sensitive or radiation-sensitive resin composition is preferably a compound that generates an acid having a cyclic structure upon irradiation with actinic rays or radiation. As the cyclic structure, a monocyclic or polycyclic alicyclic group is preferable, and a polycyclic alicyclic group is more preferable. It is preferable that carbonyl carbon is not included as a carbon atom constituting the ring skeleton of the alicyclic group.

Suitable examples of the photoacid generator contained in the actinic ray-sensitive or radiation-sensitive resin composition include a compound (specific acid generator) that generates an acid upon irradiation with actinic rays or radiation, represented by Formula (3).

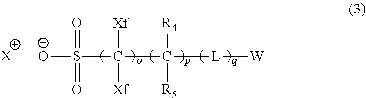

(Anion)

In Formula (3),

Xf's each independently represent a fluorine atom or an alkyl group substituted with at least one fluorine atom.

R₄ and R₅ each independently represent a hydrogen atom, a fluorine atom, an alkyl group, or an alkyl group substituted with at least one fluorine atom, and in a case where R₄ and R₅ are present in plural numbers, they may be the same as or different from each other.

L represents a divalent linking group, and in a case where L's are present in plural numbers, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The number of carbon atoms in the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. It is particularly preferable that both Xfs are fluorine atoms.

R₄ and R₅ each independently represent a hydrogen atom, a fluorine atom, an alkyl group, or an alkyl group substituted with at least one fluorine atom, and in a case where R₄ and R₅ are present in plural numbers, they may be the same as or different from each other.

The alkyl group as each of R₄ and R₅ may have a substituent, and preferably has 1 to 4 carbon atoms. R₄ and R₅ are each preferably a hydrogen atom.

Specific examples and suitable embodiments of the alkyl group substituted with at least one fluorine atom are the same as the specific examples and suitable embodiments of Xf in Formula (3).

L represents a divalent linking group, and in a case where L's are present in plural numbers, they may be the same as or different from each other.

Examples of the divalent linking group include —COO—(—C(═O)—O—), —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. Among those, —COO—, —OCO—, —CONH—, —NHCO—, —CO—, —O—, —SO₂-, —COO-alkylene group-, —OCO-alkylene group-, —CONH-alkylene group-, or —NHCO-alkylene group- is preferable, and —COO—, —OCO—, —CONH—, —SO₂-, —COO-alkylene group-, or —OCO-alkylene group- is more preferable.

W represents an organic group including a cyclic structure. Above all, it is preferably a cyclic organic group.

Examples of the cyclic organic group include an alicyclic group, an aryl group, and a heterocyclic group.

The alicyclic group may be monocyclic or polycyclic, and examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, a diamantyl group, and an adamantyl group is preferable from the viewpoints of inhibiting diffusivity into the film during a post-exposure bake (PEB) process and improving a mask error enhancement factor (MEEF).

The aryl group may be monocyclic or polycyclic. Examples of the aryl group include a phenyl group, a naphthyl group, a phenanthryl group, and an anthryl group. Among those, a naphthyl group showing a relatively low light absorbance at 193 nm is preferable.

The heterocyclic group may be monocyclic or polycyclic, but a polycyclic heterocyclic group can further suppress diffusion of the acid. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle having no aromaticity include a tetrahydropyran ring, a lactone ring, a sultone ring, and a decahydroisoquinoline ring. As a heterocycle in the heterocyclic group, a furan ring, a thiophene ring, a pyridine ring, or a decahydroisoquinoline ring is particularly preferable. Further, examples of the lactone ring and the sultone ring include the lactone structures and the sultone structures exemplified in the above-mentioned resin.

The cyclic organic group may have a substituent. Examples of the substituent include, an alkyl group (which may be either linear or branched, and preferably has 1 to 12 carbon atoms), a cycloalkyl group (which may be any one of monocyclic, polycyclic, and spiro rings, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be a carbonyl carbon.

o represents an integer of 1 to 3. p represents an integer of 0 to 10. q represents an integer of 0 to 10.

In one aspect, it is preferable that in Formula (3), o is an integer of 1 to 3, p is an integer of 1 to 10, and q is 0. Xf is preferably a fluorine atom, R₄ and R₅ are preferably both hydrogen atoms, and W is preferably a polycyclic hydrocarbon group. o is more preferably 1 or 2, and still more preferably 1. p is more preferably an integer of 1 to 3, still more preferably 1 or 2, and particularly preferably 1. W is more preferably a polycyclic cycloalkyl group, and still more preferably an adamantyl group or a diamantyl group.

In the anion represented by Formula (3), preferred examples of a combination of the partial structures other than W include SO₃⁻—CF₂—CH₂—OCO—, SO₃—CF₂—CHF—CH₂—OCO—, SO₃⁻—CF₂—COO—, SO₃—CF₂—CF₂—CH₂—, and SO₃⁻—CF₂—CH(CF₃)—OCO—.

(Cation)

In Formula (3), X⁺ represents a cation.

X⁺ is not particularly limited as long as it is a cation, but suitable aspects thereof include cations (moieties other than Z⁻) in Formula (ZI) or (ZII) which will be described later.

(Suitable Aspects)

Suitable aspects of the specific acid generator include a compound represented by Formula (ZI) or (ZII).

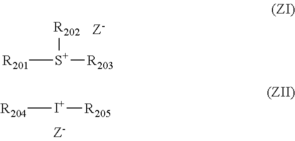

In Formula (ZI),

R₂₀₁, R₂₀₂, and R₂₀₃ each independently represent an organic group.

The number of carbon atoms in the organic group as R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ include an alkylene group (for example, a butylene group and a pentylene group).

Z- represents an anion in Formula (3), and specifically represents the following anion.

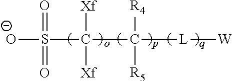

Examples of the organic group represented by R₂₀₁, R₂₀₂, and R₂₀₃ include groups corresponding to the compounds (ZI-1), (ZI-2), (ZI-3), and (ZI-4) which will be described later.

Incidentally, the specific acid generator may be a compound having a plurality of structures represented by Formula (ZI). For example, it may be a compound having a structure in which at least one of R₂₀₁, . . . , or R₂₀₃ in the compound represented by Formula (ZI) is bonded to at least one of R₂₀₁, . . . , or R₂₀₃ of another compound represented by Formula (ZI) through a single bond or a linking group.

More preferred examples of the component (ZI) include the compounds (ZI-1), (ZI-2), (ZI-3), and (ZI-4) described below.

First, the compound (ZI-1) will be described.

The compound (ZI-1) is an arylsulfonium compound, that is, a compound having arylsulfonium as a cation, in which at least one of R₂₀₁, . . . , or R₂₀₃ in Formula (ZI) is an aryl group.

In the arylsulfonium compound, all of R₂₀₁ to R₂₀₃ may be aryl groups, or some of R₂₀₁ to R₂₀₃ may be aryl groups, with the remainder being alkyl groups or cycloalkyl groups.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure containing an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, these two or more aryl groups may be the same as or different from each other.

The alkyl group or the cycloalkyl group which may be contained, as desired, in the arylsulfonium compound, is preferably a linear or branched alkyl group having 1 to 15 carbon atoms or a cycloalkyl group having 3 to 15 carbon atoms, for example, a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of R₂₀₁ to R₂₀₃ may have, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group as the substituent.

Next, the compound (ZI-2) will be described.

The compound (ZI-2) is a compound in which R₂₀₁ to R₂₀₃ in Formula (ZI) each independently represent an organic group not having an aromatic ring. Here, the aromatic ring also encompasses an aromatic ring containing a heteroatom.

The organic group not containing an aromatic ring as R₂₀₁ to R₂₀₃ has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferred examples of the alkyl group and the cycloalkyl group of R₂₀₁ to R₂₀₃ include linear or branched alkyl groups having 1 to 10 carbon atoms (for example, a methyl group, an ethyl group, a propyl group, a butyl group, and a pentyl group), and cycloalkyl groups having 3 to 10 carbon atoms (a cyclopentyl group, a cyclohexyl group, and a norbornyl group).

R₂₀₁ to R₂₀₃ may further be substituted with a halogen atom, an alkoxy group (for example, an alkoxy group having 1 to 5 carbon atoms), a hydroxyl group, a cyano group, or a nitro group.

Next, the compound (ZI-3) will be described.

The compound (ZI-3) is a compound represented by Formula (ZI-3), which is a compound having a phenacylsulfonium salt structure.

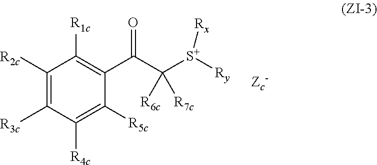

In Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Among any two or more of R_{1c} to R_{5c}, R_{5c} and R_{6c}, R_{6c} and R_{7c}, R_{5c} and Rₓ, and Rₓ and R_{y} each may be bonded to each other to form a ring structure, and the ring structure may include an oxygen atom, a sulfur atom, a ketone group, an ester bond, or an amide bond.

Examples of the ring structure include an aromatic or non-aromatic hydrocarbon ring, an aromatic or non-aromatic heterocycle, or a polycyclic fused ring formed of two or more of these rings. Examples of the ring structure include 3- to 10-membered rings, and the ring structures are preferably 4- to 8-membered ring, and more preferably 5- or 6-membered rings.

Examples of groups formed by the bonding of any two or more of R_{1c} to R_{5c}, R_{6c} and R_{7c}, and Rx and R_{y} include a butylene group and a pentylene group.

As groups formed by the bonding of R_{5c} and R_{6c}, and R_{5c} and Rₓ, a single bond or alkylene group is preferable, and examples of the alkylene group include a methylene group and an ethylene group.

Zc⁻ represents an anion in Formula (3), and specifically, is the same as described above.

Specific examples of the alkoxy group in the alkoxycarbonyl group as R_{1c} to R_{5c} are the same as the specific examples of the alkoxy group as R_{1c} to R₅.

Specific examples of the alkyl group in the alkylcarbonyloxy group and the alkylthio group as R_{1c} to R_{5c} are the same as the specific examples of the alkyl group as R_{1c} to R_{5c}.

Specific examples of the cycloalkyl group in the cycloalkylcarbonyloxy group as R_{1c} to R_{5c} are the same as the specific examples of the cycloalkyl group as R_{1c} to R₅.

Specific examples of the aryl group in the aryloxy group and the arylthio group as R_{1c} to R_{5c} are the same as the specific examples of the aryl group as R_{1c} to R_{5c}.

Examples of the cation in the compound (ZI-2) or (ZI-3) in the present invention include the cations described after paragraph [0036] of US2012/0076996A.

Next, the compound (ZI-4) will be described.

The compound (ZI-4) is represented by Formula (ZI-4).

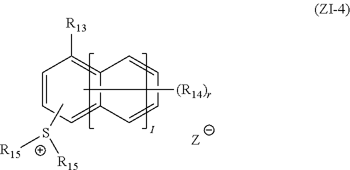

In Formula (ZI-4),
R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where R₁₄'s are present in plural numbers, they each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

R₁₅'s each independently represent an alkyl group, a cycloalkyl group, or a naphthyl group. These groups may have a substituent. Two R₁₅'s may be bonded to each other to form a ring. In a case where two R₁₅'s are bonded to form a ring, the ring skeleton may include a heteroatom such as an oxygen atom and a nitrogen atom. In one aspect, it is preferable that two R₁₅'s are alkylene groups, and are bonded to each other to form a ring structure.

1 represents an integer of 0 to 2.

r represents an integer of 0 to 8.

Z⁻ represents an anion in Formula (3), and specifically, it is as described above.

In Formula (ZI-4), the alkyl group of each of R₁₃, R₁₄, and R₁₅ is preferably an alkyl which is linear or branched and has 1 to 10 carbon atoms, and preferably a methyl group, an ethyl group, an n-butyl group, a t-butyl group, or the like.

Examples of the cation of the compound represented by Formula (ZI-4) in the present invention include the cations described in paragraphs [0121], [0123], and [0124] of JP2010-256842A, paragraphs [0127], [0129], [0130], and the like of JP2011-76056A, and the like.

Next, Formula (ZII) will be described.

In Formula (ZII), R₂₀₄ and R₂₀₅ each independently represent an aryl group, an alkyl group, or a cycloalkyl group.

The aryl group of each of R₂₀₄ and R₂₀₅ is preferably a phenyl group or a naphthyl group, and more preferably a phenyl group. The aryl group of each of R₂₀₄ and R₂₀₅ may be an aryl group having a heterocyclic structure containing an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group in each of R₂₀₄ and R₂₀₅ include linear or branched alkyl groups having 1 to 10 carbon atoms (for example, a methyl group, an ethyl group, a propyl group, a butyl group, and a pentyl group), and cycloalkyl groups having 3 to 10 carbon atoms (a cyclopentyl group, a cyclohexyl group, and a norbomyl group).

The aryl group, the alkyl group, or the cycloalkyl group of each of R₂₀₄ and R₂₀₅ may have a substituent. Examples of the substituent which the aryl group, the alkyl group, or the cycloalkyl group of each of R₂₀₄ and R₂₀₅ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents an anion in Formula (3), and specifically, is as described above.

In one aspect, the molecular weight of the acid generator is preferably 870 or less, more preferably 800 or less, still more preferably 700 or less, and particularly preferably 600 or less. Thus, DOF and LER are improved.

In addition, in the present invention, in a case where the compound that generates upon irradiation of actinic rays or radiation has a distribution with the molecular weights, the value of the weight-average molecular weight is handled in terms of a molecular weight.

The acid generators may be used singly or in combination of two or more kinds thereof.

The content of the acid generator (a total sum of contents in a case where the acid generators are present in a plurality of kinds) in the composition is preferably 0.1% to 30% by mass, more preferably 0.5% to 25% by mass, still more preferably 3% to 20% by mass, and particularly preferably 3% to 15% by mass, with respect to the total solid content of the composition.

In the case where the composition includes a compound represented by Formula (ZI-3) or (ZI-4) as the acid generator, the content of the acid generator (the total content in a case where a plurality of kinds of the acid generators are present) is preferably 5% to 35% by mass, more preferably 8% to 30% by mass, still more preferably 9% to 30% by mass, and particularly preferably 9% to 25% by mass, with respect to the total solid content of the composition.

(C) Solvent

Examples of the solvent which can be used in a case where the respective components are dissolved to prepare an actinic ray-sensitive or radiation-sensitive resin composition include organic solvents such as alkylene glycol monoalkyl ether carboxylate, alkylene glycol monoalkyl ether, alkyl lactate ester, alkyl alkoxypropionate, a cyclic lactone having 4 to 10 carbon atoms, a monoketone compound having 4 to 10 carbon atoms, which may have a ring, alkylene carbonate, alkyl alkoxyacetate, and alkyl pyruvate.

Preferred examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferred examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferred examples of the alkyl lactate ester include methyl lactate, ethyl lactate, propyl lactate, and butyl lactate.

Preferred examples of the alkyl alkoxypropionate include ethyl 3-ethoxypropionate, methyl 3-methoxypropionate, methyl 3-ethoxypropionate, and ethyl 3-methoxypropionate.

Preferred examples of the cyclic lactone having 4 to 10 carbon atoms include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Preferred examples of the monoketone compound having 4 to 10 carbon atoms, which may contain a ring, include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferred examples of the alkylene carbonate include propylene carbonate, vinylene carbonate, ethylene carbonate, and butylene carbonate.

Preferred examples of the alkyl alkoxyacetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferred examples of the alkyl pyruvate include methyl pyruvate, ethyl pyruvate, and propyl pyruvate.

Examples of the solvent that can be preferably used include solvents having a boiling point of 130° C. or higher under the conditions of normal temperature and normal pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate, propylene carbonate, butyl butanoate, isoamyl acetate, and methyl 2-hydroxyisobutyrate.

The solvents may be used singly or in combination of two or more kinds thereof.

A mixed solvent obtained by mixing a solvent containing a hydroxyl group in its structure with a solvent not containing a hydroxyl group in its structure may be used as the organic solvent.

Examples of the solvent containing a hydroxyl group include ethylene glycol, ethylene glycol monomethyl ether, ethylene glycol monoethyl ether, propylene glycol, propylene glycol monomethyl ether, propylene glycol monoethyl ether, and ethyl lactate, and among these, propylene glycol monomethyl ether and ethyl lactate are particularly preferable.

Examples of the solvent not containing a hydroxyl group include propylene glycol monomethyl ether acetate, ethylethoxypropionate, 2-heptanone, γ-butyrolactone, cyclohexanone, butyl acetate, N-methylpyrrolidone, N,N-dimethylacetamide, and dimethylsulfoxide, and among these, propylene glycol monomethyl ether acetate, ethylethoxypropionate, 2-heptanone, γ-butyrolactone, cyclohexanone, and butyl acetate are particularly preferable, and propylene glycol monomethyl ether acetate, ethylethoxypropionate, and 2-heptanone are most preferable.

The mixing ratio (mass ratio) of the solvent containing a hydroxyl group to the solvent not containing a hydroxyl group is 1/99 to 99/1, preferably 10/90 to 90/10, and more preferably 20/80 to 60/40. A mixed solvent including the solvent not containing a hydroxyl group in the amount of 50% by mass or more is particularly preferable from the viewpoint of coating evenness.

The solvent is preferably a mixed solvent of two or more kinds of solvents containing propylene glycol monomethyl ether acetate.

(D) Basic Compound

The actinic ray-sensitive or radiation-sensitive resin composition preferably contains a basic compound in order to reduce a change in performance over time from exposure to heating.

Moreover, from the viewpoint of DOF and EL performance, it is preferable that the actinic ray-sensitive or radiation-sensitive resin composition contains the basic compound. That is, the basic compound contained in the actinic ray-sensitive or radiation-sensitive resin composition is transferred to the protective film during the prebake of the formed protective film, and some of the basic compound returns to the unexposed area of the actinic ray-sensitive or radiation-sensitive film during PEB. In this case, the exposed area has a decrease in the basic compound, and thus, an acid easily diffuses, whereas the unexposed area has an increase in the basic compound, and thus, an acid hardly diffuses. As a result of such an increase in the contrast of the acid diffusion between the exposed area and the unexposed area of the actinic ray-sensitive or radiation-sensitive film, DOF and EL are further improved.

Preferred examples of the basic compound include compounds having structures represented by Formulae (A) to (E).

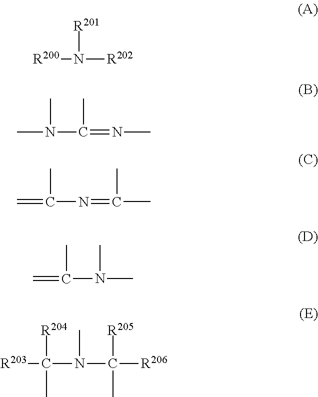

In Formulae (A) to (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), in which R²⁰¹ and R²⁰² may be bonded to each other to form a ring.

With respect to the alkyl group, as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁵, and R²⁶ may be the same as or different from each other, and each represent an alkyl group having 1 to 20 carbon atoms.

The alkyl group in Formulae (A) to (E) is more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure or a pyridine structure, an alkylamine derivative having a hydroxyl group and/or an ether bond, and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide and 2-oxopropylthiophenium hydroxide. The compound having an onium carboxylate structure is formed by carboxylation of an anionic moiety of a compound having an onium hydroxide structure, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Furthermore, the compounds described as the basic compound (XC) contained in the protective film forming composition (also referred to as an upper layer film forming composition or a topcoat composition) as described above can also be suitably used as the basic compound.

These basic compounds may be used singly or in combination of two or more kinds thereof.

The amount of the basic compound to be used is usually 0.001% to 10% by mass, and preferably 0.01% to 5% by mass, with respect to the solid content of the actinic ray-sensitive or radiation-sensitive resin composition.

The ratio between the photoacid generator to the basic compound to be used in the actinic ray-sensitive or radiation-sensitive resin composition is preferably the photoacid generator/basic compound (molar ratio)=2.5 to 300. That is, the molar ratio is preferably 2.5 or more in view of sensitivity and resolution, and is preferably 300 or less in view of suppressing the reduction in resolution due to thickening of the resist pattern with aging after exposure until the heat treatment. The photoacid generator/basic compound (molar ratio) is more preferably 5.0 to 200, and still more preferably 7.0 to 150.

(E) Hydrophobic Resin

The actinic ray-sensitive or radiation-sensitive resin composition may contain a hydrophobic resin (E). As the hydrophobic resin, for example, the above-mentioned resin (XB) which is contained in the protective film forming composition can be suitably used. Further, other suitable examples of the hydrophobic resin include “[4] Hydrophobic Resin (D)” described in paragraphs [0389] to [0474] of JP2014-149409A.

The weight-average molecular weight of the hydrophobic resin (E) in terms of standard polystyrene is preferably 1,000 to 100,000, more preferably 1,000 to 50,000, and still more preferably 2,000 to 15,000.

Furthermore, the hydrophobic resin (E) may be used singly or in combination of a plurality of kinds thereof.

The content of the hydrophobic resin (E) in the composition is preferably 0.01% to 10% by mass, more preferably 0.05% to 8% by mass, and still more preferably 0.1% to 7% by mass, with respect to the total solid content in the actinic ray-sensitive or radiation-sensitive resin composition.

(F) Surfactant

The actinic ray-sensitive or radiation-sensitive resin composition preferably further contains a surfactant (F), and more preferably contains either one or two or more of fluorine-based and/or silicon-based surfactants (a fluorine-based surfactant, a silicon-based surfactant, or a surfactant containing both a fluorine atom and a silicon atom).

By incorporating the surfactant (F) into the actinic ray-sensitive or radiation-sensitive resin composition, it becomes possible to form a resist pattern which is decreased in adhesiveness and development defects with good sensitivity and resolution at the time of using an exposure light source of 250 nm or less, and particularly 220 nm or less.

Examples of the fluorine-based and/or silicon-based surfactants include the surfactants described in JP1987-36663A (JP-S62-36663A), JP 1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), JP2002-277862A, U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and the following commercially available surfactants may be used as they are.

Examples of the commercially available surfactants that can be used include fluorine-based surfactants or silicon-based surfactants such as EFTOP EF301 and EF303 (manufactured by Shin-Akita Kasei K. K.), FLORAD FC430, 431, and 4430 (manufactured by Sumitomo 3M Inc.), MEGAFAC F171, F173, F176, F189, F113, F110, F177, F120, and R08 (manufactured by DIC Corp.), SURFLON S-382, SC101, 102, 103, 104, 105, and 106 (manufactured by Asahi Glass Co., Ltd.), TROYSOL S-366 (manufactured by Troy Chemical Corp.), GF-300 and GF-150 (manufactured by Toagosei Chemical Industry Co., Ltd.), SURFLON S-393 (manufactured by Seimi Chemical Co., Ltd.), EFTOP EF121, EFI22A, EFI22B, RFI22C, EF125M, EF135M, EF351, EF352, EF801, EF802, and EF601 (manufactured by JEMCO Inc.), PF636, PF656, PF6320, and PF6520 (manufactured by OMNOVA Solutions Inc.), and FTX-204G, 208G, 218G, 230G, 204D, 208D, 212D, 218D, and 222D (manufactured by NEOS COMPANY LIMITED). In addition, Polysiloxane Polymer KP-341 (manufactured by Shin-Etsu Chemical Co., Ltd.) can also be used as the silicon-based surfactant.

Furthermore, in addition to those known surfactants as described above, a surfactant using a polymer having a fluoroaliphatic group derived from a fluoroaliphatic compound which is produced by a telomerization method (also referred to as a telomer method) or an oligomerization method (also referred to as an oligomer method), can be used as the surfactant. The fluoroaliphatic compound can be synthesized in accordance with the method described in JP2002-90991A.

As the polymer having a fluoroaliphatic group, copolymers of monomers having fluoroaliphatic groups and (poly(oxyalkylene)) acrylate and/or (poly(oxyalkylene)) methacrylate are preferable, and they may be distributed at random or may be block copolymerized. Further, examples of the poly(oxyalkylene) group include a poly(oxyethylene) group, a poly(oxypropylene) group, and a poly(oxybutylene) group. Incidentally, the polymers may be units having alkylenes different in chain length in the same chain length, such as a poly(block combination of oxyethylene, oxypropylene, and oxybutylene), and poly(block combination of oxyethylene and oxypropylene). In addition, the copolymers of monomers having fluoroaliphatic groups and (poly(oxyalkylene)) acrylate (or methacrylate) may not be only binary copolymers but also ternary or higher copolymers obtained by copolymerization of monomers having different two or more kinds of fluoroaliphatic groups or different two or more kinds of (poly(oxyalkylene)) acrylates (or methacrylates) or the like at the same time.

Examples of the commercially available surfactants include MEGAFAC F178, F-470, F-473, F-475, F-476, and F-472 (manufactured by DIC Corp.); a copolymer of an acrylate (or methacrylate) having a C₆F₁₃ group with a (poly(oxyalkylene)) acrylate (or methacrylate); and a copolymer of an acrylate (or methacrylate) having a C₃F₇ group with a (poly(oxyethylene)) acrylate (or methacrylate) and a (poly(oxypropylene)) acrylate (or methacrylate).

Moreover, surfactants other than fluorine-based and/or silicon-based surfactants can also be used. Specific examples thereof include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonylphenol ether, polyoxyethylenelpolyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

These surfactants may be used singly or in combination of some kinds thereof.

The amount of the surfactant (F) to be used is preferably 0.01% to 10% by mass, and more preferably 0.1% to 5% by mass, with respect to the total amount (excluding the solvent) of the actinic ray-sensitive or radiation-sensitive resin composition.

(G) Onium Carboxylate Salt

The actinic ray-sensitive or radiation-sensitive resin composition may contain an onium carboxylate salt (G). Examples of the onium carboxylate salt include a sulfonium carboxylate salt, an iodonium carboxylate salt, and an ammonium carboxylate salt. In particular, as the onium carboxylate salt (G), an iodonium salt and a sulfonium salt are preferable. Further, it is preferable that the carboxylate residue of the onium carboxylate salt (G) does not contain an aromatic group and a carbon-carbon double bond. As a particularly preferred anionic moiety, a linear, branched, or cyclic (monocyclic or polycyclic) alkylcarboxylate anion having 1 to 30 carbon atoms is preferable. Further, a carboxylate anion in which a part or all of the alkyl groups are substituted with fluorine is more preferable. An oxygen atom may be contained in the alkyl chain, by which the transparency to the light at 220 nm or less is ensured, thus, sensitivity and resolving power are enhanced, and density dependency and exposure margin are improved.

Examples of the anion of the fluorine-substituted carboxylate include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid.

These onium carboxylate salts (G) can be synthesized by reacting sulfonium hydroxide, iodonium hydroxide, or ammonium hydroxide and carboxylic acid with silver oxide in an appropriate solvent.

The content of the onium carboxylate salt (G) in the composition is generally 0.1% to 20% by mass, preferably 0.5% to 10% by mass, and more preferably 1% to 7% by mass, with respect to the total solid contents of the actinic ray-sensitive or radiation-sensitive resin composition.

(H) Other Additives

The actinic ray-sensitive or radiation-sensitive resin composition can further contain a dye, a plasticizer, a light sensitizer, a light absorbent, an alkali-soluble resin, a dissolution inhibitor, a compound that promotes solubility in a developer (for example, a phenol compound with a molecular weight of 1,000 or less, an alicyclic or aliphatic compound having a carboxyl group), and the like, as desired.

Such a phenol compound having a molecular weight of 1,000 or less may be easily synthesized by those skilled in the art with reference to the method described in, for example, JP1992-122938A (JP-H04-122938A), JP1990-28531A (JP-H02-28531A), U.S. Pat. No. 4,916,210A, EP219294B, and the like.

Specific examples of the alicyclic or aliphatic compound having a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

Examples of a method for forming the actinic ray-sensitive or radiation-sensitive film on the substrate include a method in which an actinic ray-sensitive or radiation-sensitive resin composition is applied onto a substrate. The application method is not particularly limited, and a spin coating method, a spray method, a roll coating method, a dip method, or the like, which is known in the related art, can be used, with the spin coating method being preferable.

After forming the actinic ray-sensitive or radiation-sensitive film, the substrate may be heated (prebaked (PB)), as desired. Thus, a film from which insoluble residual solvents have been removed can be uniformly formed. The temperature for a prebake after forming the actinic ray-sensitive or radiation-sensitive film in the step a is not particularly limited, but is preferably 50° C. to 160° C., and more preferably 60° C. to 140° C.

The substrate on which the actinic ray-sensitive or radiation-sensitive film is formed is not particularly limited, and it is possible to use a substrate generally used in a process for manufacturing a semiconductor such as an integrated circuit (IC), a process for manufacturing a circuit board for a liquid crystal, a thermal head, or the like, and other lithographic processes of photofabrication, and examples thereof include inorganic substrates such as silicon, SiO₂, and SiN, and coating type inorganic substrates such as spin on glass (SOG).

Prior to forming the actinic ray-sensitive or radiation-sensitive film, an antireflection film may be applied onto the substrate in advance.

As the antireflection film, any type of an inorganic film type such as titanium, titanium dioxide, titanium nitride, chromium oxide, carbon, and amorphous silicon, and an organic film type formed of a light absorber and a polymer material can be used. In addition, as the organic antireflection film, a commercially available organic antireflection film such as DUV-30 series or DUV-40 series manufactured by Brewer Science, Inc., AR-2, AR-3, or AR-5 manufactured by Shipley Company, L.L.C., or ARC series such as ARC29A manufactured by Nissan Chemical Industries, Ltd. can also be used.

[Step b]

In the step b, a protective film is formed on the actinic ray-sensitive or radiation-sensitive film formed in the step a, using a protective film forming composition (topcoat composition). Examples of a method for forming the protective film include a method in which a protective film forming composition is applied onto an actinic ray-sensitive or radiation-sensitive film. The application method is not particularly limited, and examples thereof include the same method as the above-mentioned application method for the actinic ray-sensitive or radiation-sensitive resin composition.

Thereafter, heating (prebaking (PB)) may be carried out. By the prebake after forming the protective film, the receding contact angle for water on the surface of the protective film can increase, and DOF and EL performance can be improved, which is thus preferable.

The receding contact angle for water on the surface of the protective film is preferably 80° or more, and more preferably 850 or more. The upper limit value is not particularly limited, but is preferably, for example, 100° or less.

Here, the receding contact angle for water in the present specification refers to a receding contact angle at a temperature of 23° C. and a relative humidity of 45%.

Furthermore, an advancing contact angle for water on a surface of the protective film is not particularly limited, but is preferably 90° to 120°, and more preferably 90° to 110°.

In the present specification, the receding contact angle and the advancing contact angle of water on a surface of the protective film are measured as follows.

The protective film forming composition is applied onto a silicon wafer by spin coating, and dried at 100° C. for 60 seconds to form a film (with a film thickness of 120 nm), and the advancing contact angle and the receding contact angle of water droplets are measured by an expansion/contraction method, using a dynamic contact angle meter (for example, manufactured by Kyowa Interface Science Co. Ltd.).

That is, liquid droplets (with an initial liquid droplet size of 35 μL) were added dropwise onto the surface of a protective film (topcoat), and then discharged or sucked at a rate of 6 μL/sec for 5 seconds, and the advancing contact angle at which the dynamic contact angle during the discharge is stabilized, and the receding contact angle at which the dynamic contact angle during the suction is stabilized are determined. The measurement environment is as follows: 23° C.±3° C. and a relative humidity of 45%±5%.

In the liquid immersion exposure, in a view that the immersion liquid needs to move on a substrate following the movement of an exposure head that is scanning the substrate at a high speed and forming an exposure pattern, the contact angle of the immersion liquid for a resist film in a dynamic state is important, and in order to obtain better resist performance, the immersion liquid preferably has a receding contact angle in the above range.

For a reason that the effects of the present invention are more excellent, the prebaking temperature (hereinafter also referred to as a “PB temperature”) at a time after forming the protective film in the step b is preferably 100° C. or higher, more preferably 105° C. or higher, still more preferably 110C or higher, particularly preferably 120° C. or higher, and most preferably more than 120° C.

The upper limit value of the PB temperature after formation of the protective film is not particularly limited, but it may be, for example, 200° C. or lower, and is preferably 170° C. or lower, more preferably 160° C. or lower, and still more preferably 150° C. or lower.

In a case where the exposure of the step c which will be described later is liquid immersion exposure, the protective film is arranged between the resist film and the immersion liquid, and the resist film functions as a layer which is not brought into direct contact with the immersion liquid. In this case, preferred characteristics required for the protective film (protective film forming composition) are coating suitability onto the resist film, transparency to radiation, particularly to a wavelength of 193 nm, and poor solubility in an immersion liquid (preferably water). Further, it is preferable that the protective film forming composition is not mixed with the resist film, and can be uniformly applied onto the surface of the resist film.

Moreover, in order to uniformly apply the protective film forming composition onto the surface of the resist film while not dissolving the resist film, it is preferable that the protective film forming composition contains a solvent in which the resist film is not dissolved. It is more preferable that a solvent with components other than a developer which will be described later is used as the solvent in which the resist film is not dissolved. A method for applying the protective film forming composition is not particularly limited, and a spin coating method, a spray method, a roll coating method, a dip method, or the like known in the related art can be used.

The film thickness of the protective film is not particularly limited, but from the viewpoint of transparency to an exposure light source, the topcoat with a thickness of usually 5 nm to 300 nm, preferably 10 nm to 300 nm, more preferably 20 nm to 200 nm, and still more preferably 30 nm to 100 nm is formed.

After forming the protective film, the substrate is heated, as desired.

From the viewpoint of resolution, it is preferable that the refractive index of the protective film is close to that of the resist film.

The protective film is preferably insoluble in an immersion liquid, and more preferably insoluble in water.

In a case where the protective film is peeled, an organic developer which will be described later may be used, and another peeling solution may also be used. As the peeling solution, a solvent hardly permeating the resist film is preferable. In a view that the peeling of the protective film can be carried out simultaneously with the development of the resist film, the protective film is preferably peelable with an organic developer. The organic developer used for the peeling is not particularly limited as long as it makes it possible to dissolve and remove a less exposed area of the resist film. The organic developer can be selected from developers including a polar solvent such as a ketone-based solvent, an ester-based solvent, an alcohol-based solvent, an amide-based solvent, and an ether-based solvent, and a hydrocarbon-based solvent, which will be described later. A developer including a ketone-based solvent, an ester-based solvent, an alcohol-based solvent, or an ether-based solvent is preferable, a developer including an ester-based solvent is more preferable, and a developer including butyl acetate is still more preferable.

From the viewpoint of performing the peeling using an organic developer, the dissolution rate of the protective film in the organic developer is preferably 1 to 300 nm/sec, and more preferably 10 to 100 nm/sec.

Here, the dissolution rate of an protective film in the organic developer refers to a film thickness decreasing rate in a case where the protective film is exposed to a developer after film formation, and is a rate in a case where the protective film is immersed in a butyl acetate solution at 23° C. in the present specification.

An effect of reducing development defects after developing a resist film is accomplished by setting the dissolution rate of a protective film in the organic developer to 1 nm/sec or more, and preferably 10 nm/sec or more. Further, an effect that the line edge roughness of a pattern after the development of the resist film becomes better is accomplished as an effect of reducing the exposure unevenness during liquid immersion exposure by setting the dissolution rate to 300 nm/sec or less, and preferably 100 nm/sec.

The protective film may also be removed using other known developers, for example, an aqueous alkali solution. Specific examples of the usable aqueous alkali solution include an aqueous tetramethylammonium hydroxide solution.

[Step c]

In the step c, a laminate film including the resist film and the protective film formed thereon is subjected to exposure. The exposure in the step c can be carried out by a known method, and for example, the laminate film is irradiated with actinic rays or radiation through a predetermined mask. Here, the laminate film is preferably irradiated with actinic rays or radiation through an immersion liquid, but is not limited thereto. The exposure dose can be appropriately set, but is usually 1 to 100 mJ/cm².

The wavelength of the light source used in the exposure device in the present invention is not particularly limited, but light at a wavelength of 250 nm or less is preferably used, and examples thereof include KrF excimer laser light (248 nm), ArF excimer laser light (193 nm), F₂ excimer laser light (157 nm), EUV light (13.5 nm), and electron beams. Among these, ArF excimer laser light (193 nm) is preferably used.

In a case of carrying out liquid immersion exposure, before the exposure and/or after the exposure, the surface of the laminate film may be washed with a water-based chemical before carrying out the heating (PEB) which will be described later.

The immersion liquid is preferably a liquid which is transparent to exposure wavelength and has a minimum temperature coefficient of a refractive index so as to minimize the distortion of an optical image projected on the film. In particular, in a case where the exposure light source is an ArF excimer laser light (wavelength; 193 nm), water is preferably used in terms of easy availability and easy handling, in addition to the above-mentioned viewpoints.

In a case of using water, an additive (liquid) that decreases the surface tension of water while increasing the interfacial activity may be added to water at a slight proportion. It is preferable that this additive does not dissolve the resist film on a substrate, and has a negligible effect on the optical coat at the undersurface of a lens element. Water to be used is preferably distilled water. Further, pure water which has been subjected to filtration through an ion exchange filter or the like may also be used. Thus, it is possible to suppress the distortion of an optical image projected on the resist film by the incorporation of impurities.

In addition, in a view of further improving the refractive index, a medium having a refractive index of 1.5 or more can also be used. This medium may be either an aqueous solution or an organic solvent.

The pattern forming method of the present invention may also have the step c (exposing step) carried out plural times. In the case, exposure to be carried out plural times may use the same light source or different light sources, but for the first exposure, ArF excimer laser light (wavelength; 193 nm) is preferably used.

After the exposure, it is preferable to perform heating (baking, also referred to as PEB) and development (preferably further rinsing). Thus, a good pattern can be obtained. The temperature for PEB is not particularly limited as long as a good resist pattern is obtained, and is usually 40° C. to 160° C. PEB may be carried out once or plural times.

[Step d]

In the step d, a pattern is formed by carrying out development using a developer. The step d is preferably a step of removing soluble areas of the resist film simultaneously.

As the developer, any of a developer containing an organic solvent and an alkali developer can be used.

Examples of the developer (organic developer) containing an organic solvent, which is used in the step d, include developers containing a polar solvent such as a ketone-based solvent, an ester-based solvent, an alcohol-based solvent, an amide-based solvent, and an ether-based solvent, and a hydrocarbon-based solvent.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate.

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, butyl butanoate, propylene glycol monomethyl ether acetate (PGMEA), ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, and butyl propionate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, propylene glycol, diethylene glycol, and triethylene glycol; and glycol ether-based solvents such as ethylene glycol monomethyl ether, propylene glycol monomethyl ether (PGME), diethylene glycol monomethyl ether, triethylene glycol monoethyl ether, and methoxymethylbutanol.

Examples of the ether-based solvent include, in addition to the glycol ether-based solvents, dioxane and tetrahydrofuran.

As the amide-based solvent, for example, N-methyl-2-pyrrolidone, N,N-dimethylacetamide, N,N-dimethylformamide, hexamethylphosphoric triamide, 1,3-dimethyl-2-imidazolidinone, or the like can be used.

Examples of the hydrocarbon-based solvent include aromatic hydrocarbon-based solvents such as toluene and xylene; and aliphatic hydrocarbon-based solvents such as pentane, hexane, octane, and decane.

A plurality of these solvents may be mixed and used, or the solvent may be mixed with a solvent other than those described above or with water, and used. However, in order to sufficiently exhibit the effects of the present invention, the moisture content in the entire developer is preferably less than 10% by mass, and it is more preferable that the developer contains substantially no moisture.

That is, the amount of the organic solvent to be used with respect to the organic developer is preferably from 90% by mass to 100% by mass, and more preferably from 95% by mass to 100% by mass, with respect to the total amount of the developer.

Among these, as the organic developer, a developer containing at least one organic solvent selected from the group consisting of a ketone-based solvent, an ester-based solvent, an alcohol-based solvent, an amide-based solvent, and an ether-based solvent is preferable, a developer including a ketone-based solvent or an ester-based solvent is more preferable, and a developer including butyl acetate, butyl propionate, or 2-heptanone is still more preferable.

The vapor pressure of the organic developer is preferably 5 kPa or less, more preferably 3 kPa or less, and still more preferably 2 kPa or less, at 20° C. By setting the vapor pressure of the organic developer to 5 kPa or less, the evaporation on a substrate or in a development cup of the developer is suppressed, and the temperature evenness within a substrate plane is improved, whereby the dimensional evenness within a substrate plane is enhanced.

Specific examples of the solvent having a vapor pressure of 5 kPa or less (2 kPa or less) include the solvents described in paragraph [0165] of JP2014-71304A.

An appropriate amount of a surfactant may be added to the organic developer, as desired.

The surfactant is not particularly limited, but for example, an ionic or nonionic, fluorine-based and/or silicon-based surfactant, or the like can be used. Examples of such a fluorine-based and/or silicon-based surfactant include surfactants described in JP 1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, with the nonionic surfactant being preferable.

The amount of the surfactant to be used is usually 0.001% to 5% by mass, preferably 0.005% to 2% by mass, and more preferably 0.01% to 0.5% by mass, with respect to the total amount of the developer.

The organic developer may also include a basic compound. Specific and preferred examples of the basic compound which can be included in the organic developer used in the present invention are the same as those which will be described as the basic compounds XC.

As the alkali developer, for example, aqueous alkali solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; quaternary ammonium salts such as tetramethylammonium hydroxide and tetraethylammonium hydroxide; and cyclic amines such as pyrrole and piperidine; or the like can be used. Among those, an aqueous solution of tetraethylammonium hydroxide is preferably used.

Moreover, alcohols and/or a surfactant can also be added to the aqueous alkali solution in an appropriate amount before use.

The alkali concentration of the alkali developer is usually 0.01% to 20% by mass.

The pH of the alkali developer is usually 10.0 to 15.0.

The time for carrying out development time using an alkali developer is usually 10 to 300 seconds.

The alkali concentration (and the pH) of the alkali developer and the developing time can be appropriately adjusted depending on the patterns to be formed.

Examples of the developing method include a method in which a substrate is immersed in a tank filled with a developer for a certain period of time (a dip method), a method in which a developer is heaped up to the surface of a substrate by surface tension and developed by standing for a certain period of time (a puddle method), a method in which a developer is sprayed on the surface of a substrate (a spray method), and a method in which a developer is continuously discharged on a substrate rotated at a constant rate while scanning a developer discharging nozzle at a constant rate (a dynamic dispense method).

In addition, after the step of carrying out development using a developer, a step of stopping the development with replacement with another solvent may also be included.

A washing step using a rinsing liquid may be included after the step of carrying out development using a developer including an organic solvent.

The rinsing liquid is not particularly limited as long as it does not dissolve a pattern, and a solution including a general organic solvent can be used. As the rinsing liquid, for example, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent, described above as the organic solvent included in the organic developer is preferably used. More preferably, a step of carrying out washing using a rinsing liquid containing at least one organic solvent selected from the group consisting of a hydrocarbon-based solvent, a ketone-based solvent, an ester-based solvent, an alcohol-based solvent, and an amide-based solvent is carried out. Still more preferably, a step of carrying out washing using a rinsing liquid containing a hydrocarbon-based solvent, an alcohol-based solvent, or an ester-based solvent is carried out.

Here, examples of the monohydric alcohol used in the rinsing step include linear, branched, or cyclic monohydric alcohols, and specifically, 1-butanol, 2-butanol, 3-methyl-1-butanol, 3-methyl-2-butanol, tert-butyl alcohol, 1-pentanol, 2-pentanol, 3-methyl-2-pentanol, 4-methyl-2-pentanol, 1-hexanol, 2-hexanol, 3-hexanol, 4-methyl-2-hexanol, 5-methyl-2-hexanol, 1-heptanol, 2-heptanol, 3-heptanol, 4-methyl-2-heptanol, 5-methyl-2-heptanol, 1-octanol, 2-octanol, 3-octanol, 4-octanol, 4-methyl-2-octanol, 5-methyl-2-octanol, 6-methyl-2-octanol, 2-nonanol, 4-methyl-2-nonanol, 5-methyl-2-nonanol, 6-methyl-2-nonanol, 7-methyl-2-nonanol, 2-decanol, or the like can be used, with 1-hexanol, 2-hexanol, 1-pentanol, 3-methyl-1-butanol, or 4-methyl-2-heptanol being preferable.

Furthermore, examples of the hydrocarbon-based solvent used in the rinsing step include aromatic hydrocarbon-based solvents such as toluene and xylene; and aliphatic hydrocarbon-based solvents such as pentane, hexane, octane, decane (n-decane), and undecane.

In a case where an ester-based solvent is used as the organic solvent, a glycol ether-based solvent may be used, in addition to the ester-based solvent (one kind, or two or more kinds). As a specific example thereof in this case, an ester-based solvent (preferably butyl acetate) may be used as a main component, and a glycol ether-based solvent (preferably propylene glycol monomethyl ether (PGME)) may be used as a side component. Thus, residue defects are suppressed.

The respective components in plural numbers may be mixed and used, or the components may be mixed with an organic solvent other than the above solvents, and used.

The moisture content of the rinsing liquid is preferably 10% by mass or less, more preferably 5% by mass or less, and still more preferably 3% by mass or less. By setting the moisture content to 10% by mass or less, good development characteristics can be obtained.

The vapor pressure of the rinsing liquid is preferably 0.05 to 5 kPa, more preferably 0.1 to 5 kPa, and still more preferably 0.12 to 3 kPa, at 20° C. By setting the vapor pressure of the rinsing liquid to 0.05 to 5 kPa, the temperature evenness within a substrate plane is improved, and further, the dimensional evenness within a substrate plane is enhanced by inhibition of swelling due to the permeation of the rinsing liquid.

The rinsing liquid can also be used after adding an appropriate amount of a surfactant thereto.

In the rinsing step, the substrate which has been subjected to development using a developer including an organic solvent is subjected to a washing treatment using the rinsing liquid including the organic solvent. A method for the washing treatment is not particularly limited, and for example, a method in which a rinsing liquid is continuously discharged on a substrate rotated at a constant rate (a rotation application method), a method in which a substrate is immersed in a tank filled with a rinsing liquid for a certain period of time (a dip method), a method in which a rinsing liquid is sprayed onto a substrate surface (a spray method), or the like, can be applied. Among these, a method in which a washing treatment is carried out using the spin coating method, and a substrate is rotated at a rotation speed of 2,000 rpm to 4,000 rpm after washing, and then the rinsing liquid is removed from the substrate, is preferable. Further, it is preferable that a heating step (postbaking) is included after the rinsing step. The residual developer and the rinsing liquid between and inside the patterns are removed by performing the bake. The heating step after the rinsing step is carried out at usually 40° C. to 160° C., and preferably at 70° C. to 95° C., and usually for 10 seconds to 3 minutes, and preferably for 30 seconds to 90 seconds.

Moreover, in the pattern forming method of the present invention, development using an alkali developer may also be carried out after the development using an organic developer. A portion having weak exposure intensity is removed by development using an organic solvent, and a portion having strong exposure intensity is also removed by carrying out development using an alkali developer. By virtue of multiple development processes in which development is carried out in plural times in this manner, a pattern can be formed by keeping only a region with an intermediate exposure intensity from not being dissolved, so that a finer pattern than usual can be formed (the same mechanism as in paragraph [0077] of JP2008-292975A).

Washing may be carried out using a rinsing liquid after the development using an alkali developer, and as the rinsing liquid, pure water is used, or an appropriate amount of a surfactant may be added thereto before the use.

Furthermore, after the developing treatment or the rinsing treatment, a treatment for removing the developer or rinsing liquid adhering on the pattern by a supercritical fluid may be carried out.

In addition, a heating treatment can be carried out in order to remove moisture contents remaining in the pattern after the rinsing treatment or the treatment using a supercritical fluid.

An electrically conductive compound may be added to the protective film forming composition of the present invention in order to prevent failure of chemical liquid pipe and various parts (a filter, an O-ring, a tube, or the like) due to electrostatic charge, and subsequently generated electrostatic discharge. The electrically conductive compound is not particularly limited and examples thereof include methanol. The addition amount is not particularly limited, but it is preferably 10% by mass or less, and more preferably 5% by mass or less. For members of the chemical liquid pipe, various pipes coated with stainless steel (SUS), or a polyethylene, polypropylene, or fluorine resin (a polytetrafluoroethylene or perfluoroalkoxy resin, or the like) that has been subjected to an antistatic treatment can be used. In the same manner, for the filter or the O-ring, polyethylene, polypropylene, or fluorine resin (a polytetrafluoroethylene or perfluoroalkoxy resin, or the like) that has been subjected to an antistatic treatment can be used.

Moreover, generally, the developer and the rinsing liquid are stored in a waste liquid tank through a pipe after use. At that time, there is a method of passing a solvent in which a resist is dissolved again through a pipe in order to prevent the resist dissolved in a developer from being precipitated and adhering to the rear surface of a wafer, the side surface of the pipe, or the like, in a case where a hydrocarbon-based solvent is used as the rinsing liquid. Examples of the method of passing the solvent through the pipe include a method in which the rear surface, the side surface, and the like of a substrate are washed with a solvent in which the resist is dissolved and then the solvent is allowed to flow after washing with a rinsing liquid, and/or a method of flowing a solvent in which a resist is dissolved without being in contact with the resist so as to pass through a pipe.

The solvent to be passed through the pipe is not particularly limited as long as it can dissolve the resist, and examples thereof include the above-mentioned organic solvents. Propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, 1-propanol, acetone, or the like can be used. Among those, PGMEA, PGME, or cyclohexanone can be preferably used.

It is preferable that various materials (for example, an actinic ray-sensitive or radiation-sensitive resin composition, a resist solvent, a developer, a rinsing liquid, and an antireflection film forming composition) used in the protective film forming composition of the present invention and the pattern forming method of the present invention do not include impurities such as metals (solid metals and metal ions). Examples of the metal impurity components include Na, K, Ca, Fe, Cu, Mn, Mg, Al, Cr, Ni, Zn, Ag, Sn, Pb, and Li. The total content of the impurities included in these materials is preferably 1 ppm or less, more preferably 10 ppb or less, still more preferably 100 ppt or less, particularly preferably 10 ppt or less, and most preferably 1 ppt or less.

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. The filter may be formed of a composite material formed by combining this material with an ion exchange medium. The filter which has been washed with an organic solvent in advance may also be used. In the step of filtration using a filter, a plurality of kinds of filters may be connected in series or in parallel, and used. In a case of using a plurality of kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method of selecting raw materials having a small content of metals as raw materials constituting various materials, a method of subjecting raw materials constituting various materials to filtration using a filter, and a method of performing distillation under the condition for suppressing the contamination as much as possible by, for example, lining the inside of a device with TEFLON (registered trademark). The preferred conditions for filtration using a filter, which is carried out for raw materials constituting various materials, are the same as described above.

In addition to the filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

It is necessary to prevent the incorporation of metal impurities in the production process in order to reduce the impurities such as metals included in the various materials. Sufficient removal of metal impurities from a production device can be checked by measuring the content of metal components included in a washing liquid used to wash the production device. The content of the metal components included in the washing liquid after the use is preferably 100 parts per trillion (ppt) or less, more preferably 10 ppt or less, and particularly preferably 1 ppt or less.

A method for improving the surface roughness of the pattern may also be applied to the pattern formed by the pattern forming method of the present invention. Examples of the method for improving the surface roughness of the pattern include a method for treating a resist pattern by plasma of a hydrogen-containing gas disclosed in WO2014/002808A1. In addition, known methods as described in JP2004-235468A, US2010/0020297A, JP2009-19969A, Proc. of SPIE Vol. 8328 83280N-1 “EUV Resist Curing Technique for LWR Reduction and Etch Selectivity Enhancement” may also be applied.

Furthermore, a mold for imprints may be manufactured using the actinic ray-sensitive or radiation-sensitive resin composition of the present invention, and with regard to the details thereof, refer to JP4109085B and JP2008-162101A, for example.

The pattern forming method of the present invention can also be used in formation of a guide pattern (see, for example, ACS Nano Vol. 4 No. 8 Pages 4815 to 4823) in Directed Self-Assembly (DSA).

In addition, a pattern formed by the method can be used as a core material (core) in the spacer process disclosed in, for example, JP1991-270227A (JP-H03-270227A) and JP2013-164509A.

[Method for Manufacturing Electronic Device]

Moreover, the present invention also relates to a method for manufacturing an electronic device, including the above-mentioned pattern forming method of the present invention.

An electronic device manufactured by the method for manufacturing an electronic device of the present invention is suitably mounted in electrical or electronic equipment (household electronic appliance, office automation (OA)/media-related equipment, optical equipment, telecommunication equipment, and the like).

### EXAMPLES

Hereinbelow, the present invention will be described in more detail with reference to Examples. The materials, the amounts of materials used, the proportions, the treatment details, the treatment procedure, or the like shown in the Examples below may be modified if appropriate as long as the modifications do not depart from the spirit of the present invention. Therefore, the scope of the present invention should not be construed as being limited to the Examples shown below. In addition, “parts” and “%” are on a mass basis unless otherwise specified.

[Protective Film Forming Composition]

### Synthesis Example 1: Synthesis of Resin X-1

Under a nitrogen stream, 26.1 g of cyclohexanone was put into a three-neck flask and heated to 85° C. A solution formed by dissolving 10.67 g of a monomer represented by Structural Formula XM-2, 10.71 g of a monomer represented by Structural Formula XM-3, 3.03 g of a monomer represented by Structural Formula XM-8, and a polymerization initiator V-601 (manufactured by Wako pure Chemical industry Co., Ltd., 0.553 g) in 47.6 g of cyclohexanone was added dropwise thereto for 6 hours to obtain a reaction solution. After completion of the dropwise addition, the reaction solution was further reacted at 85° C. for 2 hours. After the reaction solution was left to be cooled and then added dropwise to 1,140 g of methanol for 20 minutes, and the precipitated powder was collected by filtration and dried to obtain a resin X-1 (20.9 g) shown below. The weight-average molecular weight in terms of standard polystyrene and the dispersity (Mw/Mn) of the obtained resin X-1 were 8,000 and 1.69, respectively. The compositional ratio of the repeating unit measured by ¹³C-NMR in terms of a molar ratio was 40/30/30 in the order from the left side in the formulae.

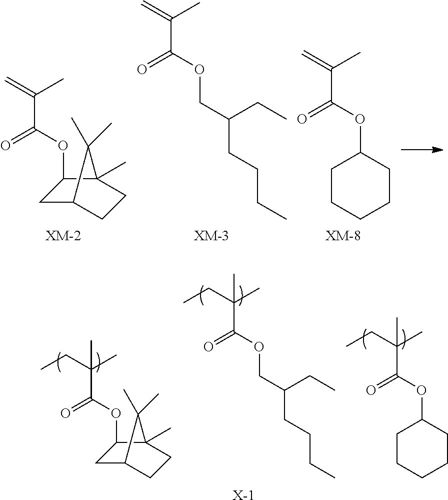

The same operation in Synthesis Example 1 was carried out to synthesize resins X-2 to X-27 exemplified below to be included in a protective film forming composition. Details thereof are shown in Table 1. Further, the resins X-1 to X-18 correspond to the resin XA and the resins X-19 to X-27 correspond to the resin XB.

In Table 1, the resins X-1 to X-27 are resins having repeating units corresponding to any one of monomers XM-1 to XM-26 at the molar ratios shown in Table 1.

Furthermore, the content R^{F} (% by mass) of fluorine atoms in each resin was determined by Equation (1), and then the content M^{F} (% by mass) of fluorine atoms in each monomer was determined by Equation (2).

Content M^{F} (% by Mass) of Fluorine Atoms in Each Monomer

[(Number of fluorine atoms×atomic weight of fluorine atoms in each monomer)/Molecular weight of the monomer]×100 Formula (1)

Content R^{F} (% by Mass) of Fluorine Atoms in Resin

Σ(Molecular weight of each monomer×Content M^{F} of fluorine atoms in each monomer×Compositional ratio of each monomer)/Σ(Molecular weight of each monomer×Compositional ratio of each monomer) Formula (2)

TABLE 1

| Monomer | 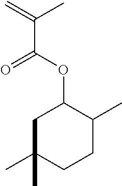 | 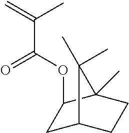 [SMILES: C=C(C)C(=O)OC1CC2CCC1(C)C2(C)C] | 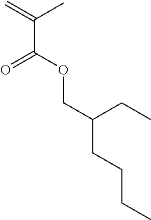 | 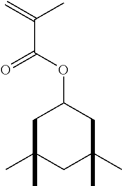 | 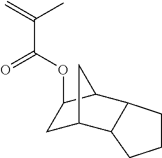 [SMILES: C=C(C)C(=O)OC1CC2CC1C1CCCC21] | 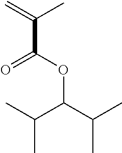 | 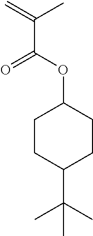 [SMILES: C=C(C)C(=O)OC1CCC(C(C)(C)C)CC1] | 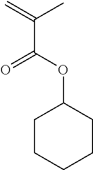 |
|---|---|---|---|---|---|---|---|---|
| | XM-1 | XM-2 | XM-3 | XM-4 | XM-5 | XM-6 | XM-7 | XM-8 |
| Molecular | 210.31 | 222.32 | 198.3 | 224.34 | 220.31 | 184.28 | 224.3 | 168.23 |
| weight of | | | | | | | | |
| monomer | | | | | | | | |
| F content M^{F} | 0% | 0% | 0% | 0% | 0% | 0% | 0% | 0% |
| (% by mass) | | | | | | | | |
| in monomer | | | | | | | | |
| | Compositional ratio (% by mole) | | | | | | | |
| Resin | XM-1 | XM-2 | XM-3 | XM-4 | XM-5 | XM-6 | XM-7 | XM-8 |
| X-1 | | 40 | 30 | | | | | 30 |
| X-2 | | 89 | 9 | | | | | |
| X-3 | | | 30 | 70 | | | | |
| X-4 | | | 18 | | 74 | | | |
| X-5 | | | | | | | 98 | |
| X-6 | 80 | | | | | | | 18 |
| X-7 | | 38 | | | 60 | | | |
| X-8 | 50 | | | | | | | 30 |
| X-9 | | 39 | 29 | | | | | 30 |
| X-10 | | | | | | 65 | | |
| X-11 | | 60 | 40 | | | | | |
| X-12 | | 76 | | | | | | |
| X-13 | | | | | | 40 | 55 | |
| X-14 | | | | | 50 | | | 40 |
| X-15 | | | 40 | | | 60 | | |
| X-16 | | 39 | 29 | | | | | 30 |
| X-17 | | 35 | 50 | | | | | |
| X-18 | | 30 | 50 | | | | | |

| Monomer | 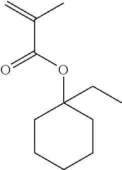 | 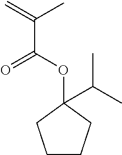 | 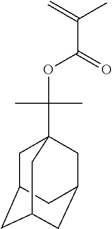 [SMILES: C=C(C)C(=O)OC(C)(C)C12CC3CC(CC(C3)C1)C2] | 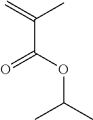 | 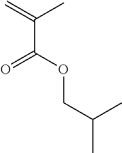 | 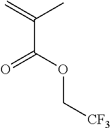 | 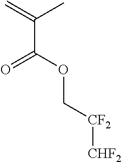 | | | |
|---|---|---|---|---|---|---|---|---|---|---|
| | XM-9 | XM-10 | XM-11 | XM-12 | XM-13 | XM-14 | XM-15 | | | |
| Molecular | 196.29 | 196.29 | 262.39 | 128.17 | 142.2 | 168.11 | 200.13 | | | |
| weight of | | | | | | | | | | |
| monomer | | | | | | | | | | |
| F content M^{F} | 0% | 0% | 0% | 0% | 0% | 34% | 38% | | | |
| (% by mass) | | | | | | | | | | |
| in monomer | | | | | | | | | | |
| | | | | | | | | | | F content R^{F} |
| | Compositional ratio (% by mole) | | | | | | | | | (% by mass) |
| Resin | XM-9 | XM-10 | XM-11 | XM-12 | XM-13 | XM-14 | XM-15 | Mw | Mw/Mn | in resin |
| X-1 | | | | | | | | 8000 | 1.69 | 0.0% |
| X-2 | | | | | | 2 | | 16000 | 1.71 | 0.5% |
| X-3 | | | | | | | | 10000 | 1.68 | 0.0% |
| X-4 | | | | | | 8 | | 9500 | 1.65 | 2.2% |
| X-5 | | | | | | 2 | | 12000 | 1.68 | 0.5% |
| X-6 | | | | | | | 2 | 14500 | 1.63 | 0.8% |
| X-7 | | | | | | 2 | | 9000 | 1.75 | 0.5% |
| X-8 | 20 | | | | | | | 10000 | 1.73 | 0.0% |
| X-9 | | | | | | 2 | | 8000 | 1.63 | 0.6% |
| X-10 | | | | 30 | | | 5 | 27000 | 2.05 | 2.3% |
| X-11 | | | | | | | | 9600 | 1.68 | 0.0% |
| X-12 | | 18 | | | | 6 | | 11000 | 1.59 | 1.6% |
| X-13 | | 5 | | | | | | 9500 | 1.70 | 0.0% |
| X-14 | | | 10 | | | | | 15000 | 1.65 | 0.0% |
| X-15 | | | | | | | | 8500 | 1.63 | 0.0% |
| X-16 | | | | | | 2 | | 8000 | 1.64 | 0.6% |
| X-17 | | | | | | 15 | | 10000 | 1.69 | 4.2% |
| X-18 | | | | | | 20 | | 9500 | 1.70 | 5.7% |

| Monomer | 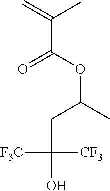 [SMILES: C=C(C)C(=O)OC(C)CC(O)(C(F)(F)F)C(F)(F)F] | 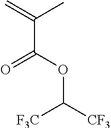 | 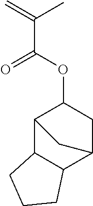 [SMILES: C=C(C)C(=O)OC1CC2CC1C1CCCC21] | 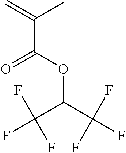 | 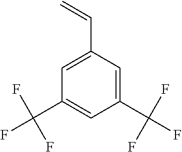 [SMILES: C=Cc1cc(C(F)(F)F)cc(C(F)(F)F)c1] | 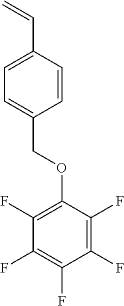 [SMILES: C=Cc1ccc(COc2c(F)c(F)c(F)c(F)c2F)cc1] | 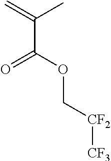 | 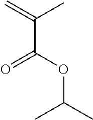 |
|---|---|---|---|---|---|---|---|---|
| | XM-16 | XM-17 | XM-18 | XM-19 | XM-20 | XM-21 | XM-22 | XM-23 |
| Molecular | 294.19 | 236.11 | 220.11 | 236.11 | 240.15 | 300.22 | 218.12 | 128.17 |
| weight of | | | | | | | | |
| monomer | | | | | | | | |
| F content M^{F} | 39% | 48% | 0% | 48% | 48% | 32% | 44% | 0% |
| (% by mass) | | | | | | | | |
| in monomer | | | | | | | | |
| | Compositional ratio (% by mole) | | | | | | | |
| Resin | XM-16 | XM-17 | XM-18 | XM-19 | XM-20 | XM-21 | XM-22 | XM-23 |
| X-19 | | | | 40 | | | | 60 |
| X-20 | | | | | 35 | | | |
| X-21 | | | | | | 30 | | 70 |
| X-22 | | | | 30 | | | | |
| X-23 | | | | | 25 | | | 35 |
| X-24 | | | | 20 | 20 | | | 50 |
| X-25 | | | | 10 | | 25 | | 35 |
| X-26 | | | | 20 | | | 40 | |
| X-27 | | | | | 20 | | | 50 |

| | | | |
|---|---|---|---|
| Monomer | 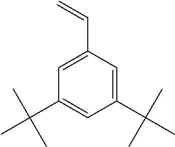 [SMILES: C=Cc1cc(C(C)(C)C)cc(C(C)(C)C)c1] | 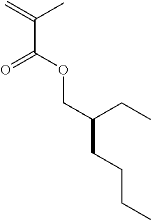 | 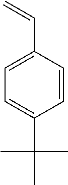 |
| | XM-24 | XM-25 | XM-26 |
| Molecular | 216.36 | 198.3 | 100.20 |
| weight of | | | |
| monomer | | | |
| F content M^{F} | 0% | 0% | 0% |
| (% by mass) | | | |
| in monomer | | | |

| | | | | | | F content R^{F} |
|---|---|---|---|---|---|---|
| | Compositional ratio (% by mole) | | | | | (% by mass) |
| Resin | XM-24 | XM-25 | XM-26 | Mw | Mw/Mn | in resin |
| X-19 | | | | 9000 | 1.65 | 26.5% |
| X-20 | | 65 | | 15000 | 1.71 | 18.7% |
| X-21 | | | | 23000 | 1.56 | 15.8% |
| X-22 | | | 70 | 10000 | 1.72 | 18.6% |
| X-23 | | 40 | | 12000 | 1.58 | 15.5% |
| X-24 | 10 | | | 8000 | 1.60 | 25.1% |
| X-25 | | 30 | | 14000 | 1.66 | 17.3% |
| X-26 | | 40 | | 28000 | 1.57 | 28.4% |
| X-27 | | 30 | | 8000 | 1.60 | 13.3% |

[Preparation of Protective Film Forming Composition]

<Step of Preparing Solvent Having Content of Peroxides of Acceptable Value or Less>

(Step of Measuring or Confirming Content of Peroxides in Solvent)

10 ml of each of the solvents shown in Table 2 (in a case of a mixed solvent, a solvent obtained after mixing) was precisely taken into 200 ml of a flask with a stopper, and 25 ml of an acetic acid:chloroform solution (3:2) was added thereto. To the obtained mixed liquid was added 1 ml of a saturated aqueous potassium iodide solution, followed by mixing, and the mixture was left to stand for 10 minutes in the dark. 30 ml of distilled water and 1 ml of a starch solution were added thereto and titrated with a 0.01 N sodium thiosulfate solution until the mixture became colorless. Next, for a blank test, the above operation was carried out in a state where each of the solvents was not added. The content of peroxides was calculated on the basis of the following equation.

Content (mmol/L) of peroxides=(A−B)×F/Amount (ml) of sample×100÷2

A: Amount (ml) of 0.01 N sodium thiosulfate consumed, which is required for titration

B: Amount (ml) of 0.01 N sodium thiosulfate consumed, which is required for blank test

F: Titer of 0.01 N sodium thiosulfate

In addition, the detection limit of peroxides by the present analysis methods was 0.01 mmol/L.

The content of peroxides in the solvent obtained above was 0.01 to 0.09 mmol/L.

(Step of Comparing Measured or Confirmed Content of Peroxides with Acceptable Value)

A step of defining the acceptable value of the content of peroxides as 0.1 mmol/L, and comparing a content of peroxides with the acceptable value was carried out. It was confirmed that any of the contents of peroxides in the solvents shown in Table 2 were the acceptable value or less.

<Step of Dissolving and Filtering Using Filter>

The respective components shown in Table 2 were dissolved in each solvent shown in Table 2 to prepare a solution having a concentration of solid contents of 3.0% by mass. The solution was filtered through a polyethylene filter with a pore size of 0.04 μm to prepare protective film forming compositions T-1 to T-32, TC-1 to TC-5, and TR-1 to TR-5. In Table 2 below, the contents (% by mass) of the compounds and the surfactants are determined with respect to the total solid content of the protective film forming composition.

Incidentally, the content of each antioxidant in the protective film forming compositions T-1 to T-32 was 300 ppm by mass, with respect to the total solid content of the protective film forming composition.

In addition, for T-30 to T-32, a total amount of the antioxidants used in combination is the concentration, and each of the mixing ratios was 2,6-di-t-butyl-para-cresol/t-butylhydroquinone=1/1, based on mass.

Furthermore, for T-1 to 32, and TC-1 to 5 among the above-mentioned protective film forming compositions, after completing the step of filtering using the filter, each of the compositions was sealed in colorless transparent glass bottles in an atmospheric environment. The glass bottle having each protective film forming composition sealed therein was stored under the condition of a temperature of 40° C. and a humidity of 30% for 6 months, and then the glass bottle was opened to subject each protective film forming composition after storage to evaluation tests which will be described later. In addition, for TR-1 to TR-5, the blending ratio was the same as TC-1 to TC-5, but was subjected to evaluation while not undergoing storage.

TABLE 2

| Protective | | | | | | | | | |
|---|---|---|---|---|---|---|---|---|---|
| film | | | | Basic compound XC | | | | | |
| forming | | | Mass ratio | | Content (% by | Surfactant (% | | | Passage of time |
| composition | Resin XA | Resin XB | (XA/XB) | Type | mass) | by mass) | Solvent XD | Antioxidant | over 6 months |
| T-1 | X-1 | X-19 | 90/10 | XC-1 | 0.7% | — | 4-Methyl-2-pentanol | 2,6-di-t-Butyl-para-cresol | With the |
| | | | | | | | | | passage |
| T-2 | X-2 | X-19 | 90/10 | XC-2 | 5.2% | — | Diisoamyl ether/4-methyl-2-pentanol | 2,6-di-t-Butyl-para-cresol | With the |
| | | | | | | | (20% by mass/80% by mass) | | passage |
| T-3 | X-3 | X-19 | 90/10 | XC-3 | 0.8% | — | 4-Methyl-2-pentanol | 2,6-di-t-Butyl-para-cresol | With the |
| | | | | | | | | | passage |
| T-4 | X-4 | X-19 | 90/10 | XC-4 | 3.6% | W-1 (0.5%) | 4-Methyl-2-pentanol | 2,6-di-t-Butyl-para-cresol | With the |
| | | | | | | | | | passage |
| T-5 | X-5 | X-19 | 90/10 | XC-5 | 0.9% | — | 4-Methyl-1-pentanol | 2,6-di-t-Butyl-para-cresol | With the |
| | | | | | | | | | passage |
| T-6 | X-6 | X-19 | 90/10 | XC-6 | 4.2% | — | 4-Methyl-1-pentanol | 2,6-di-t-Butyl-para-cresol | With the |
| | | | | | | | | | passage |
| T-7 | X-7 | X-19 | 90/10 | XC-7 | 1.1% | — | 4-Methyl-1-pentanol | 2,6-di-t-Butyl-para-cresol | With the |
| | | | | | | | | | passage |
| T-8 | X-8 | X-19 | 90/10 | XC-1 | 0.9% | — | 4-Methyl-2-pentanol | 2,6-di-t-Butyl-para-cresol | With the |
| | | | | | | | | | passage |
| T-9 | X-9 | X-19 | 90/10 | XC-2 | 5.1% | — | 4-Methyl-2-pentanol | 2,6-di-t-Butyl-para-cresol | With the |
| | | | | | | | | | passage |
| T-10 | X-10 | X-19 | 90/10 | XC-3 | 0.8% | — | 4-Methyl-2-pentanol | 2,6-di-t-Butyl-para-cresol | With the |
| | | | | | | | | | passage |
| T-11 | X-11 | X-19 | 90/10 | XC-4 | 2.0% | — | Isobutyl isobutyrate/4-methyl-2-pentanol | 2,6-di-t-Butyl-para-cresol | With the |
| | | | | | | | (60% by mass/40% by mass) | | passage |
| T-12 | X-12 | X-19 | 90/10 | XC-5 | 1.4% | — | 4-Methyl-2-pentanol | 2,6-di-t-Butyl-para-cresol | With the |
| | | | | | | | | | passage |
| T-13 | X-13 | X-19 | 90/10 | XC-2 | 1.5% | — | Diisoamyl ether/4-methyl-2-pentanol (30% by mass/70% by | 2,6-di-t-Butyl-para-cresol | With the |
| | | | | | | | mass) | | passage |
| T-14 | X-14 | X-19 | 90/10 | XC-2 | 1.2% | W-2 (0.8%) | Diisoamyl ether/4-methyl-2-pentanol (10% by mass/90% by | 2,6-di-t-Butyl-para-cresol | With the |
| | | | | | | | mass) | | passage |
| T-15 | X-15 | X-19 | 90/10 | XC-7 | 3.2% | — | Diisoamyl ether/4-methyl-2-pentanol (40% by mass/60% by | 2,6-di-t-Butyl-para-cresol | With the |
| | | | | | | | mass) | | passage |
| T-16 | X-16 | X-19 | 90/10 | XC-1 | 0.8% | — | Diisoamyl ether/4-methyl-2-pentanol (10% by mass/90% by | 2,6-di-t-Butyl-para-cresol | With the |
| | | | | | | | mass) | | passage |
| T-17 | X-16 | X-20 | 90/10 | XC-1 | 0.7% | — | Diisoamyl ether/4-methyl-2-pentanol (10% by mass/90% by | t-Butylhydroquinone | With the |
| | | | | | | | mass) | | passage |
| T-18 | X-16 | X-21 | 90/10 | XC-1 | 1.0% | — | 4-methyl-2-pentanol | t-Butylhydroquinone | With the |
| | | | | | | | | | passage |
| T-19 | X-16 | X-20/X-22 (50% by | 90/10 | XC-1 | 1.2% | W-3 (1.0%) | Diisoamyl ether/4-methyl-2-pentanol (10% by mass/90% by | t-Butylhydroquinone | With the |
| | | mass/50% by mass) | | | | | mass) | | passage |
| T-21 | X-16 | X-24 | 90/10 | XC-1 | 7.3% | — | 4-Methyl-2-pentanol | t-Butylhydroquinone | With the |
| | | | | | | | | | passage |
| T-22 | X-16 | X-25 | 90/10 | XC-1 | 0.9% | — | 4-Methyl-2-pentanol | t-Butylhydroquinone | With the |
| | | | | | | | | | passage |
| T-23 | X-16 | X-26 | 90/10 | XC-1 | 8.6% | — | Diisoamyl ether/4-methyl-2-pentanol (10% by mass/90% by | t-Butylhydroquinone | With the |
| | | | | | | | mass) | | passage |
| T-24 | X-16/X-15 (70% by | X-19 | 90/10 | XC-1/ | 0.7%/0.2% | — | 4-Methyl-2-pentanol | t-Butylhydroquinone | With the |
| | mass/30% by mass) | | | XC-7 | | | | | passage |
| T-25 | X-16 | X-19 | 95/5 | XC-1 | 0.8% | — | 4-Methyl-2-pentanol | t-Butylhydroquinone | With the |
| | | | | | | | | | passage |
| T-26 | X-16 | X-19 | 85/15 | XC-1 | 0.8% | — | 4-Methyl-2-pentanol | t-Butylhydroquinone | With the |
| | | | | | | | | | passage |
| T-27 | X-16 | X-19 | 81/19 | XC-1 | 0.8% | — | n-Decane/4-methyl-2-pentanol (25% by mass/75% by mass) | t-Butylhydroquinone | With the |
| | | | | | | | | | passage |
| T-28 | X-16 | X-19 | 75/25 | XC-1 | 0.8% | — | Diisoamyl ether/n-decane (75% by mass/25% by mass) | t-Butylhydroquinone | With the |
| | | | | | | | | | passage |
| T-29 | X-17 | X-19 | 90/10 | XC-1 | 0.8% | — | 4-Methyl-2-pentanol | t-Butylhydroquinone | With the |
| | | | | | | | | | passage |
| T-30 | X-18 | X-19 | 90/10 | XC-1 | 0.8% | — | 4-Methyl-2-pentanol | 2,6-di-t-Butyl-para-cresol/ | With the |
| | | | | | | | | t-butylhydroquinone | passage |
| T-31 | X-16 | X-27 | 90/10 | XC-1 | 0.8% | — | 4-Methyl-2-pentanol | 2,6-di-t-Butyl-para-cresol/ | With the |
| | | | | | | | | t-butylhydroquinone | passage |
| T-32 | X-7 | X-19 | 90/10 | XC-7 | 1.1% | — | Diisoamyl ether/4-methyl-2-pentanol (10% by mass/90% by | 2,6-di-t-Butyl-para-cresol/ | With the |
| | | | | | | | mass) | t-butylhydroquinone | passage |
| TC-1 | X-1 | X-19 | 90/10 | XC-1 | 0.7% | — | 4-Methyl-2-pentanol | — | With the |
| | | | | | | | | | passage |
| TC-2 | X-2 | X-19 | 90/10 | XC-2 | 5.2% | — | Diisoamyl ether/4-methyl-2-pentanol (20% by mass/80% by | — | With the |
| | | | | | | | mass) | | passage |
| TC-3 | X-3 | X-19 | 90/10 | XC-3 | 0.8% | — | 4-Methyl-2-pentanol | — | With the |
| | | | | | | | | | passage |
| TC-4 | X-4 | X-19 | 90/10 | XC-4 | 3.6% | W-1 (0.5%) | 4-Methyl-2-pentanol | — | With the |
| | | | | | | | | | passage |
| TC-5 | X-5 | X-19 | 90/10 | XC-5 | 0.9% | — | 4-Methyl-1-pentanol | — | With the |
| | | | | | | | | | passage |
| TR-1 | X-1 | X-19 | 90/10 | XC-1 | 0.7% | — | 4-Methyl-2-pentanol | — | Without the |
| | | | | | | | | | passage |
| TR-2 | X-2 | X-19 | 90/10 | XC-2 | 5.2% | — | Diisoamyl ether/4-methyl-2-pentanol (20% by mass/80% by | — | Without the |
| | | | | | | | mass) | | passage |
| TR-3 | X-3 | X-19 | 90/10 | XC-3 | 0.8% | — | 4-Methyl-2-pentanol | — | Without the |
| | | | | | | | | | passage |
| TR-4 | X-4 | X-19 | 90/10 | XC-4 | 3.6% | W-1 (0.5%) | 4-Methyl-2-pentanol | — | Without the |
| | | | | | | | | | passage |
| TR-5 | X-5 | X-19 | 90/10 | XC-5 | 0.9% | — | 4-Methyl-1-pentanol | — | Without the |
| | | | | | | | | | passage |

The abbreviations in the tables are shown below.

(Basic Compound XC)

The following ones were used as the basic compound XC.

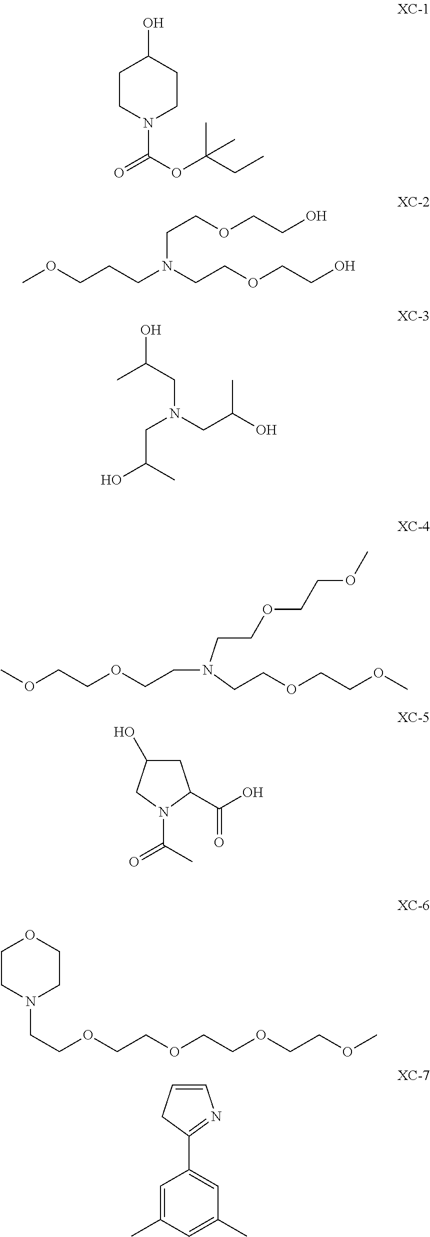

(Surfactant)

The following ones were used as the surfactant.
W-1: PF6320 (manufactured by OMNOVA Solutions Inc.; fluorine-based)
W-2: TROYSOL S-366 (manufactured by Troy Chemical Corp.; silicon-based)
W-3: Polysiloxane Polymer KP-341 (manufactured by Shin-Etsu Chemical Co., Ltd.; silicon-based)

[Resist Composition (Actinic Ray-Sensitive or Radiation-Sensitive Resin Composition)]

### Synthesis Example 2: Synthesis of Resin (1)

102.3 parts by mass of cyclohexanone were heated to 80° C. under a nitrogen stream. While stirring the solution, a mixed liquid of 22.2 parts by mass of a monomer represented by Structural Formula LM-2, 22.8 parts by mass of a monomer represented by Structural Formula PM-1, 6.6 parts by mass of a monomer represented by Structural Formula PM-9, 189.9 parts by mass of cyclohexanone, and 2.40 parts by mass of dimethyl 2,2′-azobisisobutyrate [V-601, manufactured by Wako pure Chemical industry Co., Ltd.] was added dropwise thereto for 5 hours to obtain a reaction solution. After completion of the dropwise addition, the reaction solution was further stirred at 80° C. for 2 hours. After the reaction solution was left to be cooled, it was subjected to reprecipitation with a large amount of hexane/ethyl acetate (mass ratio of 9:1) using the reaction solution, the precipitated solid content was recovered by filtration, and the obtained solid was dried in vacuo to obtain 41.1 parts by mass of a resin (1) as an acid-decomposable resin.

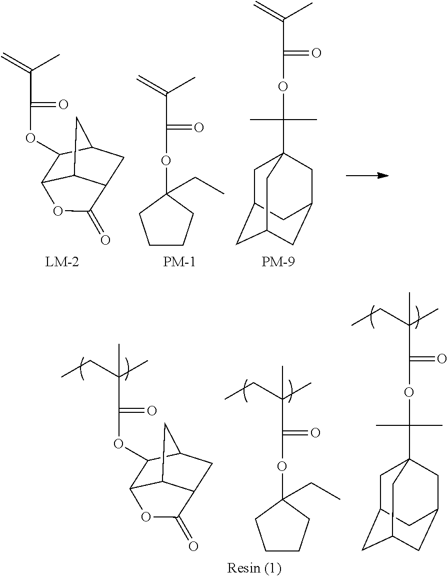

The weight-average molecular weight (Mw: in terms of polystyrene) and the dispersity determined by gel permeation chromatography (GPC) (carrier: tetrahydrofuran) from the obtained resin (1) were Mw=9,500 and Mw/Mn=1.62, respectively. The compositional ratio measured by ¹³C-NMR (Nuclear Magnetic Resonance) was 40/50/10 in terms of a molar ratio.

In the present Examples, the weight-average molecular weight (Mw), the number-average molecular weight (Mn), and the molecular weight distribution (Mw/Mn) of the obtained resin were calculated by GPC measurement under the following measurement conditions.
Column: KF-804L manufactured by Tosoh Corporation (three columns)
Developing solvent: Tetrahydrofuran (THF)
Column temperature: 40° C.
Flow rate: 1.0 mUmin
Device: HLC-8220 manufactured by Tosoh Corporation
Calibration curve: TSK Standard PSt series

<Synthesis of Resins (2) to (13)>

The same operation as in Synthesis Example 1 was carried out to synthesize resins (2) to (13) described below as the acid-decomposable resin.

Hereinbelow, the compositional ratio (molar ratio; corresponding in the order from the left side), the weight-average molecular weight (Mw), and the dispersity (Mw/Mn) of each repeating unit in the resins (1) to (13) are summarized in Table 3. These were determined by the same method as for the above-mentioned resin (1).

TABLE 3

| | | | | | Compositional ratio | | | | Molecular | Dispersity |
|---|---|---|---|---|---|---|---|---|---|---|
| | Repeating unit | | | | (molar ratio) | | | | weight (Mw) | (Mw/Mn) |
| Resin (1) | LM-2 | PM-1 | PM-9 | — | 40 | 50 | 10 | — | 9,500 | 1.62 |
| Resin (2) | LM-2 | PM-12 | PM-13 | — | 40 | 40 | 20 | — | 17,000 | 1.70 |
| Resin (3) | LM-4 | PM-2 | IM-2 | — | 45 | 50 | 5 | — | 11,000 | 1.63 |
| Resin (4) | LM-2 | PM-10 | — | — | 40 | 60 | — | — | 15,000 | 1.66 |
| Resin (5) | LM-2 | PM-3 | PM-9 | IM-3 | 40 | 40 | 10 | 10 | 10,500 | 1.62 |
| Resin (6) | LM-1 | PM-10 | IM-4 | — | 40 | 50 | 10 | — | 15,500 | 1.68 |
| Resin (7) | LM-2 | PM-15 | PM-4 | — | 40 | 40 | 20 | — | 11,000 | 1.65 |
| Resin (8) | LM-3 | PM-3 | PM-14 | — | 40 | 40 | 20 | — | 10,000 | 1.64 |
| Resin (9) | LM-4 | PM-12 | PM-15 | PM-6 | 40 | 50 | 5 | 5 | 9,000 | 1.60 |
| Resin (10) | LM-2 | PM-7 | PM-8 | — | 40 | 30 | 30 | — | 8,000 | 1.63 |
| Resin (11) | LM-3 | PM-13 | IM-1 | PM-5 | 40 | 50 | 5 | 5 | 9,500 | 1.70 |
| Resin (12) | LM-2 | PM-12 | PM-9 | — | 40 | 50 | 10 | — | 17,000 | 1.65 |
| Resin (13) | LM-2 | PM-3 | PM-11 | — | 30 | 30 | 40 | — | 14,000 | 1.71 |

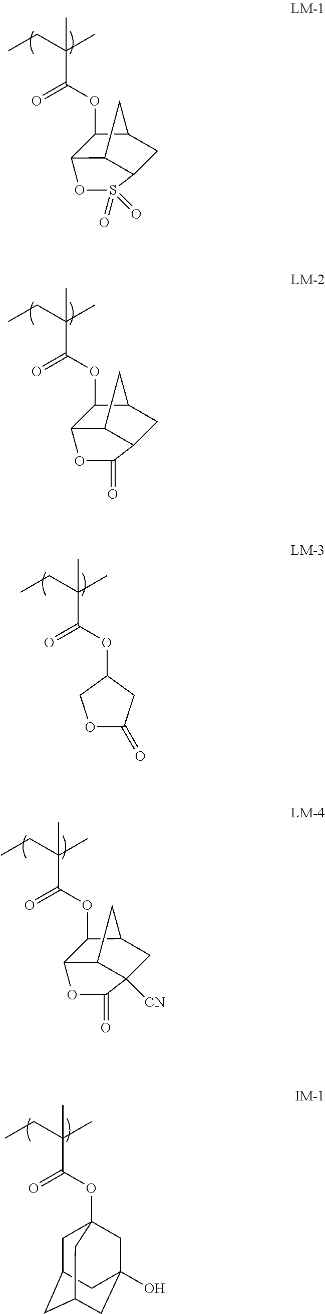

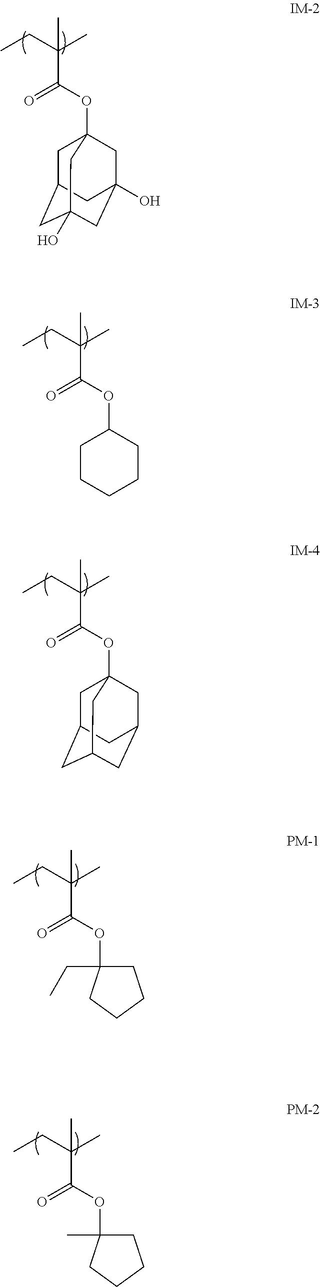

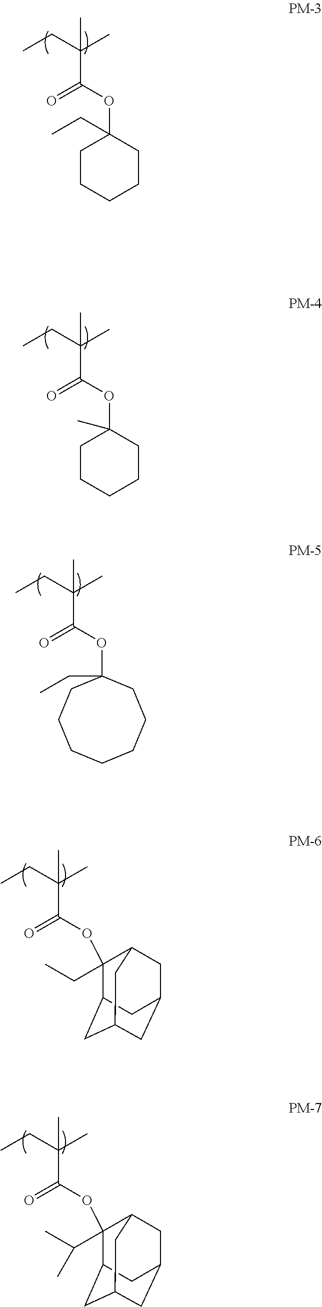

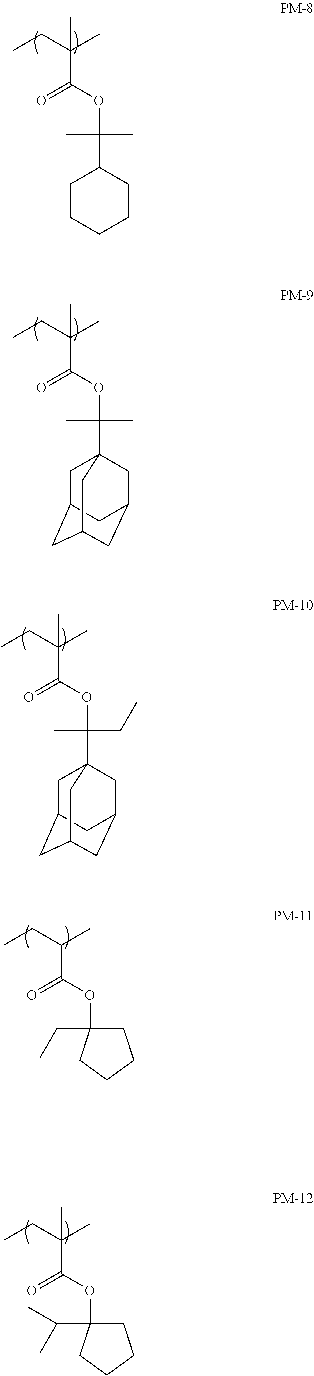

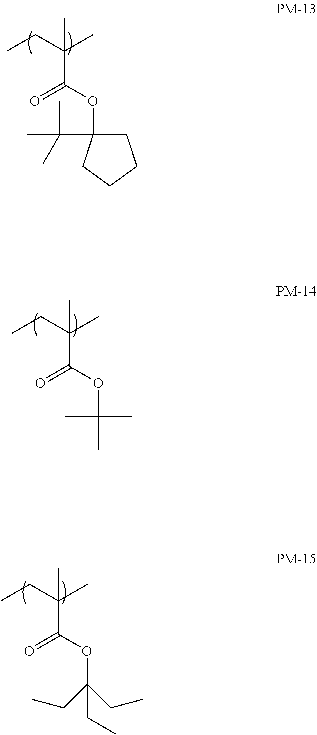

[Preparation of Resist Composition (Actinic Ray-Sensitive or Radiation-Sensitive Resin Composition)]

The components shown in Table 4 below were dissolved in the solvent shown in the same table to prepare a solution having a concentration of solid contents of 3.5% by mass, and the solution was filtered through a polyethylene filter with a pore size of 0.03 μm to prepare resist compositions Re-1 to -16.

TABLE 4

| | Acid-decomposable | | | | | | | | | | | | | | | |
|---|---|---|---|---|---|---|---|---|---|---|---|---|---|---|---|---|
| | resin | | Photoacid generator | | Basic compound | | Hydrophobic resin | | Surfactant | | | | | | | |
| Resist | (parts by mass) | | (parts by mass) | | (parts by mass) | | (parts by mass) | | (parts by mass) | | Solvent (mass ratio) | | | | | |
| Re-1 | Resin (1) | 86.5 | B1 | 12.0 | D-1 | 1.5 | E-1 | 1.0 | | | SL-1 | 70 | SL-2 | 30 | | |
| Re-2 | Resin (2) | 88.7 | B2 | 10.0 | D-1 | 1.3 | E-1 | 1.5 | | | SL-1 | 95 | SL-4 | 5 | | |
| Re-3 | Resin (3) | 86.0 | B3 | 9.5 | D-1 | 4.5 | E-1 | 1.3 | W-1 | 0.3 | SL-1 | 60 | SL-2 | 40 | | |
| Re-4 | Resin (4) | 82.7 | B4 | 15.5 | D-3 | 1.8 | E-1 | 0.5 | | | SL-1 | 60 | SL-3 | 40 | | |
| Re-5 | Resin (5) | 90.7 | B5 | 8.5 | D-4 | 0.8 | E-1 | 0.8 | | | SL-1 | 90 | SL-3 | 10 | | |
| Re-6 | Resin (6) | 88.2 | B6 | 10.5 | D-5 | 1.3 | E-1 | 2.0 | | | SL-2 | 100 | | | | |
| Re-7 | Resin (7) | 87.8 | B7 | 11.0 | D-6 | 1.2 | E-1 | 1.7 | W-2 | 0.5 | SL-1 | 90 | SL-2 | 5 | SL-4 | 5 |
| Re-8 | Resin (8) | 83.5 | B8 | 10.5 | D-2 | 6.0 | E-1 | 1.6 | | | SL-1 | 80 | SL-5 | 20 | | |
| Re-9 | Resin (9) | 87.5 | B2/B5 | 4.0/5.0 | D-1 | 3.5 | E-2 | 3.5 | | | SL-1 | 75 | SL-2 | 25 | | |
| Re-10 | Resin (1)/ | 43.1/40.0 | B3 | 16.0 | D-1 | 0.9 | E-2 | 1.8 | | | SL-1 | 80 | SL-3 | 20 | | |
| | resin (10) | | | | | | | | | | | | | | | |
| Re-11 | Resin (1) | 89.0 | B1 | 10.0 | D-5 | 1.0 | E-1 | 1.7 | | | SL-1 | 70 | SL-6 | 30 | | |
| Re-12 | Resin (10) | 86.5 | B1/B9 | 8.0/4.0 | D-3 | 1.5 | E-1 | 1.4 | | | SL-1 | 70 | SL-7 | 30 | | |
| Re-13 | Resin (11) | 88.7 | B1 | 10.0 | D-3 | 1.3 | E-2 | 2.6 | | | SL-1 | 95 | SL-4 | 5 | | |
| Re-14 | Resin (12) | 86.0 | B3 | 9.5 | D-1 | 4.5 | E-2 | 1.9 | W-3 | 1.0 | SL-1 | 60 | SL-3 | 40 | | |
| Re-15 | Resin (13) | 88.2 | B1 | 10.5 | D-5 | 1.3 | E-1 | 1.7 | | | SL-2 | 100 | | | | |
| Re-16 | Resin (10) | 88.2 | B10 | 10.5 | D-3 | 1.3 | | | | | SL-1 | 60 | SL-2 | 40 | | |

The abbreviations in Table 4 are as follows.

<Photoacid Generator>

The following compounds were used as the photoacid generator.

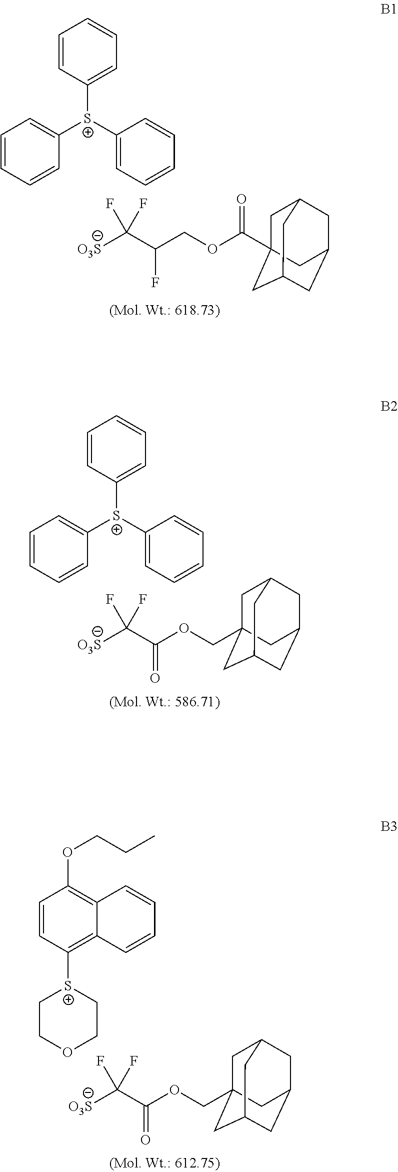

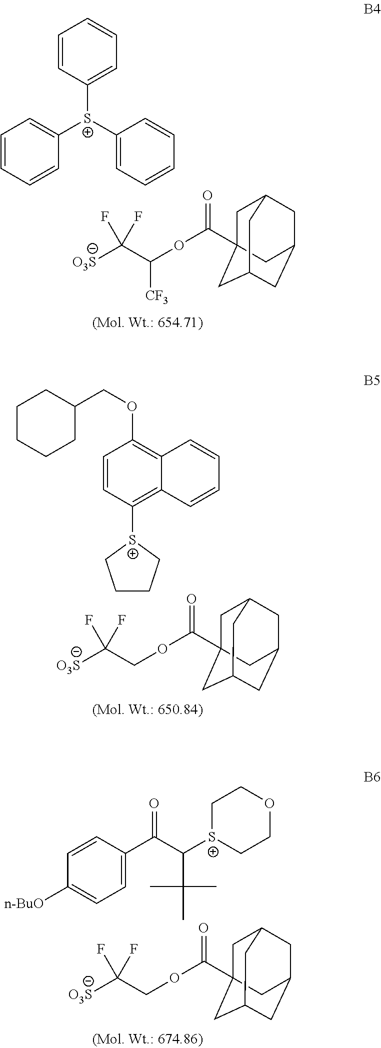

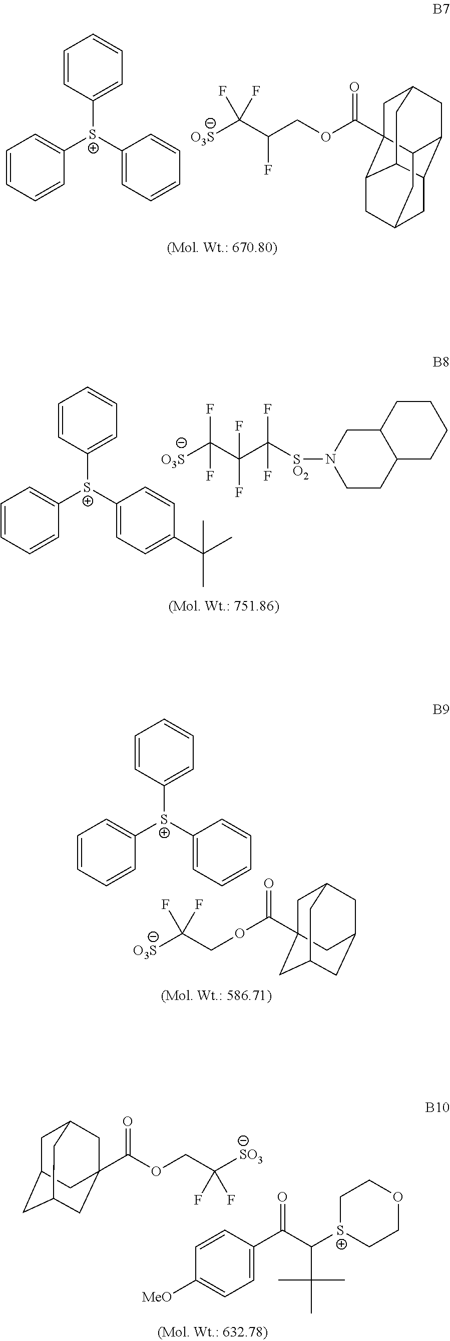

<Basic Compound>

The following compounds were used as the basic compound.

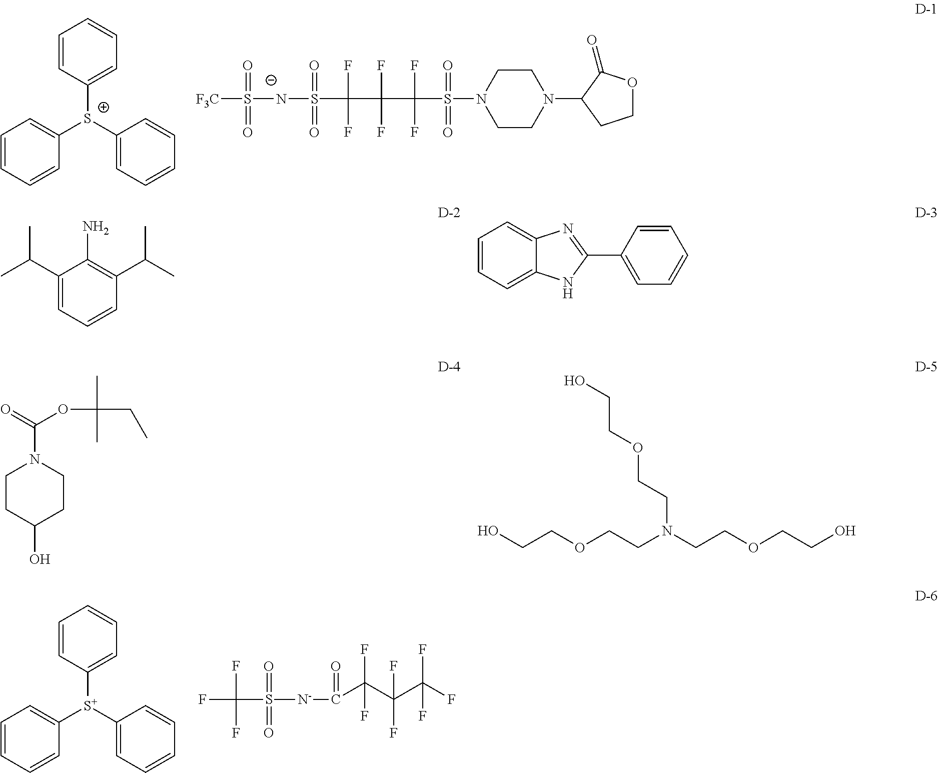

<Hydrophobic Resin>

The following resins were used as the hydrophobic resin. The compositional ratio, the weight-average molecular weight (Mw), and the dispersity (Mw/Mn) of each repeating unit are shown together. These were determined by the same method as for the resin (1) in the resist composition as described above.

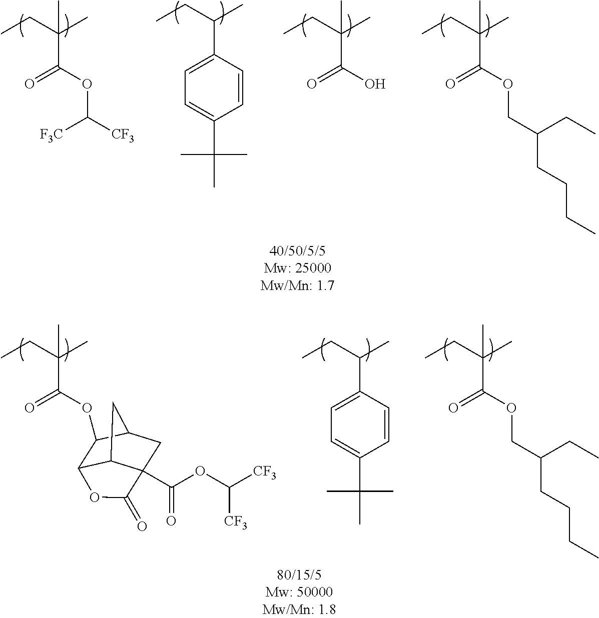

<Surfactant>

The following ones were used as the surfactant.
W-1: PF6320 (manufactured by OMNOVA Solutions Inc.; fluorine-based)
W-2: TROYSOL S-366 (manufactured by Troy Chemical Corp.; silicon-based)
W-3: Polysiloxane Polymer KP-341 (manufactured by Shin-Etsu Chemical Co., Ltd.; silicon-based)

<Solvent>

The following ones were used as the solvent.
SL-1: Propylene glycol monomethyl ether acetate (PGMEA)
SL-2: Cyclohexanone
SL-3: Propylene glycol monomethyl ether (PGME)
SL-4: γ-Butyrolactone
SL-5: Propylene carbonate
SL-6: 2-Ethylbutanol
SL-7: Perfluorobutyl tetrahydrofuran

### Examples 1 to 32, Comparative Examples 1 to 5, and Reference Examples 1 to 5

A laminate film was formed by the following method, using the resist composition and the protective film forming composition, and subjected to various evaluations. The resist compositions and the protective film forming compositions used for formation of the respective laminate films, the organic developers used for development, and the rinsing liquids used for rinsing in Examples 1 to 32, Comparative Examples 1 to 5, and Reference Examples 1 to 5 are shown in Table 5.

[Evaluations]

[Receding Contact Angle]

The receding contact angle of the protective film for water in a case of forming the protective film using the protective film forming composition prepared above was measured by the following method.

Each of the protective film forming compositions was applied onto a silicon wafer by spin coating, and dried at 100° C. for 60 seconds to form a film (with a film thickness of 120 nm). With regard to the obtained film, the receding contact angles (RCA) of water droplets were measured using a dynamic contact angle meter (manufactured by Kyowa Interface Science Co., Ltd.) by an expansion-contraction method.

The liquid droplets (with an initial liquid droplet size of 35 pL) were added dropwise onto the protective film, and suctioned at a rate of 6 L/sec for 5 seconds, and the receding contact angle (RCA) at a time of the dynamic contact angle during suction being stabilized was determined in a measurement environment under 23° C. and a relative humidity of 45%. The results are shown in Table 5.

[Image Performance Test]

Using the resist composition and the protective film forming composition, each prepared above, a laminate film was formed. For the laminate film, a pattern was formed by the following method and evaluated by the following methods.

[Formation of Hole Pattern]

An organic antireflection film forming composition, ARC29SR (manufactured by Brewer Science, Inc.), was applied onto a silicon wafer and baked at 205° C. for 60 seconds to form an antireflection film having a film thickness of 86 nm. A resist composition shown in Table 5 was applied on the obtained antireflection film, and the silicon wafer having the resist composition applied thereon was baked at 100° C. for 60 seconds to form a resist film having a film thickness described in the same table.

Next, a protective film forming composition shown in Table 5 was applied on the resist film and then baked at a PB temperature (unit: ° C.) shown in the same table for 60 seconds to form a protective film having a film thickness shown in the same table, thereby obtaining a laminate film having resist film and the protective film.

Subsequently, the laminate film was subjected to pattern exposure (liquid immersion exposure) via a squarely arrayed halftone mask (in which the hole portions were shielded) with hole portions of 65 nm and pitches between holes of 100 nm, using an ArF excimer laser liquid immersion scanner (manufactured by ASML; XT1700i, NA1.20, C-Quad, outer sigma 0.730, inner sigma 0.630, and XY deflection). Ultrapure water was used as the immersion liquid.

Thereafter, the exposed laminate film was heated (post-exposure baked: PEB) at 90° C. for 60 seconds. Then, development was carried out by puddling for 30 seconds using an organic developer described in Table 5, and rinsed by puddling for 30 seconds using a rinsing liquid described in the same table. Subsequently, the silicon wafer was rotated at a rotation speed of 2,000 rpm for 30 seconds to obtain a hole pattern with a hole diameter of 50 nm.

[Depth of Focus (DOF)]

Exposure and development were carried out by changing the conditions of the exposure focus at an interval of 20 nm in the focus direction in the exposure dose for forming a hole pattern with a hole diameter of 50 nm in the conditions for exposure and development of (Formation of Hole Pattern) above. The hole diameter (CD) of each of the obtained patterns was measured using a line-width critical dimension scanning electron microscope SEM (S-9380, Hitachi High-Technologies Corporation), and a focus corresponding to the minimum value or the maximum value in a curve obtained by plotting the respective CDs was defined as the best focus. In a case where the focus was changed around the best focus, a variation width of the focus tolerating a hole diameter of 50 nm±10%, that is, the depth of focus (DOF, unit: nm) was calculated. A value thereof indicates better performance. The results are shown in Table 5.

[Exposure Latitude (EL)]

The hole size was observed using a critical dimension scanning electron microscope (SEM, S-938011, Hitachi High-Technologies Corporation), and the optimal exposure dose at which a contact hole pattern with a hole portion of 50 nm on average was resolved was defined as a sensitivity (Eₒₚₜ) (mJ/cm²). Then, the exposure dose at a time of the hole size reaching ±10% of 50 nm (that is, 45 nm and 55 nm) which were desired values was determined, based on the determined optimal exposure dose (Eₒₚₜ). Then, an exposure latitude (EL, unit: %) defined by the following equation was calculated. As the value of EL is higher, the change in performance due to a change in the exposure dose is smaller, which is thus good. The results are shown in Table 5.

[EL (%)]=[(Exposure dose at which the hole portion reaches 45 nm)−(Exposure dose at which the hole portion reaches 55 nm)]/Eₒₚₜ×100

TABLE 5

| | | | Protective film | Film thickness | | | | | | | |
|---|---|---|---|---|---|---|---|---|---|---|---|
| | Resist | Film thickness | forming | (nm) of protective | PB after formation of | | | | | | Receding contact angle |
| No. | composition | (nm) of resist | composition | film | protective film | PEB | Organic developer | Rinsing liquid | EL (%) | DOF (nm) | (°) |
| Example 1 | Re-15 | 90 | T-1 | 90 | 90° C./60 s | 90° C./60 s | Butyl acetate | 4-Methyl-2-heptanol | 17.1 | 110 | 85 |
| Example 2 | Re-5 | 90 | T-2 | 60 | 90° C./60 s | 90° C./60 s | Butyl acetate | 4-Methyl-2-heptanol | 16.9 | 110 | 84 |
| Example 3 | Re-9 | 90 | T-3 | 70 | 90° C./60 s | 90° C./60 s | Butyl acetate | 4-Methyl-2-heptanol | 17.2 | 110 | 85 |
| Example 4 | Re-13 | 90 | T-4 | 30 | 100° C./60 s | 90° C./60 s | Butyl acetate | 4-Methyl-2-heptanol | 16 | 100 | 84 |
| Example 5 | Re-15 | 85 | T-5 | 60 | 90° C./60 s | 90° C./60 s | Butyl acetate | 4-Methyl-2-heptanol | 14.2 | 80 | 84 |
| Example 6 | Re-11 | 90 | T-6 | 50 | 90° C./60 s | 90° C./60 s | Butyl acetate | 4-Methyl-2-heptanol | 13.8 | 80 | 84 |
| Example 7 | Re-15 | 70 | T-7 | 70 | 100° C./60 s | 90° C./60 s | Butyl acetate | 4-Methyl-2-heptanol | 14.1 | 80 | 84 |
| Example 8 | Re-12 | 90 | T-8 | 50 | 90° C./60 s | 90° C./60 s | Butyl acetate | 4-Methyl-2-heptanol | 17.3 | 110 | 85 |
| Example 9 | Re-6 | 90 | T-9 | 90 | 90° C./60 s | 90° C./60 s | Butyl acetate | 4-Methyl-2-heptanol | 16.2 | 100 | 84 |
| Example 10 | Re-1 | 90 | T-10 | 90 | 90° C./60 s | 90° C./60 s | Butyl acetate | 4-Methyl-2-heptanol | 16.1 | 100 | 84 |
| Example 11 | Re-5 | 85 | T-11 | 60 | 90° C./60 s | 90° C./60 s | Butyl acetate | — | 14.9 | 110 | 85 |
| Example 12 | Re-13 | 90 | T-12 | 70 | 90° C./60 s | 90° C./60 s | 2-Heptanone | 4-Methyl-2-heptanol | 15.8 | 100 | 84 |
| Example 13 | Re-2 | 90 | T-13 | 30 | 90° C./60 s | 90° C./60 s | Butyl acetate | 4-Methyl-2-heptanol | 18.2 | 120 | 85 |
| Example 14 | Re-16 | 90 | T-14 | 60 | 100° C./60 s | 90° C./60 s | Butyl acetate | 4-Methyl-2-heptanol | 18.1 | 120 | 85 |
| Example 15 | Re-2 | 90 | T-15 | 50 | 90° C./60 s | 90° C./60 s | Butyl acetate | — | 17.3 | 110 | 85 |
| Example 16 | Re-14 | 85 | T-16 | 70 | 90° C./60 s | 90° C./60 s | Butyl acetate | 4-Methyl-2-heptanol | 16.9 | 110 | 84 |
| Example 17 | Re-13 | 70 | T-17 | 50 | 90° C./60 s | 90° C./60 s | Butyl acetate | 4-Methyl-2-heptanol | 17 | 110 | 84 |
| Example 18 | Re-7 | 85 | T-18 | 100 | 100° C./60 s | 90° C./60 s | Butyl acetate | 4-Methyl-2-heptanol | 16 | 100 | 84 |
| Example 19 | Re-7 | 100 | T-19 | 90 | 90° C./60 s | 90° C./60 s | Butyl acetate | 4-Methyl-2-heptanol | 16.9 | 110 | 84 |
| Example 21 | Re-3 | 90 | T-21 | 70 | 90° C./60 s | 90° C./60 s | Butyl acetate | 4-Methyl-2-heptanol | 16.3 | 100 | 84 |
| Example 22 | Re-15 | 90 | T-22 | 30 | 100° C./60 s | 90° C./60 s | Butyl acetate | 4-Methyl-2-heptanol | 15.9 | 100 | 84 |
| Example 23 | Re-1 | 90 | T-23 | 60 | 90° C./60 s | 90° C./60 s | Butyl propionate | 4-Methyl-2-heptanol | 17 | 110 | 84 |
| Example 24 | Re-8 | 90 | T-24 | 50 | 90° C./60 s | 90° C./60 s | Butyl acetate | 4-Methyl-2-heptanol | 16.2 | 100 | 84 |
| Example 25 | Re-11 | 90 | T-25 | 70 | 90° C./60 s | 90° C./60 s | Butyl acetate | 4-Methyl-2-heptanol | 15.7 | 100 | 84 |
| Example 26 | Re-4 | 90 | T-26 | 50 | 90° C./60 s | 90° C./60 s | Butyl acetate | n-decane | 16.1 | 100 | 84 |
| Example 27 | Re-15 | 90 | T-27 | 90 | 90° C./60 s | 90° C./60 s | Butyl acetate | 4-Methyl-2-heptanol | 15.8 | 100 | 84 |
| Example 28 | Re-10 | 90 | T-28 | 90 | 90° C./60 s | 90° C./60 s | Butyl acetate | 4-Methyl-2-heptanol | 12.2 | 60 | 85 |
| Example 29 | Re-15 | 90 | T-29 | 90 | 90° C./60 s | 90° C./60 s | Butyl acetate | 4-Methyl-2-heptanol | 15.6 | 100 | 84 |
| Example 30 | Re-15 | 90 | T-30 | 90 | 90° C./60 s | 90° C./60 s | Butyl acetate | 4-Methyl-2-heptanol | 15.1 | 90 | 83 |
| Example 31 | Re-15 | 90 | T-31 | 90 | 90° C./60 s | 90° C./60 s | Butyl acetate | 4-Methyl-2-heptanol | 14.8 | 90 | 83 |
| Example 32 | Re-15 | 70 | T-32 | 70 | 100° C./60 s | 90° C./60 s | Butyl acetate | 4-Methyl-2-heptanol | 15.1 | 90 | 84 |
| Comparative | Re-15 | 90 | TC-1 | 90 | 90° C./60 s | 90° C./60 s | Butyl acetate | 4-Methyl-2-heptanol | 11.3 | 50 | 78 |
| Example 1 | | | | | | | | | | | |
| Comparative | Re-5 | 90 | TC-2 | 60 | 90° C./60 s | 90° C./60 s | Butyl acetate | 4-Methyl-2-heptanol | 10.9 | 50 | 78 |
| Example 2 | | | | | | | | | | | |
| Comparative | Re-9 | 90 | TC-3 | 70 | 90° C./60 s | 90° C./60 s | Butyl acetate | 4-Methyl-2-heptanol | 11.4 | 50 | 78 |
| Example 3 | | | | | | | | | | | |
| Comparative | Re-13 | 90 | TC-4 | 30 | 100° C./60 s | 90° C./60 s | Butyl acetate | 4-Methyl-2-heptanol | 10.8 | 50 | 83 |
| Example 4 | | | | | | | | | | | |
| Comparative | Re-15 | 85 | TC-5 | 60 | 90° C./60 s | 90° C./60 s | Butyl acetate | 4-Methyl-2-heptanol | 11.1 | 50 | 83 |
| Example 5 | | | | | | | | | | | |
| Reference | Re-15 | 90 | TR-1 | 90 | 90° C./60 s | 90° C./60 s | Butyl acetate | 4-Methyl-2-heptanol | 17.1 | 110 | 85 |
| Example 1 | | | | | | | | | | | |
| Reference | Re-5 | 90 | TR-2 | 60 | 90° C./60 s | 90° C./60 s | Butyl acetate | 4-Methyl-2-heptanol | 16.9 | 110 | 84 |
| Example 2 | | | | | | | | | | | |
| Reference | Re-9 | 90 | TR-3 | 70 | 90° C./60 s | 90° C./60 s | Butyl acetate | 4-Methyl-2-heptanol | 17.2 | 110 | 85 |
| Example 3 | | | | | | | | | | | |
| Reference | Re-13 | 90 | TR-4 | 30 | 100° C./60 s | 90° C./60 s | Butyl acetate | 4-Methyl-2-heptanol | 16 | 100 | 84 |
| Example 4 | | | | | | | | | | | |
| Reference | Re-15 | 85 | TR-5 | 60 | 90° C./60 s | 90° C./60 s | Butyl acetate | 4-Methyl-2-heptanol | 14.2 | 80 | 84 |
| Example 5 | | | | | | | | | | | |

As seen from the results shown in Table 5, desired effects of the present invention were obtained with the protective film forming compositions of Examples 1 to 32, which contained the resin, the basic compound, the solvent, and the antioxidant. On the other hand, the desired effects were not obtained with the protective film forming compositions of Comparative Examples 1 to 5, which did not contain the antioxidant.

Furthermore, in each of Examples 16, 26, and 27 in which the content of the resin XB was 20% by mass or less with respect to the total solid content of the protective film forming composition, more excellent effects of the present inventions than those of the protective film forming composition of Example 28 were obtained.

Moreover, the protective film forming composition of Example 16, in which the content of fluorine atoms in the resin XA was 0% to 5% by mass, had more excellent effects of the present invention than the protective film forming composition of Example 30.

Furthermore, the protective film forming composition of Example 16, in which the content of fluorine atoms in the resin XB was 15% by mass or more, had more excellent effects of the present invention than the protective film forming composition of Example 31.

Incidentally, the protective film forming composition of Example 32, in which the solvent contained the secondary alcohol and the ether solvent, had more excellent effects of the present invention than the protective film forming composition of Example 7.

In addition, the protective film forming composition of Example 3, in which the resin XA was a resin not containing fluorine atoms, had more excellent effects of the present invention than the protective film forming composition of Example 10.

What is claimed is:

1. A protective film forming composition, comprising:
a resin;
a basic compound;
a solvent; and
an antioxidant.

2. The protective film forming composition according to claim 1,
wherein the resin contains a resin XA and a resin XB containing fluorine atoms, and
the resin XA is a resin not containing fluorine atoms, or in a case where the resin XA contains fluorine atoms, the resin XA is a resin having a lower content of fluorine atoms than the content of fluorine atoms in the resin XB, based on a mass.

3. The protective film forming composition according to claim 2,
wherein the content of the resin XB is 20% by mass or less with respect to the total solid content of the protective film forming composition.

4. The protective film forming composition according to claim 1,
wherein the solvent contains a secondary alcohol.

5. The protective film forming composition according to claim 2,
wherein the content of fluorine atoms in the resin XA is 0% to 5% by mass.

6. The protective film forming composition according to claim 2,
wherein the content of fluorine atoms in the resin XB is 15% by mass or more.

7. The protective film forming composition according to claim 1,
wherein the solvent contains a secondary alcohol and an ether-based solvent.

8. The protective film forming composition according to claim 2,
wherein the difference between the content of fluorine atoms in the resin XA and the content of fluorine atoms in the resin XB is 10% by mass or more.

9. The protective film forming composition according to claim 2,
wherein the resin XA is a resin not containing fluorine atoms.

10. The protective film forming composition according to claim 1,
wherein the basic compound contains at least one selected from the group consisting of an amine compound and an amide compound.

11. A method for producing a protective film forming composition, comprising:
a step of preparing a solvent having a content of peroxides of an acceptable value or less; and
a step of mixing the solvent, a resin, a basic compound, and an antioxidant to prepare a protective film forming composition.

12. A pattern forming method comprising:
a step of forming an actinic ray-sensitive or radiation-sensitive film on a substrate, using an actinic ray-sensitive or radiation-sensitive resin composition;
a step of forming a protective film on the actinic ray-sensitive or radiation-sensitive film, using the protective film forming composition according to claim 1;
a step of exposing a laminate film including the actinic ray-sensitive or radiation-sensitive film and the protective film; and
a step of subjecting the exposed laminate film to development using a developer,
wherein the protective film forming composition contains a resin, a basic compound, a solvent, and an antioxidant.

13. The pattern forming method according to claim 12,
wherein the exposure is liquid immersion exposure.

14. A method for manufacturing an electronic device, comprising the pattern forming method according to claim 12.

15. The protective film forming composition according to claim 2,
wherein the solvent contains a secondary alcohol.

16. The protective film forming composition according to claim 3,
wherein the solvent contains a secondary alcohol.

17. The protective film forming composition according to claim 3,
wherein the content of fluorine atoms in the resin XA is 0% to 5% by mass.

18. The protective film forming composition according to claim 4,
wherein the content of fluorine atoms in the resin XA is 0% to 5% by mass.

19. The protective film forming composition according to claim 2,
wherein the solvent contains a secondary alcohol and an ether-based solvent.

20. The protective film forming composition according to claim 3,
wherein the solvent contains a secondary alcohol and an ether-based solvent.
